(19) United States
(12) Patent Application Publication
(10) Pub. No.: US 2025/0341560 A1
(43) Pub. Date: Nov. 6, 2025

(54) MULTI-BAND DETECTION AND CLASSIFICATION OF PARTIAL DISCHARGE

(71) Applicant: OSENSA INNOVATIONS CORP., Burnaby (CA)

(72) Inventors: Jeffrey Charles ANDLE, Orlando, FL (US); Peter RIZUN, Harrison Hot Springs (CA); Daryl G. JAMES, Coquitlam (CA)

(21) Appl. No.: 19/197,943

(22) Filed: May 2, 2025

Related U.S. Application Data
(60) Provisional application No. 63/642,863, filed on May 5, 2024.
(60) Provisional application No. 63/642,867, filed on May 5, 2024.

(51) Int. Cl. G01R 31/16

(52) U.S. Cl. CPC G01R 31/16

(57) ABSTRACT

A method for detecting a partial discharge in electric power equipment is disclosed. Two or more narrowband signals corresponding to respective frequency bands of the partial discharge are obtained by two or more receivers, and a temporal coincidence of the two or more narrowband signals is detected, thereby indicating a possible presence of the partial discharge. Then a synchronous recurrence of the partial discharge over a plurality of power cycles is determined, thereby validating the possible presence of the partial discharge. A corresponding system is also provided.

### CROSS-REFERENCE TO RELATED APPLICATIONS

The present application claims the benefit from the U.S. patent provisional applications 63/642,863 and 63/642,867 filed on May 5, 2024, the entire contents of which are incorporated herein by reference.

### FIELD OF THE INVENTION

The present invention addresses methods, devices and systems for more reliably detecting partial discharge in medium and high voltage insulation using ultra-high frequency (UHF) radio wave detection.

### BACKGROUND OF THE INVENTION

The detection of partial discharge (PD) is important in the preventive and predictive maintenance regimens of medium and high voltage equipment. Partial discharge can occur in the insulation of any electrical equipment over about 1000V. While there are many assets in the electrical grid at voltage levels from 70 kV to 1 MV, and these systems definitely need to prevent unexpected failures, the overwhelming majority of commercially and technically relevant systems are between 3 kV and 40 kV in the generation, distribution, and industrial end use of electrical power. Laboratory methods and off-line, in situ methods of measuring partial discharge are highly refined and offer powerful analytical tools. These systems remove grid power, which is noisy, from the system and supply a controlled, clean power to one phase at a time.

However, failures can evolve faster than the typical off-line service intervals and these methods are expensive. Continuous, on-line monitoring systems are preferred for preventive and predictive maintenance, especially in less critical and more numerous assets where off-line testing is too expensive. The present invention improves on a non-contact, in situ, continuous class of measurements using the electromagnetic waves radiated from the point of discharge as an indicator of partial discharge. It addresses the competing challenges of high sensitivity and broad frequency bandwidth needed to reliably detect partial discharge emissions with frequency selectivity needed to avoid and ignore interfering radio transmissions in an evermore crowded frequency spectrum.

### SUMMARY OF THE INVENTION

According to one aspect of the invention the approach uses narrow band detectors to avoid other radio signals in an over-crowded radio spectrum but still maintains frequency diversity by having a plurality of selected frequency bands. The various bands are simultaneously sampled in order to verify that a received signal is wideband by verifying that the filtered replicas are coincident in time. Other aspects include examining the shape of detected pulses for correlation to one or more signatures in each of the narrow bandwidths to classify signals. Other aspects of the invention are limited to AC power systems and address rejecting signals that are not recurrent at about the same phase of the AC power cycle while rejecting signals with low recurrence or random phase relationship to the power system. Other aspects of the invention attribute the existence of partial discharge in sub spans of the three phase AC power cycle as being localized to an insulator bridging either a specific line to neutral or a line to line spacing.

According to one aspect of the invention, there is provided a method for detecting a partial discharge in electric power equipment, comprising:
(a) by at least two receivers, obtaining corresponding at least two narrowband signals corresponding to respective frequency bands of the partial discharge; and
(b) detecting a temporal coincidence of said at least two narrowband signals, thereby indicating presence of the partial discharge.

The method further comprises identifying a synchronous recurrence of the partial discharge over a plurality of power cycles, thereby validating the possible presence of the partial discharge.

In the method described above, the step (a) comprises:
receiving electromagnetic signals using one or more antennas placed in the vicinity of said electric power equipment at a location selected to acquire radiation induced by the partial discharge;
submitting output electrical signals of said one or more antennas to a set of bandpass filters of different passbands;
the step (b) comprises:
   detecting significant pulses within output signal streams of said set of bandpass filters, each significant pulse indicating a possible partial discharge; and
   determining candidate indicators of occurrence of the partial discharge as significant pulses that appear concurrently in two or more of the output signal streams of said set of bandpass filters.

In the method described above, the significant pulses have an amplitude exceeding a specified threshold and a joint overlap time interval exceeding a specified time duration. The specified threshold might be implicit as the lower range of the analog-to-digital convertor or might be a set parameter of firmware.

The method further comprises:
determining a pattern of said determining candidate indicators between each electric power cycle of a moving superset of a predetermined number of successive electric power cycles;
comparing the most recent of said candidate indicators to previous indicators within said superset occurring within a predetermined time interval of the superset of power cycles related to the times of said candidate indicators; and
affirming that said candidate indicators repeat synchronously and at the same or higher signal strength, a predetermined number of times within the superset.

The method further comprises:
dividing each said power cycle into a number of monitoring periods;
comparing said output signal streams of said set of bandpass filters during each monitoring period to determine temporal coincidence of a majority of said significant pulses; and
acquiring said candidate indicators for each of said successive power cycles.

The method further comprises:
employing a second set of bandpass filters, exceeding said set of passband filters, each being coupled to an output of said one or more antennas; and
selecting a number of output signal streams from said second set of bandpass filters, equal to a number of bandpass filters in said set of bandpass filters, based on signal quality indications.

In the method, the step (b) is based on one of the following:
direct logarithmic envelope detection of said at least two narrowband signals;
direct linear envelope detection of said at least two narrowband signals; and
direct linear envelope detection of said at least two narrowband signals to produce detected envelopes followed by logarithmic conversion of the detected envelopes.

In the method, the step (b) comprises processing said at least two narrowband signals according to a peak and hold method to capture amplitudes of partial discharge pulses, with optional blanking feature to suppress noise.

In the above peak and hold method, pulses are processed as follows. Initialize a candidate “peak” variable to the system minimum value, a “count” variable to zero, and a “blocking” flag to false.

On each received “new” sample, if the “blanking” flag is false:
If “new”> “peak”, then set “peak” to “new” and set “count” to zero, resetting the peak window with the newer candidate peak. Otherwise, increment “count”.
If “count” has reached a first limit, being the peak window length,
   If “peak” is larger than a threshold, set the “blanking” flag.
   Output “peak”. Set “peak” to system minimum value and reset “count” to zero.
Else output the system minimum value.

On each received “new” sample, if the “blanking” flag is true:
Increment “count”.

If “count” has reached a second limit, being the blanking window length, reset “count” to 0 and clear the “blanking” flag to false.

In the method described above, said partial discharge belongs to a known set of classes of partial discharges, and said different passbands are selected based on known bandwidths of radiated spectra of said partial discharges, said passbands being selected according to one of the following:
equal bandwidths around spread central frequencies; and
bandwidths determined as a function of central frequencies.

The method further comprises classifying the partial discharge signal.

In the method, said partial discharge belongs to a known set of classes of partial discharges, the method further comprises determining a number of class-specific, band-specific, signatures for each class of said set of classes and each spectral band of said different passbands based on:
acquiring a set of reference signals, each reference signal representing a respective class of partial discharge at source;
supplying, said each reference signal to each bandpass filter of said set of bandpass filters; and
extracting said class-specific, band-specific, signatures as detected signals of said set of bandpass filters.

The reference signals may be synthesized by design and need not be physically acquired.

In the method described above, said partial discharge belongs to a known set of classes of partial discharges, the method further comprising:
determining a number of class-specific, band-specific, signatures for each class of said set of classes and each spectral band of said different passbands based on:
acquiring one of:
   a set of time-domain characterizations of partial-discharge at source, each time-domain characterization corresponding to a respective partial-discharge class; and
   a set of frequency-domain characterizations of partial-discharge at source, each
   frequency-domain characterization corresponding to a respective partial-discharge class; and
   computing said class-specific, band-specific, signatures using an analytical model of said bandpass filters, and one of said time-domain characterizations and frequency-domain characterization.

The method further comprises:
for each set of class-specific signatures, comparing a shape of each of said significant pulses with a respective band-specific signature to produce respective shape-similarity indicators;
and
associating said significant pulses with either of:
   at least one of the classes of said known set of classes of partial discharges based on acceptable levels of said respective shape-similarity indicators; and
   a null class otherwise.

The method further comprises determining said respective shape-similarity indicators prior to said determining candidate indicators.

The method further comprises visualizing the partial discharge.

According to another aspect of the invention, there is provided a system for detecting a partial discharge in electrical power equipment, comprising:
(a) at least two receivers for obtaining corresponding at least two narrowband signals corresponding to respective frequency bands of the partial discharge signal; and
(b) a means for detecting a temporal coincidence of said at least two narrowband signals, thereby indicating a presence of the partial discharge.

The system further comprises a means for identifying a synchronous recurrence of the partial discharge signal over a plurality of power cycles, thereby validating the partial discharge.

In the system described above, said at least two receivers (a) comprise:
at least one antenna placed at a location selected to acquire electromagnetic radiation induced by the partial discharge;
a set of bandpass filters, of different passbands, each coupled to said at least one antenna to produce a respective signal stream;
said means for detecting (b) comprise:
   a set of pulse detectors, each detector for detecting pulses within a signal stream of a respective bandpass filter; and
   a coincidence filter configured to determine occurrence of a possible partial discharge based on the pulses appearing concurrently in two or more of the signal streams of said pulse detectors.

In the system described above, the significant pulses have an amplitude exceeding a specified threshold and a joint overlap time interval exceeding a specified time duration. The overlap time interval could be as short as the ADC sample and hold time.

The system further comprises a synchronicity filter configured to:
determine a pattern of detected signals within each electric power cycle of a moving superset of a predetermined number of successive electric power cycles;
identify signals, within said superset, occurring within a predefined mutual phase-displacement within a power cycle period; and
affirm that said detected signals repeat synchronously at the same or higher signal strength, a predetermined number of times within the superset.

The system further comprises a buffer for holding said candidate indicators of occurrence of partial discharges during a moving superset of a predetermined number of successive electric power cycles.

The buffer may be a circular buffer, comprising:
a number, equal to said predetermined number, of separate memory devices for storing said candidate indicators during said moving superset of a predetermined number of successive electric-power cycles; and
a module for the number of identifying prior coincidence records equal to or greater than a current coincidence record.

In the apparatus, said circular buffer is configured as a shared memory device for storing said candidate indicators during said moving superset of said predetermined number of successive electric-power cycles.

In the system described above, said each detector is one of:
a logarithmic envelope detector directly coupled to said respective bandpass filter;
a linear envelope detector directly coupled to said respective bandpass filter; and
a linear envelope detector, directly coupled to said respective bandpass filter to produce detected envelopes, coupled to a logarithmic converter of the detected envelopes.

The system is configured to select said set of bandpass filters and said set of detectors from a larger number of antennas, together with corresponding bandpass filters and detectors, based on signal-quality indications.

The system further comprises means for processing the output signal streams of said set of bandpass filters according to a peak and hold technique to capture amplitudes of partial discharge pulses, with an optional blanking feature for suppressing noise.

The system further comprises means for classifying the partial discharge signal.

The system further comprises a module for determining a number of class-specific, band-specific signatures for each class of a known set of partial discharge classes and each spectral band of said different passbands, said module configured to:
acquire a set of reference signals, each reference signal representing a respective partial discharge class at a source; and
supply said each reference signal to each bandpass filter of said set of bandpass filters; and
extract said class-specific, band-specific, signatures as detected signals of said set of bandpass filters.

The system further comprises a classification module, for classifying the partial discharge, configured to:
compare each of said candidate indicators of occurrence of the partial discharge with a respective band-specific signature to produce respective shape-similarity indicators; and
associate said candidate indicators with a respective class according to said respective shape-similarity indicators.

In the system described above, the means for detecting further comprises a single historical buffer configured to store trailing average data for partial discharge for at least one cycle length.

For example, the system may comprise a simplified synchronicity filter coupled to said coincidence filter, the simplified synchronicity filter having a single historical buffer and configured to:
receive samples from the coincidence filter;
upon receiving a sample of magnitude “A” with the buffer's content being of magnitude “B”, provide an output determined as the lesser of “A” and “B”; and
update the buffer content to a value equal to {A×(1.0−F)+B×F}, F being a predefined positive averaging factor between 0.0 and 1.0.

The system further comprising a means for visualizing the partial discharge.

Thus, improved methods and system for detecting and classifying a partial discharge have been provided.

### BRIEF DESCRIPTION OF THE DRAWINGS

The patent or application file contains at least one drawing executed in color. Copies of this patent application publication with color drawing(s) will be provided by the Office upon request and payment of the necessary fee.

Embodiments of the present invention will be further described with reference to the accompanying exemplary drawings, in which:

FIG. 1 illustrates a set of broadband antennas receiving electromagnetic waves (EM waves) including partial-discharge (PD) pulses and extraneous signals, in accordance with an embodiment of the present invention;

FIG. 2 illustrates time domain and frequency domain representations of exemplary pulses that may be from PD or from noise sources for use in embodiments of the present invention;

FIG. 3 illustrates extraction of a predefined number (five in the illustrated example) of narrowband signals from the spectrum received at one or more antennas, only the spectra of the illustrated PD pulses are illustrated, the narrowband signals are used for ascertaining presence, or otherwise, of PD pulses, in accordance with an embodiment of the present invention;

FIG. 4 illustrates pass-band extraction using band-pass filters of equal pass bands (10 MHz, each) around spread central frequencies selected according to expected spectra of received PD pulses at the antennas, in accordance with an embodiment of the present invention;

FIG. 5 illustrates pass-band extraction using band-pass filters of different pass bands (between 10 and 20 MHz) around spread central frequencies selected according to expected spectra of received PD pulses at the antennas, in accordance with an embodiment of the present invention;

FIG. 6 illustrates sampling of output signals of a single log detectors following a bandpass filter of a passband of Ω, with an option of using a time-window sampler (coarse sampler) preceding a fine sampler sampling at a rate observing the Nyquist-Shannon rate, in accordance with an embodiment of the present invention;

FIG. 7 illustrates exemplary cyclical recurring PDs in a single-phase high-voltage power generation or distribution system;

FIG. 8 illustrates conventional three-phase voltages at points of generation and distribution;

FIG. 9 illustrates a cross-section of an underground three-phase high-voltage cable for use in an embodiment of the present invention;

FIG. 10 illustrates paths of potential partial discharge at end points of a high-voltage three-phase underground cable;

FIG. 11 illustrates paths of potential partial discharge at end points of high-voltage three-phase overhead transmission lines;

FIG. 12 illustrates local-outlet voltage phase versus possible high-voltage phases;

FIG. 13 illustrates potential intra-phase partial discharges (PDs) in one cycle (20 milliseconds or 50/3 milliseconds);

FIG. 14 illustrates a simplified view of potential intra-phase PDs in one power cycle;

FIG. 15 illustrates potential inter-phase partial discharges (PDs) in one power cycle;

FIG. 16 illustrates a simplified view of potential inter-phase PDs in one power cycle;

FIG. 17 illustrates combined potential intra-phase and inter-phase partial discharges;

FIG. 18 illustrates a simplified view of combined potential intra-phase and inter-phase PDs;

FIG. 19 illustrates time-window sampling (coarse sampling) to precede fine sampling targeting only potential intra-phase PDs, in accordance with an embodiment of the present invention;

FIG. 20 illustrates time-window sampling (coarse sampling) to precede fine sampling targeting only potential inter-phase PDs, in accordance with an embodiment of the present invention;

FIG. 21 illustrates a scheme for identifying sources of intra-phase PDs using time-window sampling;

FIG. 22 illustrates a scheme for identifying sources of inter-phase PDs using time-window sampling;

FIG. 23 illustrates sorting detected-signal data into time bins for a case of known absence of inter-phase PDs, in accordance with an embodiment of the present invention;

FIG. 24 illustrates sorting detected-signal data into time bins for a case of potential intra-phase and inter-phase PDs, in accordance with an embodiment of the present invention;

FIG. 25 is an overview of a method of detecting partial charge, in accordance with an embodiment of the present invention;

FIG. 26 illustrates a method of confirming synchronous recurrence of detected PDs in multiple power cycles, in accordance with an embodiment of the present invention;

FIG. 27 illustrates an example of output of a process within the method of FIG. 26 determining of the maximum synchronously recurring value of detected PD signals in the new sample and prior super cycle as confirmation of PD detection;

FIG. 28 illustrates selecting a set of narrower bands from an envisaged broadband of PD electromagnetic (EM) spectrum, extracting respective narrowband signals from the electrical output signals of the antennas, and using logarithmic detectors (log detectors) to produce wider-duration pulses from each narrow-band signal to be used for ascertaining and classification of any received PDF EM wave, in accordance with an embodiment of the present invention;

FIG. 29 illustrates an option of using more receivers than intended for extracting narrow band signals from the electric output signal(s) of the antenna(s) in order to facilitate distinguishing PD signals from background extraneous signals, in accordance with an embodiment of the present invention;

FIG. 30 is an overview of a PD detection system comprising an analog receiver and a processing hub;

FIG. 31 illustrates basic components of the processing hub, including set of fine samplers and A/D convertors, a coincidence filter, and a synchronicity filter, in accordance with an embodiment of the present invention;

FIG. 32 illustrates a pulse-shape comparator for a single PD class;

FIG. 33 illustrates an augmented coincidence filter for a single PD-class, based on using either pulse-shapes similarities or raw pulse data for temporal coincidence filter inputs, in accordance with an embodiment of the present invention;

FIG. 34 illustrates use of a set of parallel augmented coincidence filters to determine coincidence indicators for multiple PD classes, in accordance with an embodiment of the present invention;

FIG. 35 is a generic representation of augmented coincidence detector;

FIG. 36 illustrates a basic hardware structure of a processing hub, in accordance with an embodiment of the present invention;

FIG. 37 illustrates an arrangement for confirming PD-detection, if any, using a circular buffer for retaining any detected PDs' data during a moving time window and synchronicity filter identifying multiple occurrences of any detected PD in a super cycle of a number of power cycles

FIG. 38 illustrates a process of generating reference band-specific PD-pulse shapes for used in classifying detected PD pulses, in accordance with an embodiment of the present invention;

FIG. 39 illustrates exemplary patterns of detected pulses of individual channels 1 to χ, for χ=4;

FIG. 40 presents an alternate representation of the patterns of FIG. 39;

FIG. 41 illustrates incidences of PDs to a power cycle at a three-phase high-voltage generation or distribution facility where the phase difference between the sinusoidal high-voltage source of the PDs and an accessible stepped-down low-voltage sinusoidal waveform is negligible;

FIG. 42 illustrates incidences of PDs to a power cycle at a three-phase high-voltage generation or distribution facility where the phase difference between the sinusoidal high-voltage source of the PDs and an accessible stepped-down low-voltage sinusoidal waveform is approximately 2π/3 radians;

FIG. 43 illustrates incidences of PDs to a power cycle at a three-phase high-voltage generation or distribution facility where the phase difference between the sinusoidal high-voltage source of the PDs and an accessible stepped-down low-voltage sinusoidal waveform is approximately 4π/3 radians;

FIG. 44 illustrates an arrangement for use of fine sampling of the output signals of the log detectors to establish coincidence, or otherwise, of detected samples from the output samples, in accordance with an embodiment of the present invention;

FIG. 45 illustrates a process of determining temporal coincidence of pulses detected from the band-specific samples;

FIG. 46 is an overview of an arrangement for determining coincidence of a number of band-specific pulses, in accordance with an embodiment of the present invention;

FIG. 47 illustrates operation of a synchronicity filter using separate memory devices for determining multiple occurrences of detected pulses during a current power-cycle within a preceding moving super cycle of a number of power-cycles (20 or 50/3 milliseconds each), in accordance with an embodiment of the present invention;

FIG. 48 illustrates exemplary candidate PD indicators within a super cycle of power cycles;

FIG. 49 illustrates a memory device operated in a circular storage mode for holding validated PD-related pulse for each cycle of a moving super cycle;

FIG. 50 illustrates an arrangement for temporal coordination of the processes of a coincidence filter determining coincidence of detected pulses and synchronicity determination, in accordance with an embodiment of the present invention;

FIG. 51 illustrates an analog coincidence filter, in accordance with an embodiment of the present invention;

FIG. 52 illustrates processing of the output of the analog coincidence filter in a simplified processing hub;

FIG. 53 illustrates a process of generating time windows within a power cycle of the high-voltage source corresponding to intra-phase and inter-phase voltage peaks and troughs, in accordance with an embodiment of the present invention;

FIG. 54 illustrates a method for identifying a source, or sources, of detected partial discharges.

FIG. 55 illustrates a memory for accumulating data used to create an image being a graphical representation of partial discharge;

FIG. 56 illustrates an alternate system for detecting partial discharges, in accordance with an embodiment of the present invention;

FIG. 57 illustrates an alternate method for detecting PDs;

FIG. 58A shows a cloud plot 800 illustrating the partial discharge;

FIG. 58B shows a gray scale bitmap 801 illustrating the partial discharge;

FIG. 59 illustrates non-overlapping observation windows;

FIG. 60 illustrates overlapping observation windows'

FIG. 61 illustrates dual observation windows;

FIG. 62 illustrates a table relating ranges of time instants to identifiers of dual observation windows; and

FIG. 63 illustrates an overview of the system for detecting partial discharges.

### TERMINOLOGY

Partial discharge: is a phenomenon in which a small region within an insulating medium tends to suffer electrical breakdown at a lower system voltage than the majority of the insulation. This causes a small amount of accumulated electrical charge polarization to collapse (discharge), resulting in short current spikes and voltage steps. Because the discharge only partially bridges the insulation, it is called partial discharge.

Coincidence: Coincidence in the context of this document is a measure of the degree to which two or more signals coincide in time and have an expected balance of amplitudes. A coincidence filter, at the least, outputs a signal related to the instantaneous presence of two or more signals. Some coincidence filters ensure that the overlap of signals occurs for a minimum time duration while others ensure that the amplitudes of the signals have an expected balance with one another versus frequency.

Recurrence: A signal is said to recur if it repeats in a discernible pattern. In DC partial discharge or within a short span of time in any PD, a single defect may break down (discharge) in a recurrent pattern. See also synchronicity.

Synchronicity: In AC PD, a defect tends to discharge at the same phase in a 2 phase relationship. Such recurring PDs are said to have synchronicity. In some applications it is desirable to only report synchronously recurring PDs as they have a high likelihood of being related to meaningful insulation defects.

### REFERENCE NUMERALS

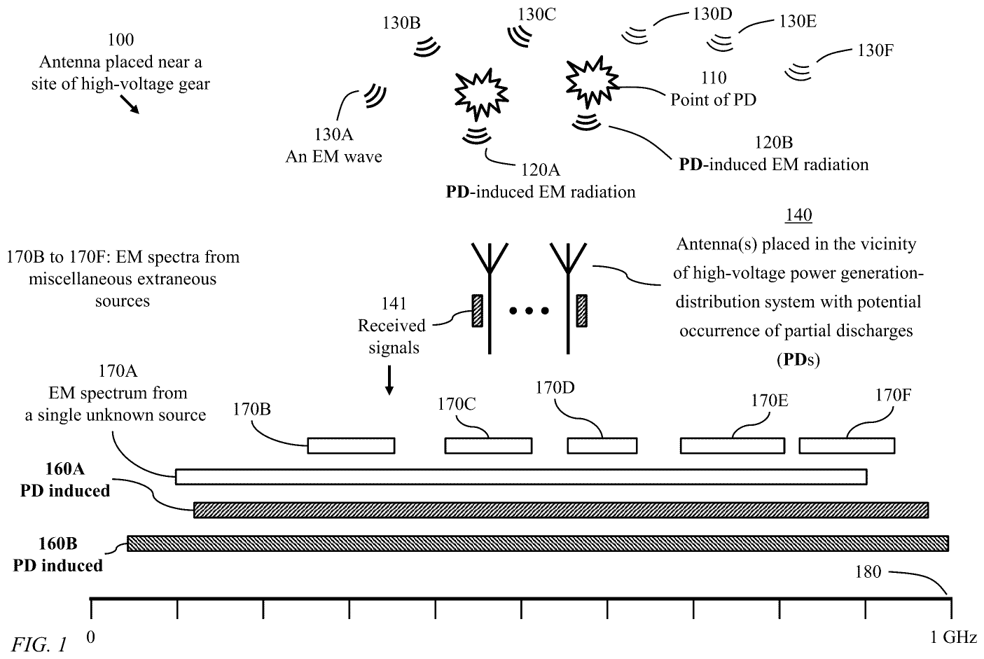

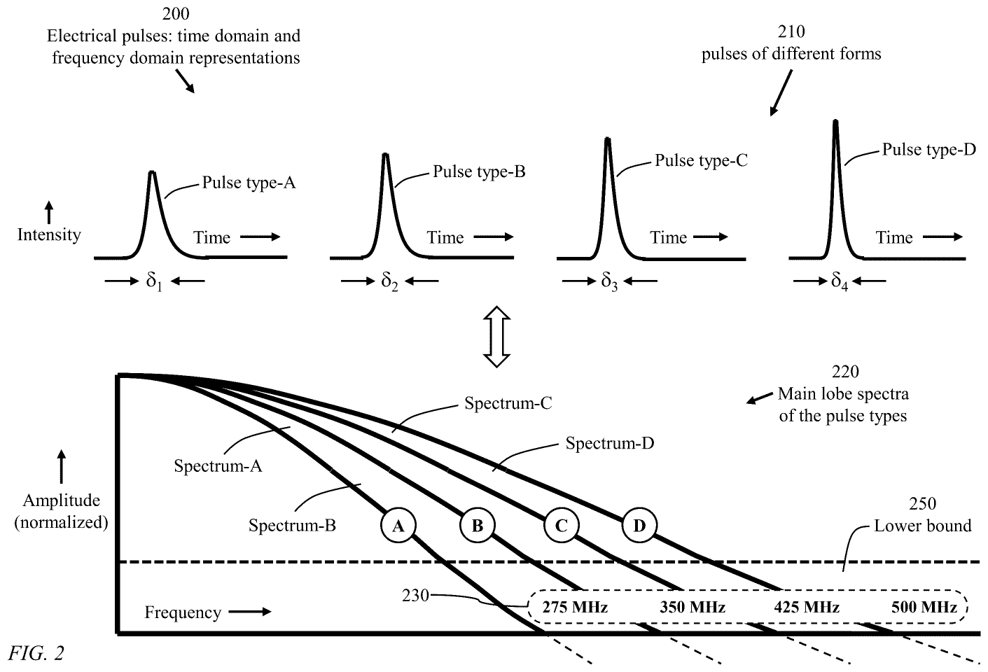

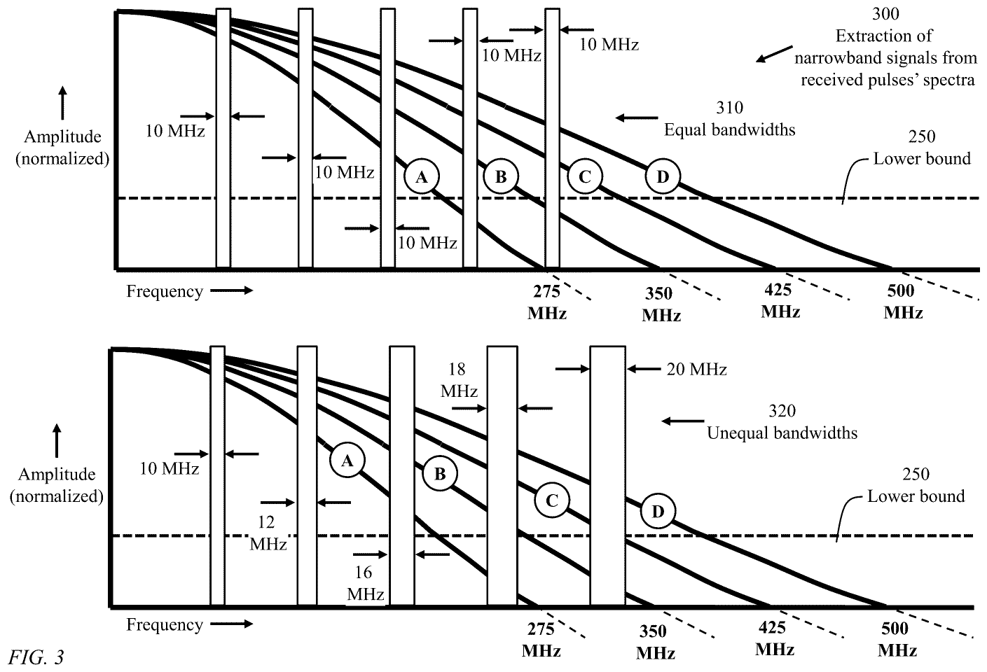

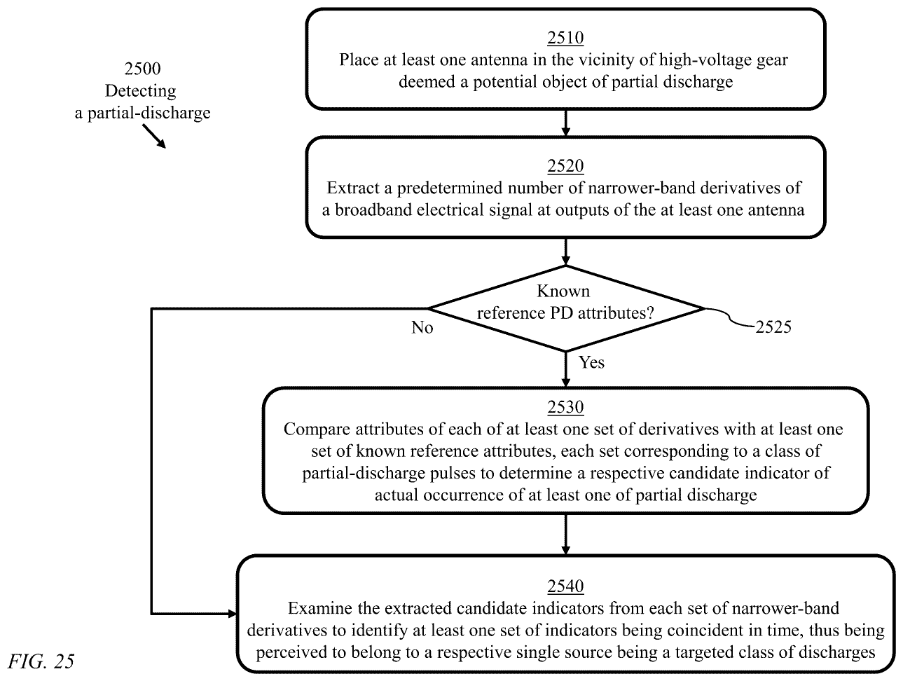

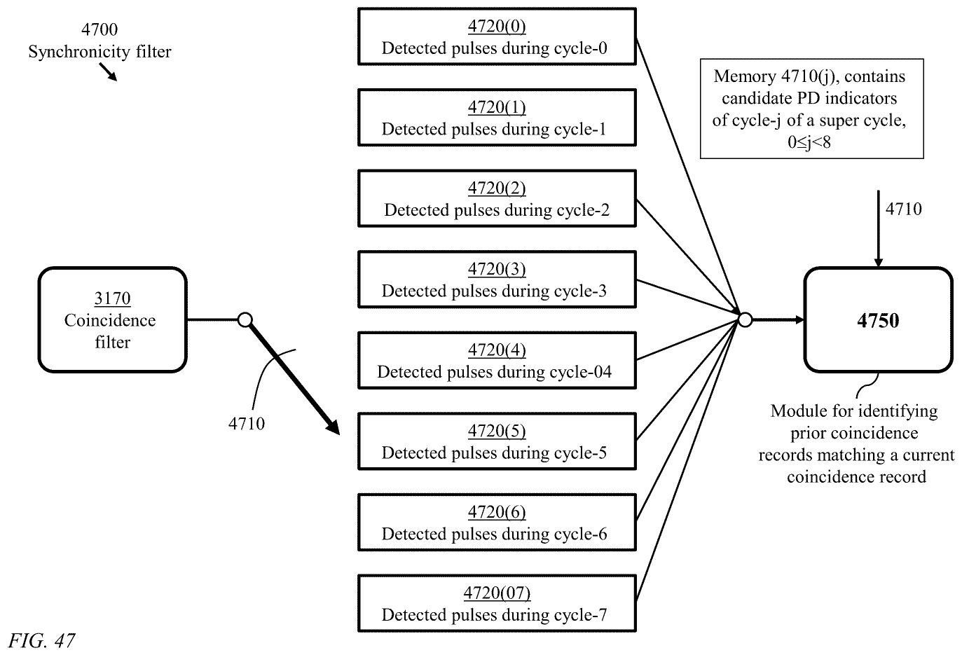

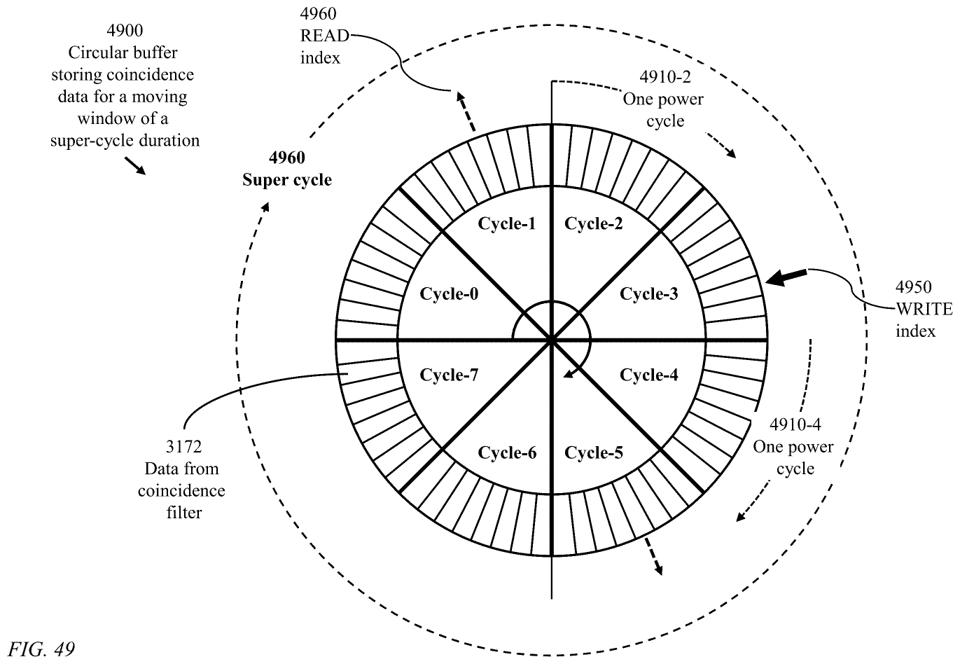

100: Antennas receiving electromagnetic waves (EM waves) including partial-discharge (PD) pulses and extraneous signals
110: Exemplary points of PD pulses 110A, 110B, . . .
120: Radiated EM waves due to the PDs
130: Miscellaneous extraneous EM waves from transmitters, such as 130A to 130F
140: A number of antennas used for detecting EM waves for detecting potential occurrence of PDs, the antennas unavoidable also receive the extraneous signals
141: Electric signals at output of an antenna 140
160: Spectra of PD pulses, such as 160A and 160B
170: Spectra of the extraneous EM waves, such as 170A to 170F
180: Expected maximum bandwidth of combined EM waves received at the antenna
200: Time domain and frequency domain representations of exemplary PD pulses
210: Time-domain representation
220: Frequency-domain representation of the exemplary PD pulses, illustrating only significant portions of the spectra and omitting any extraneous signals despite their presence
230: Exemplary frequency bounds of the main lobes of the spectral of the Illustrated PD pulses
250: A lower bound of amplitudes of frequency spectrum considered to be significant
300: Extraction of a predefined number (five in the illustrated example) of narrowband signals from the spectrum received at each antenna, only the spectra of the illustrated PD pulses are illustrated, the narrowband signals are used for ascertaining presence, or otherwise, of PD pulses
310: A first option of extracting narrowband signals of equal bandwidth (10 MHz each) at selected reference frequencies (75, 125, 175, 225, and 275 MHz in the illustrated example).
320: A second option of extracting narrowband signals at selected reference frequencies (75, 126, 189, 249, 320 MHz) of bandwidths that depend on the selected frequencies (10, 12, 16, 18, and 20 MHz in the illustrated example)
400: Passband extraction, option 310 (FIG. 3)
410: Sources of PD pulses in addition to extraneous signals as illustrated in FIG. 1
420: Bandpass filters, individually identified as 420-1 to 420-χ, χ=5 in the example, of 10 MHz bandwidth each at the reference frequencies of option 310
440: Logarithmic detectors (log detectors), individually identified as 440-1 to 440-χ, χ=5, of extracted narrowband signals, of 10 MHz bandwidth each, at the reference frequencies of option 310
450: Pulse width (time duration) at outputs of individual log detectors
460: Requisite fine-sampling rates of outputs of the log detectors; the sampling rate should exceed the indicated rates to enable pulse detection and classification
470: Indication of detectability of output pulses of the log detectors corresponding to the exemplary PD pulses, labeled A, B, c, and D, of FIG. 2
500: Passband extraction, option 320
520: Bandpass filters, individually identified as 520-1 to 520-χ, χ=5 in the example, of bandwidths 10, 12, 16, 18, and 20 MHz, respectively corresponding to reference frequencies 75, 126, 189m 249, and 320 MHz of option 320 (FIG. 3)
540: Logarithmic detectors (log detectors), individually identified as 540-1 to 540-χ, χ=5, of extracted narrowband signals, of bandwidths 10, 12, 16, 18, and 20 MHz at the reference frequencies of option 320
550: Pulse width (time duration) at outputs of individual log detectors
560: Requisite fine-sampling rates of outputs of the log detectors; the sampling rate should exceed the indicated rates to enable pulse detection and classification
570: Indication of detectability of output pulses of the log detectors corresponding to the exemplary PD pulses, labeled A, B, c, and D, of FIG. 2
600: Sampling output signals of a single log detectors following a bandpass filter of a passband of Ω
610: Case of an unknown phase of high-voltage cycle at a source of PD
620: Case of a known phase of high-voltage cycle at a source of PD
630: Band-filtered signal of bandwidth Ω
640: log-detector output comprising detected pulses (corresponding to PDs, if any) plus filtered extraneous signals
650: Time-window sampler (coarse sampler) of log-detector output 640
655: Output of time-window sampler containing signals during relevant time windows only
670: a fine sampler sampling at a rate judicially exceeding the Nyquist-Shannon rate of 2Ω
680: A conventional A/D convertor
700: An example of cyclical synchronously recurring PDs in a single-phase high-voltage power generation or distribution system
711: A PD occurring near the peak of a sinusoidal waveform at high-voltage equipment
712: A PD occurring near the trough of a sinusoidal waveform at high-voltage equipment
800: Conventional three-phase voltages at points of generation and distribution
810: A first phase voltage, labeled phase-A voltage
820: A second phase voltage, labeled phase-B voltage
830: A third-phase voltage, labeled phase-C voltage
840: Inter-phase voltage A-B
850: Inter-phase voltage B-C
860: Inter-phase voltage C-A
900: Cross-section of an underground three-phase high-voltage cable
905: A cable connected to ground
910: A conductor for carrying phase-A current
920: A conductor for carrying phase-B current
930: A conductor for carrying phase-C current
940: Intra-phase insulation
950: Inter-phase insulation
950: Metallic sheath connected to ground
1000: Paths of potential partial discharge at end points of a high-voltage three-phase underground cable
1010: Phase-A cycle
1020: Phase-B cycle
1030: Phase-C cycle
1100: Paths of potential partial discharge at end points of a high-voltage three-phase underground cable
1120: Phase insulator (1120A, 1120B, 1120C fore phases A, B, and C, respectively)
1200: Local-outlet phase versus possible corresponding high-voltage phase
1210: High-voltage phase-A cycle
1220: High-voltage phase-B cycle
1230: High-voltage phase-C cycle
1240: Local-outlet cycle
1300: Potential intra-phase partial discharges (PDs) in one cycle (20 milliseconds or 50/3 milliseconds)
1321: PD near peak value of phase voltage (1321A, 1321B, 1321C, for phases A, B, C)
1322: PD near trough value of phase voltage (1322A, 1322B, 1322C, for phases A, B, C)
1400: Potential intra-phase PDs in one cycle (continued)
1460: PD through an insulator of a single phase (1460A, 1460B, 1460C for phases A, B, C)
1500: Potential inter-phase partial discharges (PDs) in one cycle (20 milliseconds or 50/3 milliseconds)
1521: PD near peak value of inter-phase voltage (1521AB, 1521BC, 1521CA, for inter phases A-B, B-C, C-A)
1522: PD near trough value of inter-phase voltage (1522AB, 1522BC, 1522CA, for inter phases A-B, B-C, C-A)
1600: Potential inter-phase partial discharges (PDs) in one cycle (continued)
1660: PD through an inter-phase insulator (1660A, 1660B, 1660C for inter-phases A-B, B-C, C-A)
1700: Combined potential intra-phase and inter-phase partial discharges (PDs) in one cycle (20 milliseconds or 50/3 milliseconds
1800: Combined potential intra-phase and inter-phase PDs (continued)
1900: Time-window sampling (coarse sampling) to precede fine sampling targeting only potential intra-phase PDs
1925: Sampling time-windows targeting intra-phase PDs
1960: PDs through intra-phase insulators
2000: Time-window sampling (coarse sampling) to precede fine sampling targeting only potential inter-phase PDs
2025: Sampling time-windows targeting inter-phase PDs
2060: PDs through inter-phase insulators
2100: Isolating sources of Intra-phase PDs
2150: Potential PDs occurring at the intra-phase insulators
2160: Potential PDs occurring at an insulator of a specific phase (2160A, 2160B, 2160C at phases A, B, and, respectively)
2200: Isolating sources of Inter-phase PDs
2250: Potential PDs occurring at the inter-phase insulators
2260: Potential PDs occurring at an insulator of a specific pair of phases (2250C-A, 2260A-B, 2160B-C)
2300: Sorting detected-signal data into time bins for a case of known absence of inter-phase PDs
2350: Time bins
2400: Sorting detected-signal data into time bins 2350 for a case of potential intra-phase and inter-phase PDs
2500: Overview of a method of detecting partial charge
2510: Process-I of using at least one antenna to receive potential radiated PD electromagnetic (EM) signals and unavoidable other extraneous EM signals
2520: Process-II of extracting narrow band signals from the electric output signal(s) of the antenna(s) in order to facilitate distinguishing PD signals from background extraneous signals
2525: Branching point
2530: Process of comparing shapes of output pulses of the log detectors with known reference shapes
2540: Process-III of determining a pattern of detected PD signals, if any, within each electric-power cycle of a superset of a predetermined number Π, Π>1, of successive electric-power cycles (of 20 milliseconds or 50/3 milliseconds)
2600: A synchronicity filter confirming synchronous recurrence of detected PDs in multiple power cycles
2630: Process-IV of determining a count of presence of the pattern of detected PDF signals in prior II power cycles as confirmation of PD detection
2700: An example of output of process 2640
2800: A step of process-II of selecting a set of narrower bands from an envisaged broadband of PD EM spectrum, extracting respective narrowband signals from the electrical output signals of the antennas, and using logarithmic detectors (log detectors) to produce wider-duration pulses from each narrow-band signal to be used for ascertaining and classification of a received PDF EM wave, if any
2810: A single sharp PD pulse which may be one of many received at each antenna 140
2820: band-pass filters
2830: Log detectors
2840: Transport medium to a processing hub
2850: Pulse shapes determined at the log detectors
2900: An option of using more receivers than intended for process-II (FIG. 25) and selecting receiver outputs based on reception quality
2930: A low-noise amplifier
2940: A band-selection switch (including a comparator, not illustrated)
2950: An electrical signal of a specified pass band
3000: An overview of a PD detection system
3020: A set of log detectors (part of a set of analog receivers)
3040: Master clock (phase-locked to power cycle)
3050: A processing hub for processing outputs of the log detectors
3090: Indication of detected PDs
3100: Basic components of the processing hub 3050
3120: A set of samplers and A/D convertors
3140: Data from A/D convertors
3170: A coincidence filter
3172: Magnitudes of potential PDs, if any
3175: A circular buffer (also referenced as a circular memory) implemented using multiple memory devices (FIG. 47) or a shared memory device (FIG. 49)
3180: A synchronicity filter
3200: A shape comparison arrangement for a single PD class
3210: Pulse shape data from outputs of A/D convertors
3260: A shape comparator
3270: Reference pulse shapes
3280: Shape similarity indicators
3288: Paths to shape-comparator 3260
3300: PD-class-specific augmented coincidence detection
3320: Augmented coincidence filter
3325: A set 3325 of pulse-shape signatures
3365: A set of χ binary class-k similarity indicators
3370: coincidence correlator
3380: PD-class-specific coincidence indicator giving magnitude of possible PD for either a class or a raw data signal
3400: Augmented coincidence detection with detail for each class for multiple PD classes
3500: Generic representation of augmented coincidence detector (augmented: using pulse shapes)
3520: A set of K shape-comparators (K being a number of OD classes)
3530: A set of K coincidence correlators
3580: Class-specific coincidence indicators
3600: Processing-Hub basic hardware components
3610: Interface with χ analog receivers
3620: Software module implementing the coincidence filtering
3630: Software module implementing the synchronicity filtering
3640: Input buffers of output data of the A/D convertors
3650: Memory holding reference pulse-shape signatures
3660: Memory holding data of detected pulses, within χ bands, during a single power cycle
3670: Circular buffer holding coincidence data for a moving super cycle
3680: Memory storing results of PDs detected during a moving monitoring period
3690: A processor (or an assembly of processors)
3700: Confirming PD detection, if any
3800: Generating reference band-specific PD-pulse shapes
3900: Exemplary output of individual channels 1 to χ, χ=4
3910: Band-specific significant pulses considered to belong to one PD
3920: Band-specific significant pulses considered to belong to another PD
3930: One power cycle (20 milliseconds or 50/3 milliseconds)
3940: A band-specific pulse considered to belong to extraneous signals
3950: Pulses possibly related to PDs from distant sources
3980: Buffers each holding data identifying respective significant band-specific pulses
4000: Exemplary output of individual channels (continued from 3900)
4100: Relating incidence of PDs to a power cycle at a high-voltage generation or distribution facility; the phase difference between the high-voltage sinusoidal wave form and an accessible stepped-down low-voltage sinusoidal waveform, derived from the high-voltage source, is negligible
4110: Power cycle at the high-voltage level
4120: An accessible low-voltage sinusoidal waveform derived from the high-voltage source
4200: Relating incidence of PDs to a power cycle at a high-voltage generation or distribution facility; the phase difference between the high-voltage sinusoidal wave form and an accessible stepped-down low-voltage sinusoidal waveform, derived from the high-voltage source, 2π/3 radians
4300: Relating incidence of PDs to a power cycle at a high-voltage generation or distribution facility; the phase difference between the high-voltage sinusoidal wave form and an accessible stepped-down low-voltage sinusoidal waveform, derived from the high-voltage source, 4π/3 radians
4400: Arrangement for use of fine sampling of the output signals of the log detectors to establish coincidence, or otherwise, of detected pulses from the output samples
4410: Band-specific samples
4430: A moving, monitoring period equal to or longer than an expected PD pulse
4435: A time bin of duration longer than a typical PD but shorter than a desired ability to resolve individual PDs and, in some embodiments, equal to 4430.
4440: A number β of time-bins 4435 each for holding results of coincidence indication of a respective monitoring period
4500: process of determining temporal coincidence of pulses detected from the band-specific samples
4520: Detected band-specific pulses
4525: Temporal intersection of χ band-specific pulses
4600: An overview of an arrangement for determining coincidence of χ band-specific pulses
4610: Buffers
4620: An electronic circuit or software instructions for comparison of band-specific samples
4630: a buffer holding coincidence indications 4640 for a single monitoring period
4640: Coincidence filtered peak amplitude in a single monitoring period
4650: Cyclical updating of bins contents during successive cyclical monitoring periods
4660: Coincidence data including 4640 determined during cyclical monitoring period of index J, 0≤J≤β
4700: Synchronicity filter determining occurrence of detected pulses during a current power-cycle validated by those in a preceding moving super cycle of a number Π of power-cycles (20 or 50/3 milliseconds each)
4710: Detected power-cycle-specific pulses
4720: The magnitude of the largest individual detected pulse in each of β time intervals in ach of Π prior power cycles
4750: A module for identifying prior coincidence records equal to or exceeding a current coincidence record and outputting a value determined by a required number of prior values being greater to or equal to the current value in a given time interval of the record.
4800: Exemplary candidate PD magnitudes within a super cycle of power cycles (20 or 50/3 milliseconds each)
4805: A set of Π separate memory devices accessed sequentially in a circular mode or Π memory division in a shared single memory operated in a circular-storage mode
4820: A validated detected pulse being present in 7 out of eight (Π=8) cycles of a super cycle
4830: A validated detected pulse being present in 6 out of eight (Π=8) cycles of a super cycle
4850: Detected pulses (4850A to 4850G) which, being sporadic, appear to be generated at sources other than PD sources
4900: A memory device operated in a circular storage mode for holding validated PD-related pulse for each cycle of the Πcycles of a moving super cycle
4910: Coincidence data stored during a power cycle (20 or 50/3 milliseconds)
4950: A WRITE index of memory address for overwriting current data relevant to a current cycle period after comparing the current data with Π individual cycle-specific data of the super cycle
4960: Rotating READ index
5000: An arrangement for temporal coordination of the processes of coincidence filter 3170 for determining coincidence of detected pulses, in each of χ band-specific data streams per power-cycle duration, and synchronous recurrence determination 4720
5050: A controller employing at least one hardware processor
5100: An alternative 5100 to digital coincidence filtering
5110: RF pulses
5120: Bandpass filters
5125: Envelope detectors
5130: An adder
5150: Further-processing of sum of detected envelopes
5160: An optional log detector
5165: A lower bound of a valid pulse
5175: Intersection time interval
5200: Processing of the output of the analog coincidence filter in a simplified processing hub
5300: Process of identifying source(s) of PD occurrence
5310: A process of generating time windows within a power cycle of the high-voltage source corresponding to intra-phase and inter-phase voltage peaks and troughs
5320: A process of window sampling of outputs of log detectors after fine sampling
5400: A method of locating a source of a detected PD
5500: A memory arrangement for creating an image for visualization of partial discharge
5510: Discretized time or phase during a power cycle
5520: Discretized amplitude
5600: An alternate system for PD detection employing a coincidence filter, a synchronicity filter, and a single historical buffer
5610: A coincidence filter
5620: A historical buffer
5641: A synchronicity filter
5642: A display pixel
5643: An averaging factor “F”, 0<F<1.0
5700: Alternate method for detecting PDs
5800: A cloud plot illustrating a partial discharge and a gray-scale bitmap
5900: Non-overlapping observation windows
6000: Overlapping observation window
6100: Dual observation window
6200: A table relating ranges of time instants to identifiers of dual observation windows

### DETAILED DESCRIPTION

The present invention discloses a method and system of detecting and identifying partial discharge which overcomes issues with prior art methods. The present invention uses a plurality of narrowband filters, each selected to occupy a frequency band with a low probability of intentional external radio interference and each selected to have a bandwidth offering a sufficiently low thermal noise floor but wide enough to offer pulse resolution at tens of nanoseconds. While prior art does have examples of a plurality of filtered bands, the bands used were quite wide, making them prone to external transmitter interference, and they were measured one at a time, making it difficult to ensure that the signals coincide. The present invention measures at least two bands simultaneously and verifies a correlation with a required level of signal balance between the two bands to validate a partial discharge source for the radio signals in a so-called coincidence filter.

Each receiver channel has at least one antenna connection and one filter, an optional low noise amplifier (LNA) and a log envelope detector. A design approach of this aspect of the invention is to (a) select a log envelope detector with sufficient dynamic range (for example, −60 dBm to 0 dBm), (b) select an LNA of sufficiently high gain (for example, at least 10 dB and preferably at least 25 dB) and sufficiently low noise floor (e.g <2 dB noise figure) such that the noise performance of the log detector when fed by the LNA is determined primarily by the loss and bandwidth of the filter between the receiver antenna and the LNA. The filter bandwidth and loss are selected so that the receiver thermal noise floor (in dBm) is less than the sensitivity floor of the amplifier and detector (e.g. −60 dBm-10 dB gain is −70 dBm sensitivity). A SAW filter with a bandwidth of tens of MHz and a loss of 2-3 dB feeding an LNA with a noise figure of 1˜2 dB can have a thermal noise floor of <−90 dBm, well below the sensitivity of amplifier and detector. The LNA gain can be increased to take advantage of the lower noise floor, or the filter bandwidth can be increased until the noise floor approaches the sensitivity.

The inverse of the filter bandwidth determines the pulse resolution. Partial discharge can have nanosecond or shorter rise times and extremely broad bandwidth. An excessively narrow filter bandwidth, e.g. 1 MHz, will only receive a small fraction of a GHz bandwidth signal and will have an impulse response on the order of 1 microsecond. SAW filters with 10-100 MHz bandwidth offer 100 ns to 10 ns pulse widths and yield favorable trade offs of resolving PD pulses while avoiding nearby transmitter frequencies and also allow moderate cost analog to digital converter (ADC) selection.

For a fixed energy, band-limited transmitter, increasing the gain and having the filter bandwidth match the spectrum of the transmitter favors higher gain and the narrowest possible bandwidth that is wider than the transmission spectrum. For partial discharge, the transmitted signal from the discharge and the thermal noise both have wide spectral distribution and the signal to noise ratio is almost independent of bandwidth. Therefore, the bandwidth may be chosen as any convenient bandwidth that avoids know interference signals while offering a suitable degree of time domain resolution. Generally, this leads to using relatively narrow bandwidths to find clear spectrum and relatively high gain LNAs. These will lose information on the true pulse shape but will still allow individual PD events to be observed in most cases.

A subset of at least two of the plurality of detectors are simultaneously measured. In the most preferred embodiment, a log envelope detector obtains a dB reading that is optionally linearized to mV or other linear signal amplitude units after being converted from analog data to digital data. This offers the high dynamic range of the log envelope detector, necessary for high sensitivity to small signals, and computationally allows the linearity of linear envelope detectors that is necessary to many signal processing algorithms requiring quantitative accuracy. Linear envelope detectors may be used with a sufficient bit depth of the analog to digital converter (ADC), but fast, high resolution ADCs are prohibitively expensive in most applications.

In other embodiments, the signal is retained in logarithmic representation and the linear addition of signals is performed by counting discharge events in predetermined amplitude intervals of the logarithmic units and then totalling the products of the counts and nominal linear value of each amplitude range.

In some embodiments, the digitized waveform of each channel is correlated against the expected waveform of a typical PD pulse that is passed through that channel's filter. The output of the correlation is a detection signal indicating the degree to which the measured waveform matches the expected waveform of a PD and the time at which the match best occurred.

In a subset of these embodiments, the digitized waveform of each receiver channel is correlated against a plurality of expected waveforms, providing a plurality of detection signals indicating the degree to which the waveform matches a plurality of classifications of partial discharge.

In some embodiments, the signals are discriminated first by a coincidence filter, which filters based on whether the signal is broad band such that similar signal levels coincide in different frequency bands at similar amplitudes, and then by a synchronicity filter, which filters based on whether the signal is synchronized with the power line frequency at a stable phase/voltage with a sufficiently high repetition rate. In an exemplary system, two baseband signals derived from different passband filters are converted from analog signals to digital data, optionally digitally filtered and optionally shape-correlated, then processed through a coincidence filter and then a synchronicity filter to create a validated partial discharge result. The figure shows two inputs, but the number of signals is not limited to two. The coincidence filter outputs time signals that are validated surrogates of the input signals, emphasizing the amplitudes of pulses with spectral energy in a majority of the filter bands, for example both bands for the two-band example shown, and de-emphasizing those with energy in a minority of the filter bands.

The digitized signal from a high band and a low band analog receiver and analog-to-digital converters (ADCs) may be processed with optional pulse shape correlation filters being optionally used for detecting a signature corresponding to one or more specific PD signatures. The pulse shape elements may optionally be vectorized with a plurality of pulse shapes corresponding to a plurality of partial discharge signatures. The digitized and optionally pulse-shaped signals, still representing analog waveforms of the input pulses, are compared between the at least two input elements in a coincidence filter. The output of the coincidence filter is a scalar in some embodiments and a vector in embodiments employing classification schemes based on pulse shape or frequency content and is a digital discrete time signal representing the recombined signals of the various bandpass filters. The filtered result analyzed for discrete PD events, which are then compared to trailing power cycles stored in memory in a synchronicity filter to only report pulse events with magnitudes that are synchronously recurring over past cycles, synchronous in phase.

The invention may be practised with more than two signal channels. The coincidence filter emphasizes signals that are sufficiently wide band, having energy in multiple selected frequency bands, while the synchronicity filter emphasizes only those wide-band signals that are repetitively coherent with the power frequency at a stable phase of the power cycle. The result is a validated PD. Optional peak detectors may be desirable after ADC, after pulse shape correlation filters, after the coincidence filter, and after the synchronicity filter. It is also possible to reverse the order of the synchronicity filter with the coincidence filter, requiring a synchronicity filter and phase memory for each input channel.

The coincidence filter can use cross-correlations of the signals for mathematical simplicity or may use other logic in more procedural and non-linear analysis. The coincidence filter tests that signals in different filtered portions of the spectrum coincide in time with one another. The degree to which the signals coincide in time and the degree to which they have approximately equal signal strength can be used to discriminate local partial discharge (broader bandwidth and sharper pulse) from discharges that travel a long distance on a power line (with frequency dependent attenuation and time delay). The latter tend to be low pass filtered and suffer time dispersion such that the different frequencies see different delay times and losses along the cable. An opposite effect occurs in narrow bus ducts, which act as waveguides with a cutoff frequency. Adjusting the selectivity of the coincidence filter allows non-localized partial discharge to be discriminated or observed by adjusting filter parameters.

FIG. 1 illustrates an example 100 of sources of partial discharge and a set of broadband antennas receiving electromagnetic waves (EM waves) including partial-discharge (PD) pulses and extraneous signals. Exemplary two points 110A and 110B of partial discharge, generating EM PD pulses 120A and 120B, are illustrated. Extraneous EM waves 130A, 130B, 130C, 130D, 130E, and 130F from miscellaneous transmitters (not illustrated) are present.

In order to detect potential occurrence of PDs, one or more antennas 140 are used for detecting potential PD pulses. The antennas also, unavoidably, receive the extraneous signals. The rationale for employing multiple antennas will be described below. The electric signals 141 at output of the antennas 140 are processed differently.

The figure illustrates spectra 160 of the PD induced EM signals, such as 160A and 169B of signals 120A and 120B, respectively as well as spectra 170, such as 170A to 170F of extraneous signals 130 to 130F, respectively. In the illustrated example, the expected maximum frequency-band-occupancy of combined PD signals is well past 1 gigahertz (1 GHz).

FIG. 2 illustrates time domain 210 and normalized frequency domain 220 representations 100 of four exemplary pulses of four pulse classes. In the time-domain, the pulses may have different intensities and durations. The indicated durations 81, 82, 83, and 84 may be defined in terms of equivalent rectangular pulses. In the frequency domain, the spectrum of each of the pulses generally takes the shapes of a function similar to a sinc function with the main lobe being the significant portion of the spectrum. Extraneous signals other than PD-like pulses are not illustrated in FIG. 2; however, their presence is also taken into consideration in the process of PD detection. “PD-like pulse” shall be used to specifically indicate a pulse that looks like PD but has not been verified to be PD. The main-lobe spectra denoted A, B, C, and D correspond to the four PD-like pulse types. As well known, the narrower the pulse, the wider the main-lobe spectrum. In a process of extracting narrower spectral bands from the received signal spectra, an amplitude lower bound 250 is set, and the selection of the spectral bands attempts to avoid parts of the spectra below the amplitude lower bound. It is noted that some classes of PD may have bandwidths of several GHz and the pulse widths and bandwidths shown are illustrative only.

For PD pulses, generally at the point of defect the physical discharge is very fast, with sub nanosecond rise times. Certain discharge classes are slower and discharges typically lose high frequency faster than low frequency energy as the current pulse propagates along the conductors from the physical defect. Radio waves are emitted wherever the current pulse exists, so the electromagnetic signature from a pulse electrically closer to the source has wider bandwidth than that of a pulse that has travelled a long distance. Radio waves in air decay as the inverse of the distance squared while losses on a line are proportional to distance. Unless the source is quite close to the antenna it is more likely that the received signal is a low pass filtered replica of the actual discharge and in some applications one can assume that pulse D is closer than C, etc. with A being the furthest. In some applications it could be assumed that D is one class (for example, insulation defect PD), that C is another class (e.g. sharp edge corona discharge), while B and A might be assumed to result from loose wire arcing, generator brush noise, and other unrelated processes.

FIG. 3 illustrates an example 300 of extraction of a predefined number (five in the illustrated example) of narrowband signals from the spectrum received at each antenna, only the spectra of the illustrated PD pulses are illustrated, the narrowband signals are used for ascertaining presence, or otherwise, of PD pulses. According to a first option, 310, narrowband signals of equal bandwidths (10 MHz each) are extracted at selected reference frequencies (75, 125, 175, 225, and 275 MHz in the illustrated example). According to a second option, 320, narrowband signals are extracted at selected reference frequencies (75, 126, 189, 249, 320 MHz in the illustrated example) with bandwidths that depend on the selected reference frequencies (10, 12, 16, 18, and 20 MHz in the illustrated example). In some embodiments a single broadband antenna may provide a signal to multiple narrowband filters. For example, a power splitter after a low noise amplifier easily distributes signals with acceptable noise performance or a ladder filter with parallel inputs can be used to demultiplex the signals without a splitter. In other embodiments, independent antennas feed each filter. The former solutions tend to have better signal efficiency but requires a larger antenna. The latter approach tends to allow smaller antennas but requires multiple antennas.

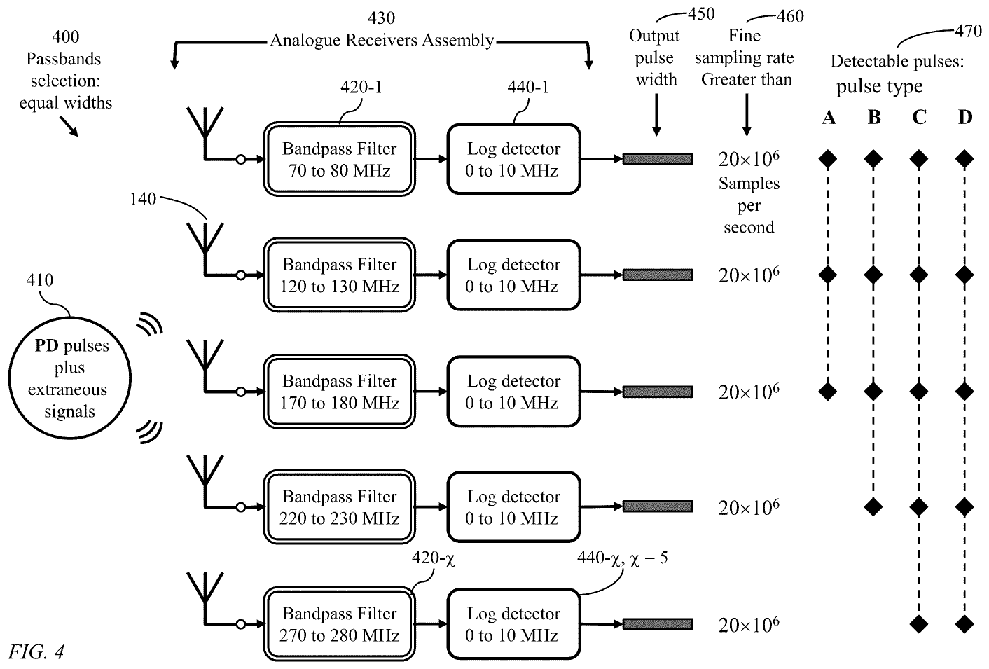

FIG. 4 illustrates pass-band extraction 400, according to option 310, FIG. 3, using an analog-receivers assembly 430 comprising five analog receivers having independent antennas 140, bandpass filters 420 of different pass bands but equal bandwidths of 10 MHz each, and identical logarithmic detectors 440. The pass bands are (70-80), 120-130), (170-180), (220-230), and (270-280). The passbands are selected according to expected spectra of received PD-like pulses at the antennas 140. The antennas receive EM waves from sources 410 which include potential PD-like sources in addition to extraneous signal sources as illustrated in FIG. 1.

The Bandpass filters 420 are individually identified as 420-1 to 420-χ, χ=5. The logarithmic detectors 440 are individually identified as 440-1 to 440-χ, χ=5, each processing extracted narrowband signals, of 10 MHz bandwidth each, at the reference frequencies of option 310.

The pulse widths (time duration) 450 at outputs of individual log detectors 440 depend on corresponding bandwidths of the bandpass filters 420 and the response time constants of the log detectors 440. They are approximately equal since the bandwidths are equal at 10 MHz each and the log detectors are assumed to be identical.

The requisite fine-sampling rates 460 of outputs of the log detectors depend on the bandwidths of corresponding bandpass filters 420 and the response time constants of the log detectors 440. The indicated sampling rates are double corresponding bandwidths of the bandpass filters 420. The fine sampling rate should exceed the indicated rates to enable pulse detection and classification. In some embodiments the sampling rate may be lower than twice the bandwidth since the log detector output is unipolar, and it is not necessary to rule out zero crossings between samples. In practice this leads to amplitude jitter that might be difficult to overcome in later signal processing.

The detectability 470 of output pulses of the log detectors depends on the main-lobe spectra of the PD-like pulses received at the antennas. For a pulse of type A, the significant part of the main-lobe spectrum is less than 230 MHz but exceeds 180 MHz, hence bandpass filters 420-4 and 420-5 do not reliably capture the pulse. For a pulse of type B, the significant part of the main-lobe spectrum is less than 280 MHz but exceeds 230 MHz, hence bandpass filter 420-5 does not reliably capture the pulse. For a pulse of type C or type-D, the significant part of the main-lobe spectrum exceeds 280 MHz, hence all bandpass filters 420 reliably capture the pulse. In preferred embodiments, all of the bandpass filters would be within the detectable pulse bandwidth of desired classes, allowing them to contribute to verifying that the signal was, in fact, PD. In pulse shape discrimination, it might be that wider pulses A and B are deemed to come from other processes than PD or from PD that has travelled along a cable for significant length, losing its high frequency components. While the lower bounds 250 should prevent their inclusion, FIG. 2 and FIG. 3 show all pulse types as having the same low frequency amplitude. A much higher amplitude type A pulse, e.g. from a high current loose connection, may have detectable signal strength in all five detected filter responses but can be discriminated by the balance of the filter responses.

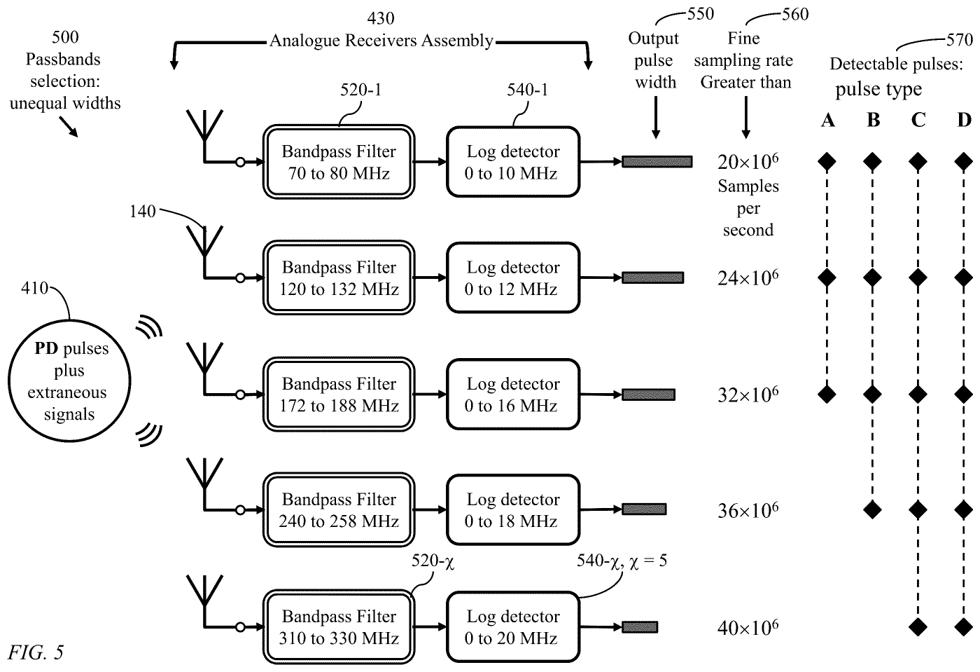

FIG. 5 illustrates pass-band extraction 500, according to option 320, FIG. 3, using an analog-receivers assembly 530 comprising five analog receivers having independent antennas 140, bandpass filters 520 of different pass bands of different bandwidths between 10 MHz and 20 MHz, and logarithmic detectors 540 processing analog signals of different bandwidths. The pass bands are (70-80), 120-132), (172-188), (240-258), and (3170-330). The passbands are selected according to expected spectra of received PD-like pulses at the antennas 140. The antennas receive EM waves from sources 410 which include potential PD-like sources in addition to extraneous signal sources as illustrated in FIG. 1.

The Bandpass filters 520 are individually identified as 520-1 to 520-χ, χ=5. The logarithmic detectors 440 are individually identified as 540-1 to 540-χ, χ=5, processing extracted narrowband signals of bandwidths 10, 12, 16, 18, and 20 MHz, respectively corresponding to reference frequencies 75, 126, 180, 249, and 320 MHz of option 320 (FIG. 3). The choice of bandwidths is a balance between detection sensitivity and interference avoidance. PD signals and thermal noise both increase as 10*log(Ω) but intentional noise should be fully filtered. The rejection of likely interfering signals limits the desired bandwidth. In practice, technical limits and commercial availability also impact bandwidth selection. In most technologies there exists an optimum filter bandwidth that is proportional to the center frequency as an ideal design is scaled.

The pulse widths (time duration) 550 at outputs of individual log detectors are inversely proportional to corresponding bandwidths of the bandpass filters 520 but also limited by the response rate of the detectors 540. Thus, assuming sufficiently fast log detectors, the pulse width at output of log detector 540-1 is double the pulse width at output of log detector 540-5.

The requisite fine-sampling rates 560 of outputs of the log detectors depend on the bandwidths of corresponding bandpass filters 520. The indicated sampling rates are double the corresponding bandwidths of the bandpass filters 520, although slower sampling can be made to work with some performance impact. The fine sampling rate should exceed the indicated rates to enable optimal pulse detection and classification.

The detectability 570 of output pulses of the log detectors depends on the main-lobe spectra of the PD-like pulses received at the antennas. For a pulse of type A, the significant part of the main-lobe spectrum is less than 230 MHz but exceeds 188 MHz, hence bandpass filters 520-4 and 520-5 do not reliably capture the pulse. For a pulse of type B, the significant part of the main-lobe spectrum is less than 280 MHz but exceeds 258 MHz, hence bandpass filter 520-5 does not reliably capture the pulse. For a pulse of type C or type-D, the significant part of the main-lobe spectrum exceeds 330 MHz, hence all bandpass filters 420 reliably capture the pulse. To practice aspects of this invention, the pulse widths of the target PD classes should provide energy in all measured bands. Bands without, for example, high frequency signal content could be deemed to not be PD or to be from a distant source that should not be reported in the asset being monitored.

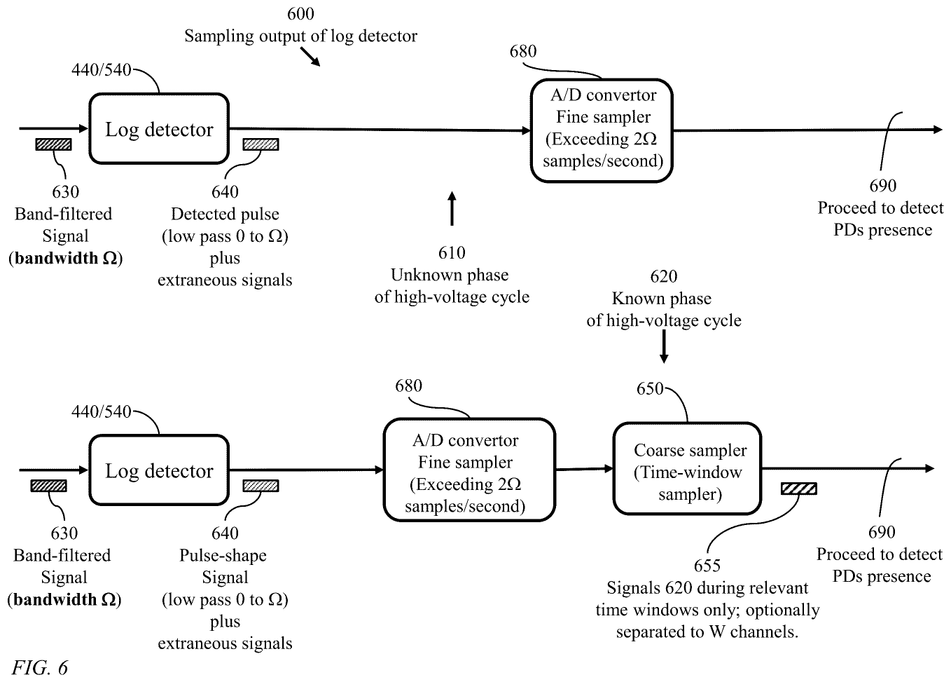

FIG. 6 illustrates a process 600 of sampling an output signal of a single log detector receiving a band-filtered signal 630 of a bandwidth Ω from a bandpass filter 420 or 520 with an option of time-window sampling (coarse sampling) following fine sampling at a sufficiently high sampling rate. While it is physically possible to gate the signal before fine sampling, there are many practical reasons not to. The fine sampling represents a transition from physical analog circuitry to the digital realm. Switching, demultiplexing, and parallel processing of digital data within an Field Programmable Gate Arrays (FPGA) or Microcontroller Unit (MCU) are easier to accomplish with lower added costs, easier to calibrate and adjust, and less susceptible to electromagnetic interference.

If at any time instant the phase of the high-voltage cycle at a source of PD is unknown (case 610), the output 640 of the log detector is digitized and digital data is supplied directly to further processing 690. Otherwise, if the phase of the high-voltage cycle is known (case 620), the output 640 of the log detector is digitized and the digital data is supplied to a coarse time-window sampler 650 which produces a time-window-sampled signal 655 to further processing 690. The log-detector output 640 may comprise detected pulses corresponding to potential PDs as well as filtered extraneous signals. In preferred embodiments, the coarse window is applied after the fine sampler in the digital domain. In the most preferred embodiments, it is performed after all signal verification steps and determines into which phase bin the data is assigned. While a single coarse filter is shown, a plurality of coarse filters may divert different phase intervals to different subsequent processing. The output 655 of time-window sampler 650 contains signals occupying relevant time windows only. The fine sampler 670 may sample at a sufficiently high sampling rate. A conventional A/D convertor 680 produces digital representation of the output of the fine sampler 670.

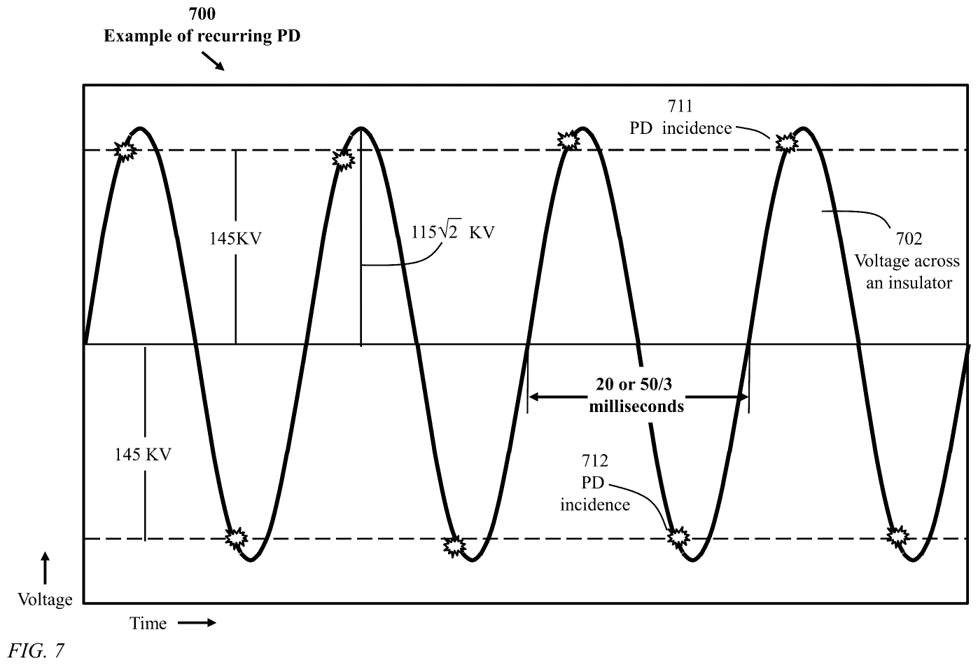

FIG. 7 illustrates an example 700 synchronously recurring PDs in a single-phase high-voltage power generation or distribution system for a case of a power supply at 115 r.m.s. Kilovolts (KVs). For each power cycle. A first PD 711 occurs near the peak (115×1.41421 KVs) of a sinusoidal waveform at high-voltage equipment. A second PD 712 occurs near the trough (−115×1.41421 KVs) of the sinusoidal waveform. In the illustrated example, the PDs 711 and 712 occur at a voltage value of 145 KV. This situation occurs when the inception voltage of the electrical equipment is just below the peak working voltage of the electrical power waveform. As the ratio of working voltage to inception voltage increases, the first discharge shifts left (earlier) in phase and additional discharges may also occur.

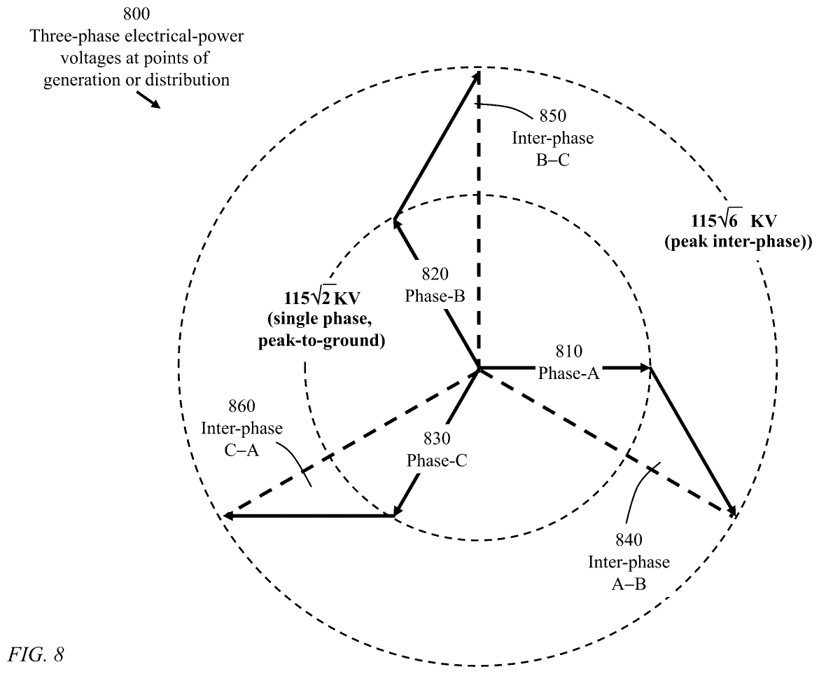

FIG. 8 illustrates conventional three-phase voltages 800 at points of generation and distribution. A first-phase voltage 810, labeled phase-A voltage, a second-phase voltage 820, labeled phase-B voltage, and a third-phase voltage 830, labeled phase-C voltage are represented as vectors of equal magnitudes (conventional stated as R.M.S. values) of reference angles 0.0, 2π/3, and 4π/3, respectively. In some arrangements, inter-phase voltages may be of interest. Inter-phase voltages A-B, 840, B-C, 850, and C-A, 860, are represented as vectors of angles −π/6, π/2, and 7π/6, respectively.

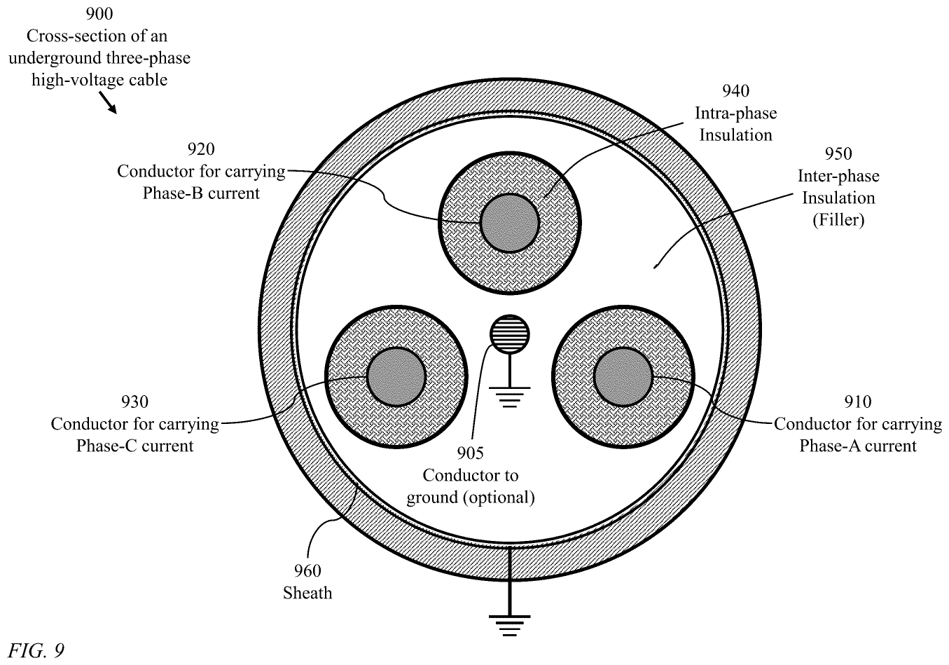

FIG. 9 illustrates a cross-section 900 of an underground three-phase high-voltage cable. Three conductors 910, 920, and 930 carry currents of phases A, B, and C, respectively. Each of conductors 910, 920, and 930 is encased in an intra-phase insulator 940. A filler 950, which is an inter-phase insulator, holds the insulated cables within a metallic sheath 960 connected to ground. An optional cable 970, connected to ground, may be provided.

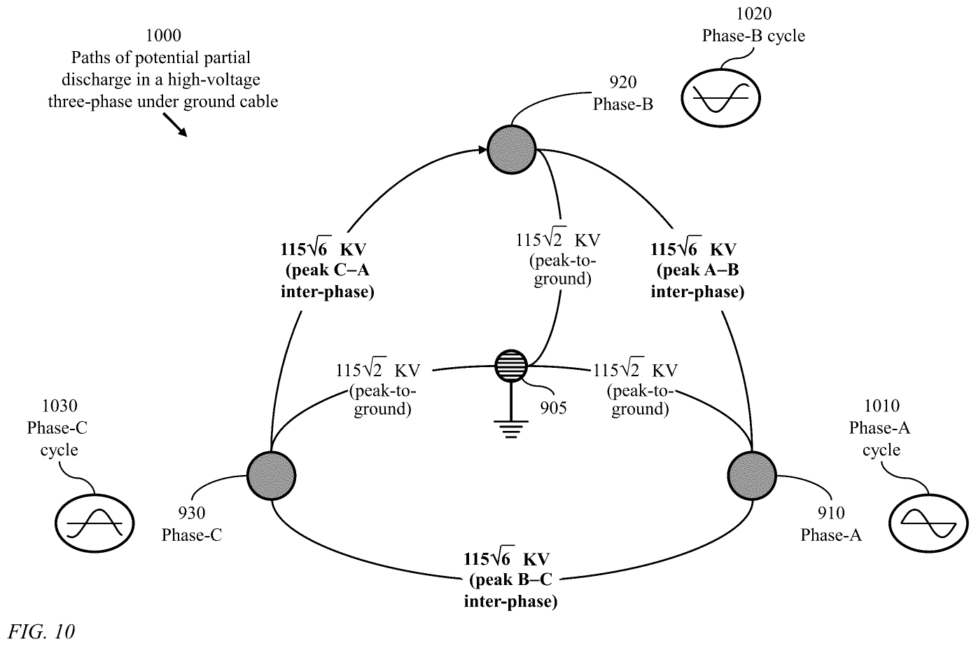

FIG. 10 illustrates paths 1000 of potential partial discharge at end points of the high-voltage three-phase underground cable of FIG. 9. Paths 1010-1, 1010-2, and 1010-3 are paths between conductors 910, 920, and 930, respectively and ground. Paths 1020-1, 1020-2, and 1020-3 are paths traversing insulators between: conductors 910 and 920; conductors 920 and 930; and conductors 930 and 910 respectively.

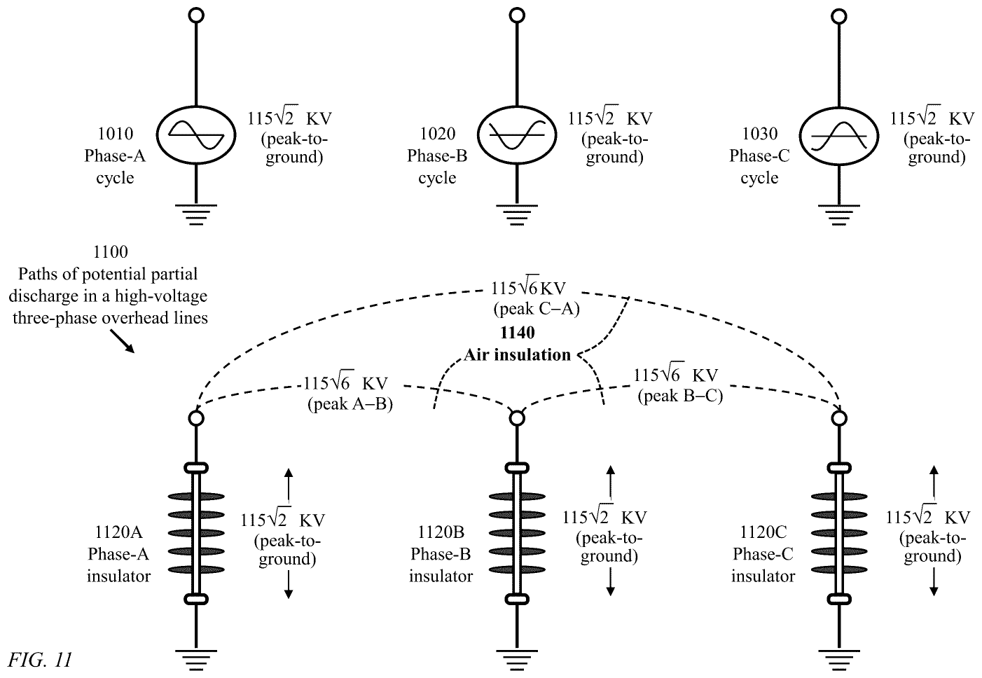

FIG. 11 illustrates paths 1100 of potential partial discharge between high-voltage three-phase overhead conductors {1110, 1120, and 1130} and ground. The sinusoidal voltage cycles of the three phases are indicated (11Paths 1140A, 1140B, and 1140C are paths traversing insulators between conductors 1110, 1120, and 1130, respectively, and ground.

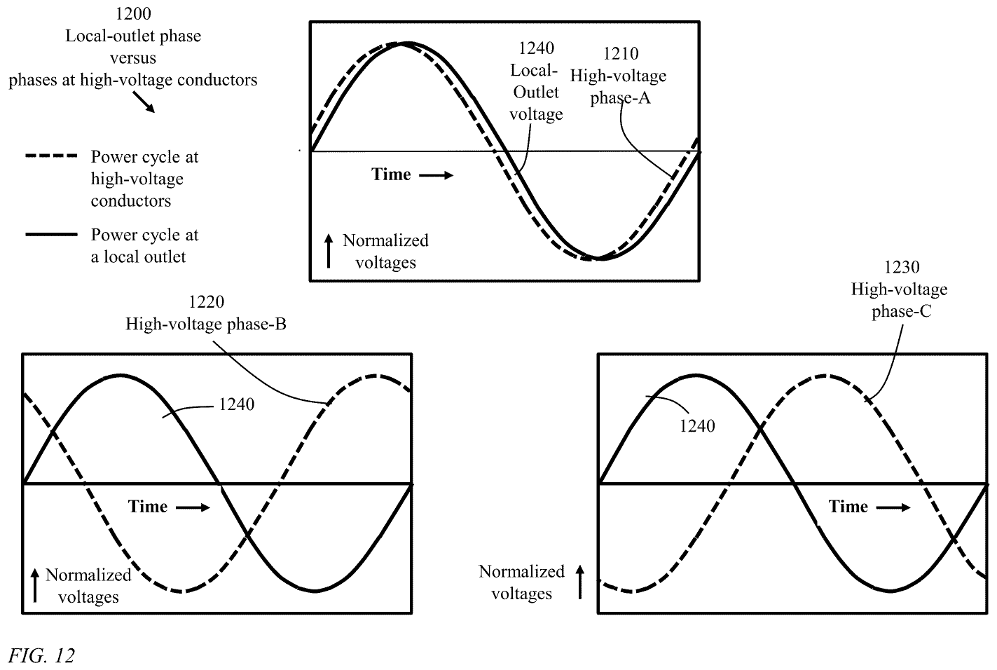

FIG. 12 illustrates an example 1200 of a local-outlet voltage cycle versus possible high-voltage cycles 1210, 1220, and 1230 of phases A, B, and C respectively.

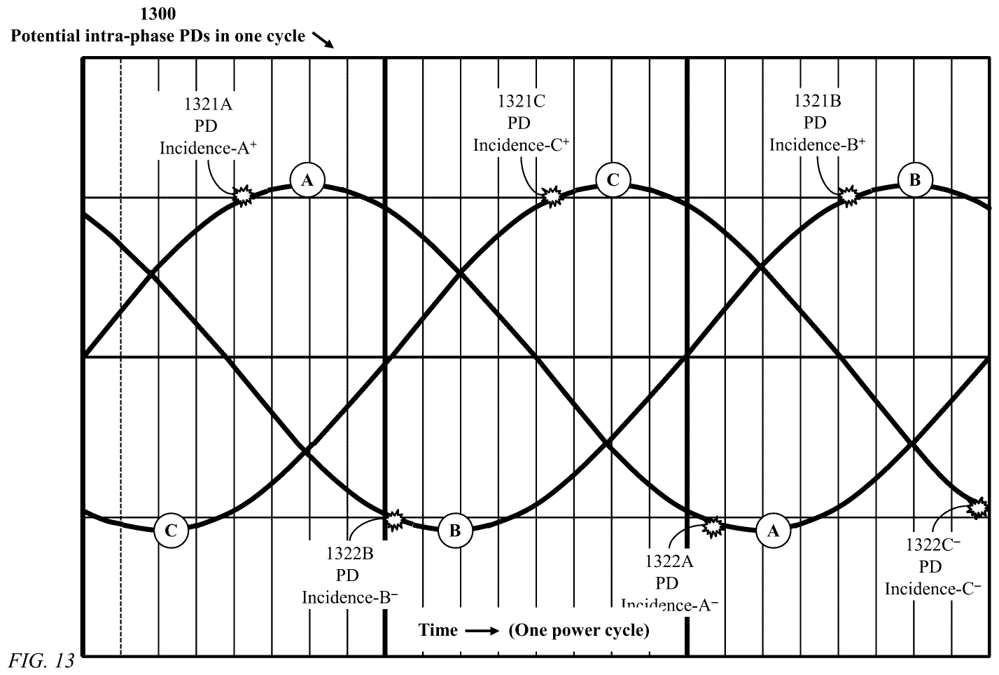

In FIG. 13 to FIG. 23, PD occurrences are indicated at all peaks (crests and troughs), but real systems may have PDs only at one or two phases. As known in the art, some PD defects are polarity sensitive.

FIG. 13 illustrates an example 1300 of potential intra-phase partial discharges (PDs) in one power cycle (20 milliseconds or 50/3 milliseconds). PD incidences 1321 occur near the peak voltage value (1321A, 1321B, 1321C, for phases A, B, C). PD incidences 1322 occur near the trough voltage values (1322A, 1322B, 1322C, for phases A, B, C respectively).

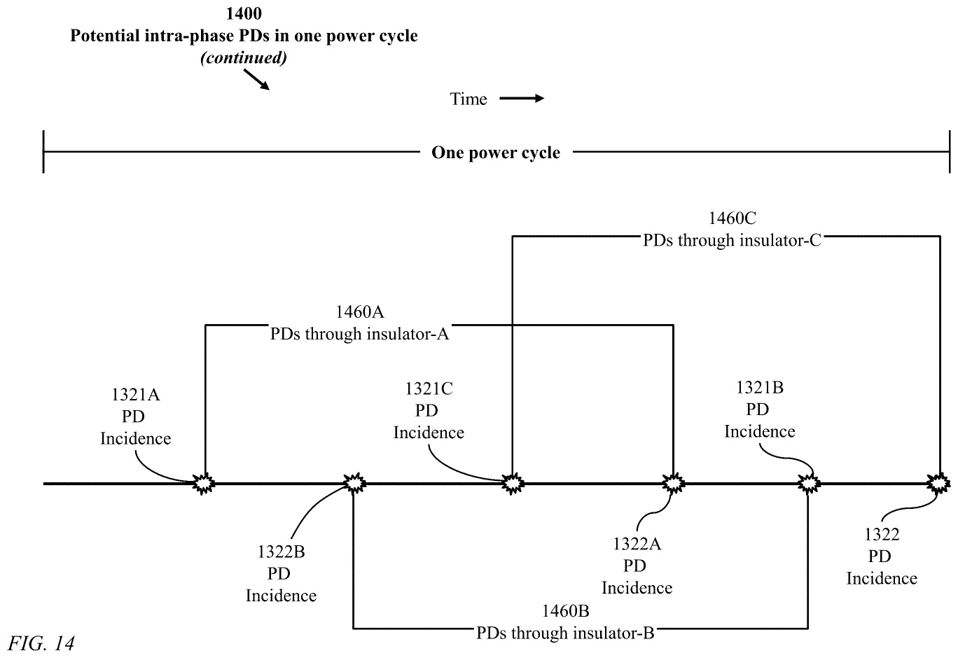

FIG. 14 is a simplified view 1400 of potential intra-phase PDs in one power cycle indicating potential PD incidences 1460A, 1460B, and 1460C traversing insulators of phases A, B, and C, respectively.

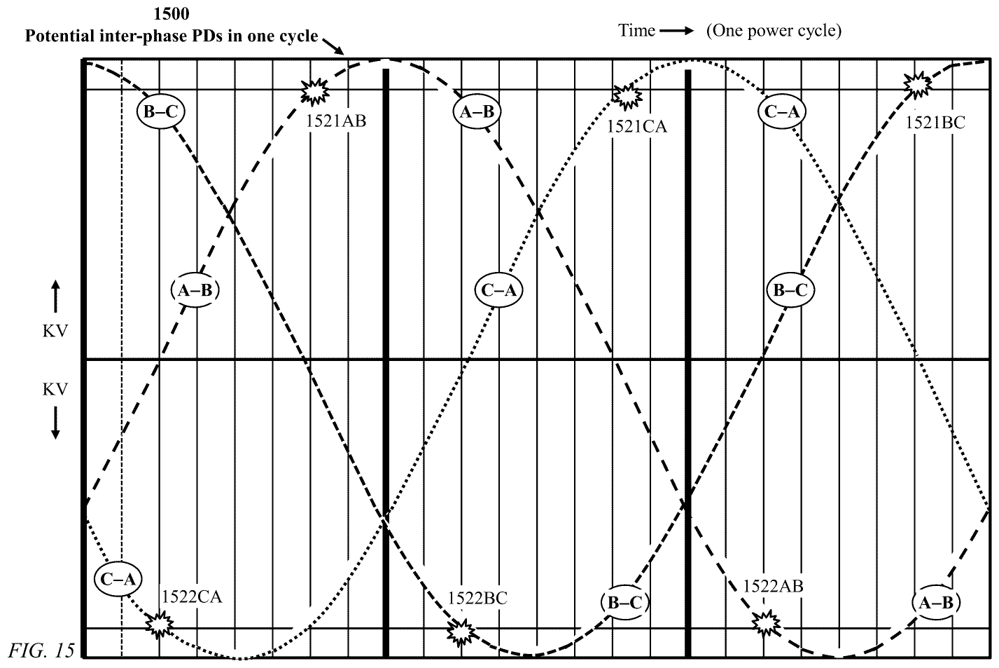

FIG. 15 illustrates an example 1500 of potential inter-phase partial discharges (PDs) in one power cycle. PD incidences 1521 occur near the peak inter-phase voltage value (1521AB, 1521BC, 1521CA, for inter-phases A-B, B-C, and C-A, respectively. PD incidences 1522 occur near the trough inter-phase voltage value (1522AB, 1522BC, 1522CA, for inter-phases A-B, B-C, and C-A, respectively.

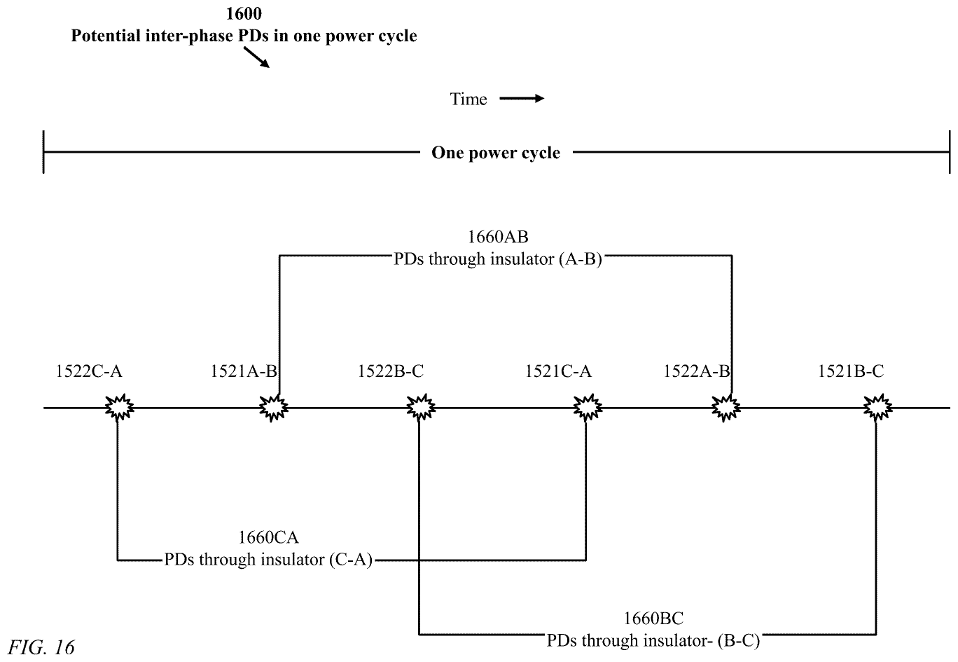

FIG. 16 is a simplified view 1600 of potential inter-phase PDs in one power cycle indicating potential PD incidences 1660AB, 1660BC, and 1660CA traversing inter-conductor insulators.

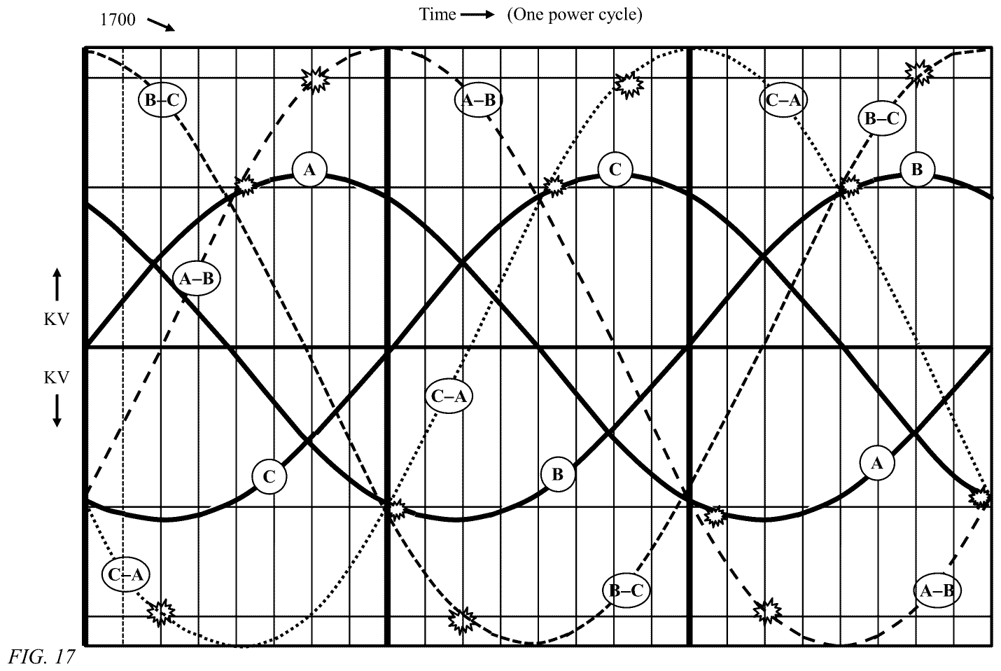

FIG. 17 illustrates all potential PD incidents 1700 within a single power cycle, including intra-phase and inter-phase potential partial discharges.

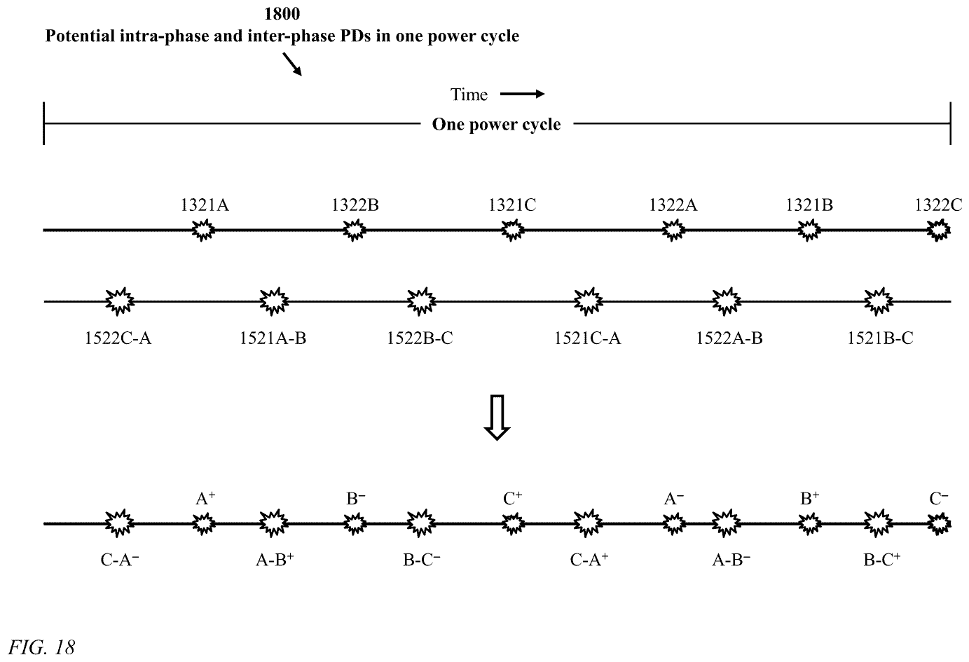

FIG. 18 is a simplified view 1800 combined potential intra-phase and inter-phase partial discharges within a power cycle (20 milliseconds or 50/3 milliseconds. PDs occurring through an insulator at positive and negative voltages are identified with the superscripts “+” and “−”. There are up to six potential PDS traversing intra-phase insulators and up to six potential PDs traversing inter-phase insulators to a total of twelve potential PD incidences during a single power cycle.

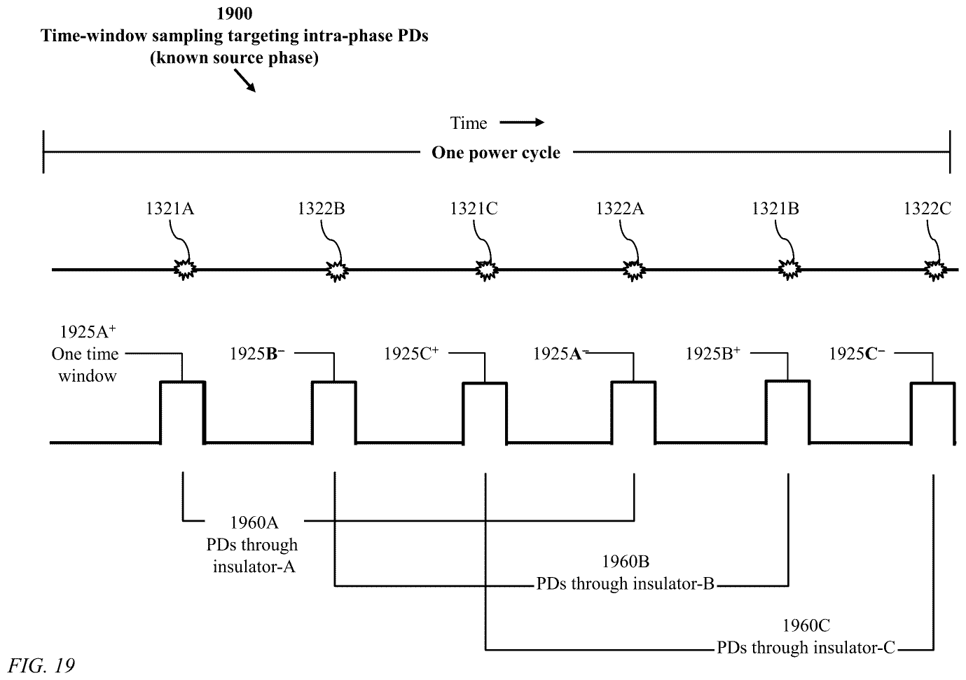

FIG. 19 illustrates a process 1900 of time-window sampling (coarse sampling) to precede fine sampling to target only potential intra-phase PDs. Sampling Time-windows 1925 correspond to time intervals of a power cycle during which only intra-phase PDs may occur. Specifically, a time window 1925 referenced with the suffix A⁺ coincides with a time interval during which a detected PD would occur near the peak of the high voltage of phase A while a time window 1925 referenced with the suffix A⁻ coincides with a time interval during which a detected PD would occur near the trough of the high voltage of phase A. The notation likewise applies to phases B and C. PDs traversing an intra-phase insulator of phase A are identified as 1960A; likewise, 1960B and 1960C identify PDs traversing intra-phase insulators of Phase B and phase C, respectively. In implementations there may be three or six different window sampling filters, all connected in parallel to the input but feeding six independent analyzers or combined in pairs (A+,A−), (B+,B−), and (C+,C−) to three analyzers. In implementations there may be three window samplers feeding A, B and C processing.

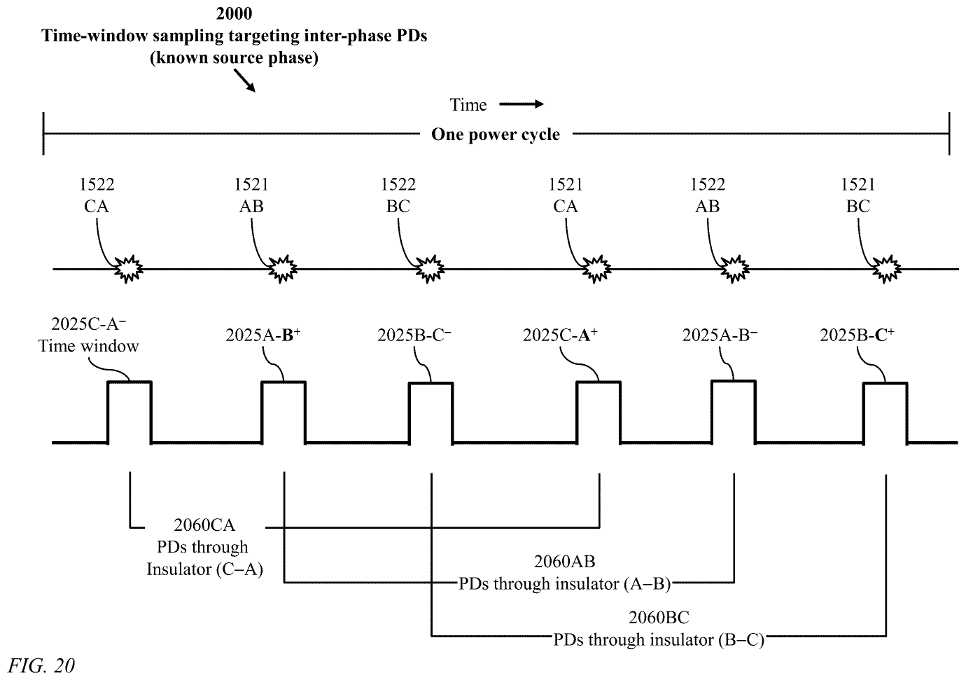

FIG. 20 illustrates a process 2000 of time-window sampling (coarse sampling) to precede fine sampling to target only potential inter-phase PDs. Sampling Time-windows 2025 correspond to time intervals of a power cycle during which only inter-phase PDs may occur. Specifically, a time window 2025 referenced with the suffix (A−B)⁺ coincides with a time interval during which a detected PD would occur near the peak of the high voltage between conductors serving phases A and B (FIG. 8) while a time window 2025 referenced with the suffix (A−B)⁻ coincides with a time interval during which a detected PD would occur near the trough of the high voltage between conductors serving phases A and B. Likewise, the notation applies to inter-phase voltages between conductors serving phases B and C as well as between conductors serving phases C and A. PDs traversing an inter-phase insulator between phases A and B are identified as 2060AB and similarly for PDs traversing an insulator between conductors serving phases B and C as well as an insulator serving phases C and A. Again, in implementations there may be three or six different window sampling filters, all connected in parallel to the input but feeding six independent analyzers or combined in pairs to three analyzers. In implementations there may be three window samplers feeding phase-pair specific processing.

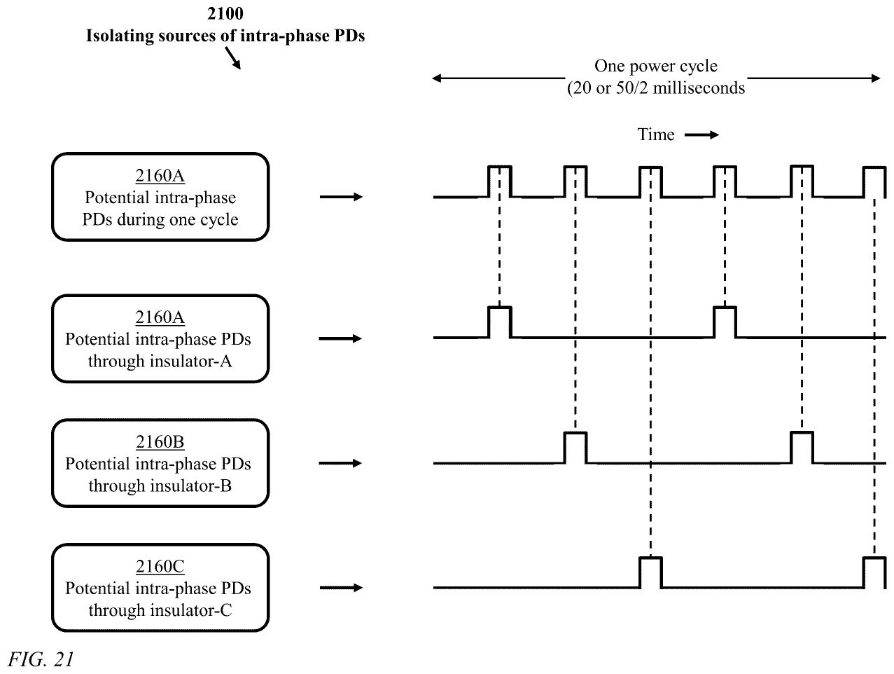

FIG. 21 illustrates a scheme 2100 for identifying sources of phase-to-neutral PDs using time-window sampling. The set 1925 of time windows corresponds to time intervals of a power cycle during which only phase-to-neutral PDs may occur as illustrated in FIG. 19. The pair of time windows referenced as 2160A corresponds to time intervals of a power cycle during which only phase-A PDs may occur. The pair of time windows referenced as 2160B corresponds to time intervals of a power cycle during which only phase-B PDs may occur. The pair of time windows referenced as 2160C corresponds to time intervals of a power cycle during which only phase-C PDs may occur.

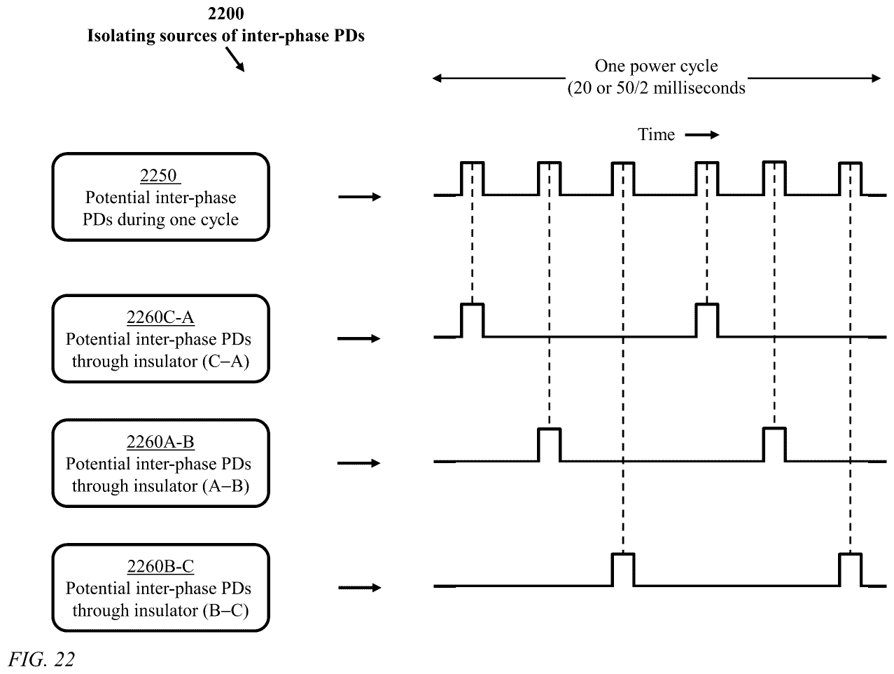

FIG. 22 illustrates a scheme 2200 for identifying sources of inter-phase PDs using time-window sampling. The set 2025 of time windows corresponds to time intervals of a power cycle during which only inter-phase PDs may occur as illustrated in FIG. 20. The pair of time windows referenced as 2260(C-A) corresponds to time intervals of a power cycle during which only PDs between conductors serving phases C and A may occur. The pair of time windows referenced as 2260(A-B) corresponds to time intervals of a power cycle during which only PDs between conductors serving phases A and B may occur. The pair of time windows referenced as 2260(B-C) corresponds to time intervals of a power cycle during which only PDs between conductors serving phases B and C may occur.

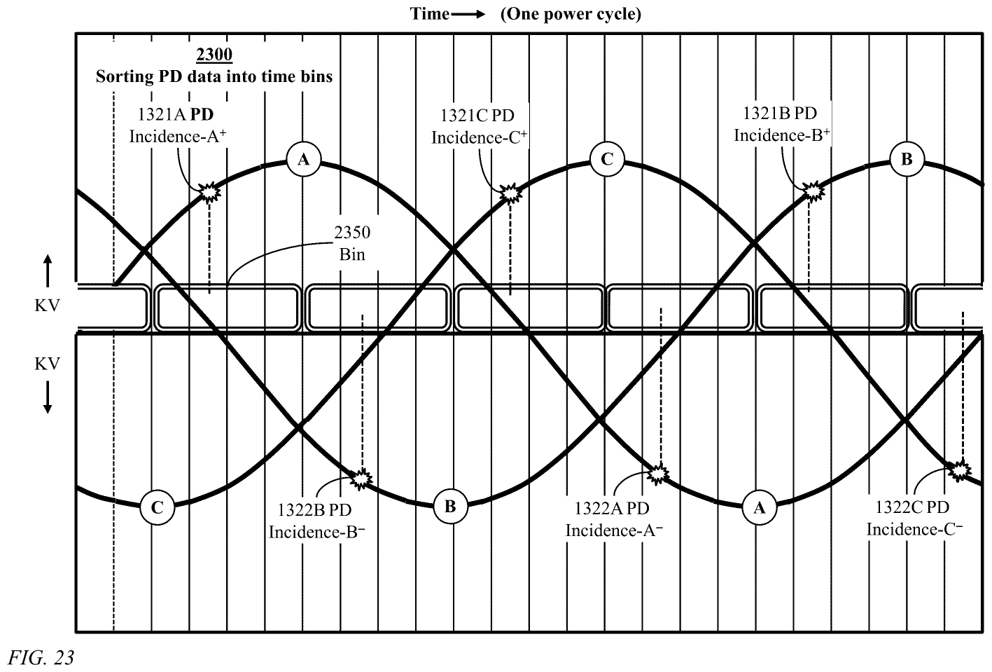

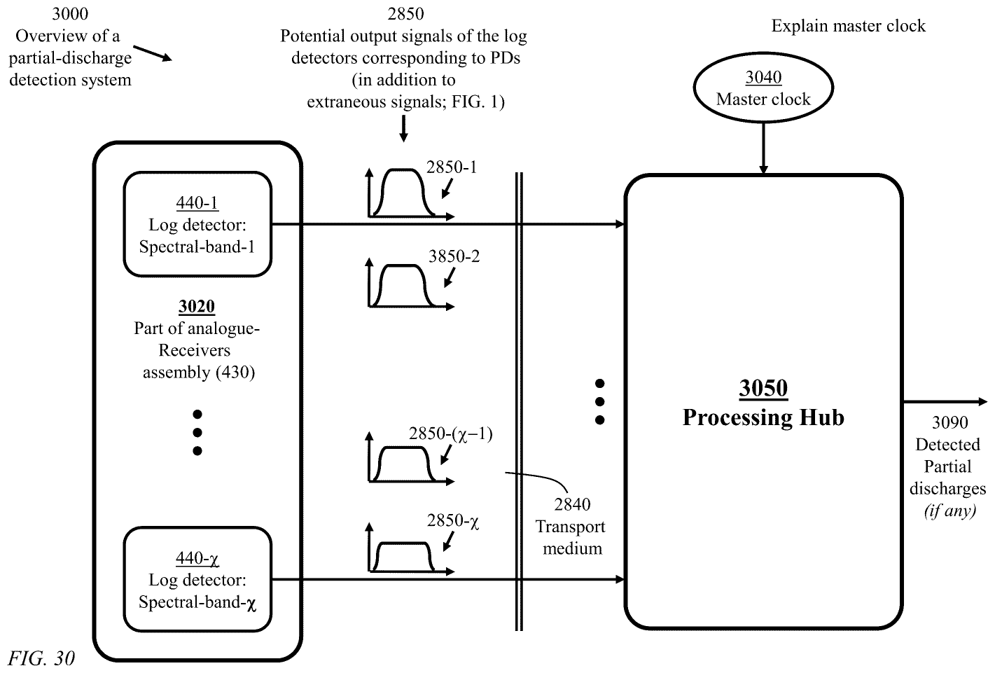

FIG. 23 illustrates a scheme 2300 of sorting detected-signal data into time bins 2350 for a case of known absence of inter-phase PDs. Data relevant to output signals of the log detectors 440 or 540 are written in memory divisions having a one-to-one correspondence to the time bins. The time-bin data (rather, the memory-divisions data) is processed in a processing-hub 3050 to be introduced in FIG. 30. In preferred implementations the sorting is also performed in said hub. Note that the bins associated with each line are shown as occupying the time or phase period in advance of the maximum. Depending on the class of equipment, the type of discharge, and the severity of the discharge, the time or phase span associated with a specific line or electrical phase of the three phase system may be centered on the peak or may be in advance of the peak or in between.

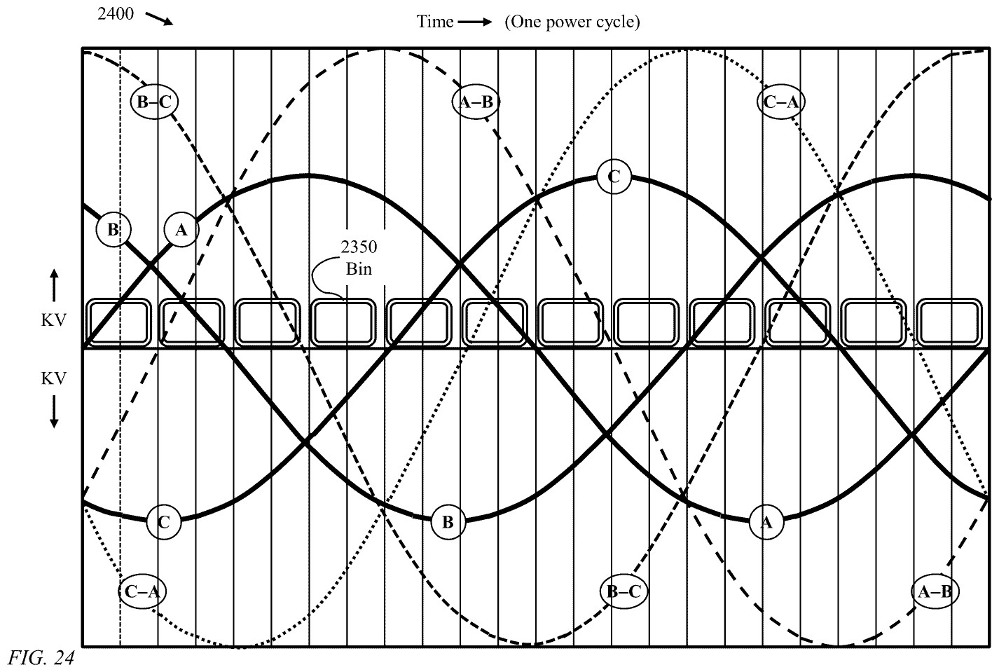

FIG. 24 illustrates a scheme 2400 of sorting detected-signal data into time bins 2350 for a case of potential intra-phase and inter-phase PDs. Data relevant to output signals of the log detectors 440 or 540 are written in the memory divisions having a one-to-one correspondence to the time bins. The time-bin data (i.e., the memory-divisions data) are processed in the aforementioned processing hub 3050. The final case of only inter-phase PD could also occur and is simply that of FIG. 23 with the bins shifted 60 degrees.

FIG. 25 is an overview of a method 2500 of detecting partial charge. Process 2510 uses at least one antenna 140 to receive potential radiated PD electromagnetic (EM) signals and unavoidable other extraneous EM signals. Process-2520 extracts a predetermined number of narrow band signals from the electric output signal(s) of the antenna(s) in order to facilitate distinguishing PD signals from background extraneous signals. Distinguishing PD signals is based on exploiting unique properties of PD radiation that are very unlikely to be present in other EM radiated signals. Process 2530 branches to process 2540 if reference attributes of PD classes (such as class-specific time-domain pulse shape) are available. Otherwise, process 2530 branches to process 2550 bypassing process 2540. Process 2540 compares attributes such as shapes of output pulses of the log detectors with known reference attributes (shapes) to determine an indication of an actual occurrence of a partial discharge. This indication is an analog waveform or digital representation thereof with a shape being the related to the source signal and target signal and an amplitude indicating the degree to which they are similar and the input signal (PD event) amplitude. A common method uses matched filter techniques, while other similar methods exist. The reference shapes create a non-orthogonal basis set and the amplitudes of the indicators give the degree to which an incoming signal matches each member of the basis set. The indication is optionally used in step 2540. Process 2540 examines the extracted narrowband output signals to determine whether the predetermined number of narrowband signals belong to a respective single source based on time coincidence and amplitude balance using correlation methods.

Data is stored in a series of time bins for each receiver being part of the coincidence filter. The width of these time bins is sufficiently small to allow meaningful comparison of the time of arrival in one receiver to another but sufficiently wide as to exceed the width of the detected dB or mV pulse. The minimum size of such bins would relate to the inverse of the bandwidth of a receiver which might be as small as 10 ns to as large as 1 us depending primarily on the filter. In any case the length of the series of bins should extend several ADC samples, for example 16 samples at 30M samples per second is on the order of 528 ns and somewhat smaller and larger bin sets are a matter of technical choice and memory availability. A detected signal must coincide in at least two different frequency bands at approximately the same time (“coincidence filter”) because the source signal of partial discharge is extremely broadband. If energy is detected in one receiver band and not in any other frequency band, the analyzer assumes this is an interfering signal or a very distant partial discharge signal and the signal is rejected. The degree of signal balance that is required is a parameter of the system and determines the degree of localization that the system wishes to enforce.

In preferred embodiments the raw signals or the cross-correlated signals still have a very high data rate of tens of millions of samples per second, perhaps 2\hat{ }19 or 2\hat{ }20 per power cycle, while the synchronicity filter would want far fewer samples, perhaps 2\hat{ }11 per power cycle. In some embodiments the sampling rate reduction is performed by under-sampling, and the coincidence filter would have a peak hold (max value) functionality over a set of samples of length at least equal to the sampling rate reduction. Time sample compression can be accomplished by averaging, accumulating, or peak holding the coincidence filter output over a number of samples comparable to the under-sampling rate.

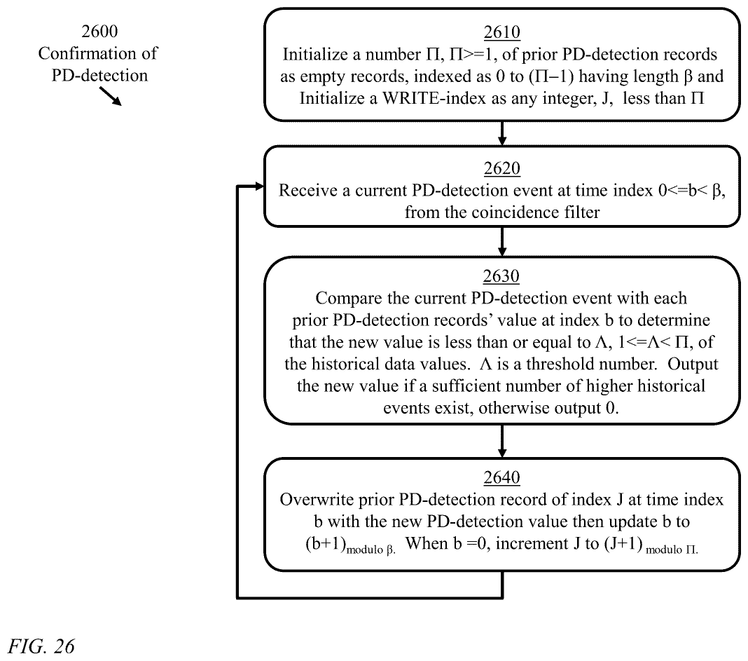

FIG. 26 illustrates a method 2600, implements a synchronicity (or recurrence) filter, for confirming synchronous recurrence of detected PDs. The method determines a pattern of detected PD signals, if any, at substantially the same phase of the power wave cycle within each electric-power cycle of a superset of a predetermined number Π, Π>1, of successive electric-power cycles (of 20 milliseconds or 50/3 milliseconds). Implementations of synchronicity filters are illustrated in FIG. 47 and FIG. 49. Signals that do not repeat on a sufficiently high fraction of the preceding signals are considered to not be partial discharge but are remembered to serve as confirmation for future signals.

Process 2610 initializes a number, Π, of prior PD-detection records of length β as empty records, indexed as 0 to (Π−1) and initializes a WRITE-index as a positive integer J, J<Π. Each element of each record denotes the highest PD amplitude detected in that time interval in that record. Ideally β is sufficiently high that only one PD occurs per element but is also small enough that small amounts of timing jitter do not falsely negate synchronous recurrence. Exemplary values for β could be 2\hat{ }10 to 2\hat{ }12 ranging from almost 20 us down to 5 us. Finer intervals could suppress real PD if the phase jitter of their timing is too large and could count longer PD events in multiple intervals while coarser intervals only allowing a single, largest event per interval could miss closely spaced PDs.

Process 2620 receives an instantaneous PD-detection event, corresponding to a current power cycle, from a coincidence filter 3170 of processing hub 3050 illustrated in FIGS. 30 to 35.

Process 2630 assumes a threshold, A, on the number of prior events in time slot b, with 0<=b<β, that are greater than or equal to the current PD event. It compares the current PD-detection event with the bth element of each prior PD-detection record to determine that a threshold number of events in the prior cycles were equal to or greater than the present value. If the threshold is met, the new value is output, otherwise zero (or the lowest negative number) is output. In alternate embodiments, if Λ values are not higher than the PD, the Λ^{th} highest value is output.

Larger Λ values provide a more stringent constraint and will ignore larger signals if they are not reproducible, leading to fewer false positives. Smaller Λ values are more permissive and will not miss larger PD that are intermittent. The value of Λ must be at least 1 to implement the principles of IEC 60270 that a PD is reported as the largest repeating value of pulse magnitude. In no implementation of a synchronicity filter is the filter output larger than the input value. Setting Λ=0 makes the filter pass all events.

An improved embodiment compares the new value to 3Π (or a higher multiple of Π) prior samples, being the samples at elements b−1, b, and b+1 in each record. This allows the proper representation of two PD events occurring close in time while allowing higher phase jitter of a synchronously recurring PD. It is understood that for b=0 that b−1 is really b=β−1 of record J−1. It is further understood that for b=β−1, b+1 is really b−0 of record J=J+1. Similarly, it is understood that J underflows or overflows 0<=J<Π. Since this approach uses three times the number of samples, 0<Λ<3Π and Λ is typically three times as large for the same level of filtering.

Alternately the coincidence filter could apportion the signal over the primary bin and a leading and trailing bin, for example ½ of the quantity to the primary bin and ¼ to each of the earlier and later bins. In this way, jitter of +/−1 bin would have non-zero overlap and would be counted with a slight reduction. This has the disadvantage of showing the PD at half amplitude and possible reporting additional PDs of ¼ amplitude. The total discharge in pC would not be seriously affected but the peak PD and count of events would be misrepresented.

Process 2640 overwrites element b of prior PD-detection record of index J with the current PD-detection event making record J become the current record as the process evolves for J. When element number b reaches β and resets to 0, the process 2640 updates J to (J+1)_{modulo Π}.

In embodiments, the buffer being received is the oldest sample buffer, the new sample is compared to the old data and corresponding data of other buffers at the present time index, and the old data is overwritten with the new data before incrementing the index. In embodiments a less pipelined approach is used, and a full record of new data is collected and processed at the end of each power cycle.

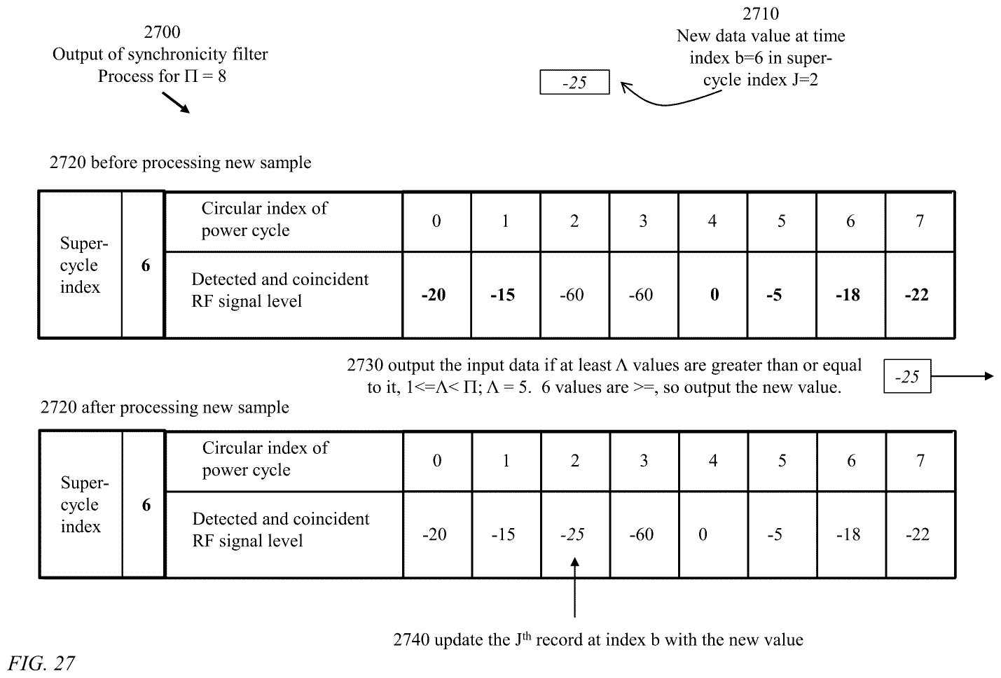

FIG. 27 illustrates an example 2700 of output of process 2630, of method 2600, which determines a count of the number of maximum value of detected PD signals in a prior super cycle of Π power cycles, with Π=8 that are greater than or equal to the new value. The cyclical indices of the constituent power cycles of a super cycle are indexed as 0 to (Π−1), that is 0 to 7. During a current power cycle, the new sample is received and the number of prior amplitudes that are greater than or equal to the new event are counted. If the number is at least A then the new value is output as a validated, synchronously recurring PD. If not, the value is rejected. In some embodiments when the value is rejected, 0 is output. In other embodiments the Λ^{th} highest value is output. In practice, the number of cycles in a super cycle are limited since until Λ records are processed, the output will be zero (or the lowest negative number). If Λ is not a small number compared to the accumulation time, e.g. 60 periods for one second of collection, the accumulated and averaged results could be impacted. Since Λ needs to be a meaningful proportion of Π, Π needs to be limited.

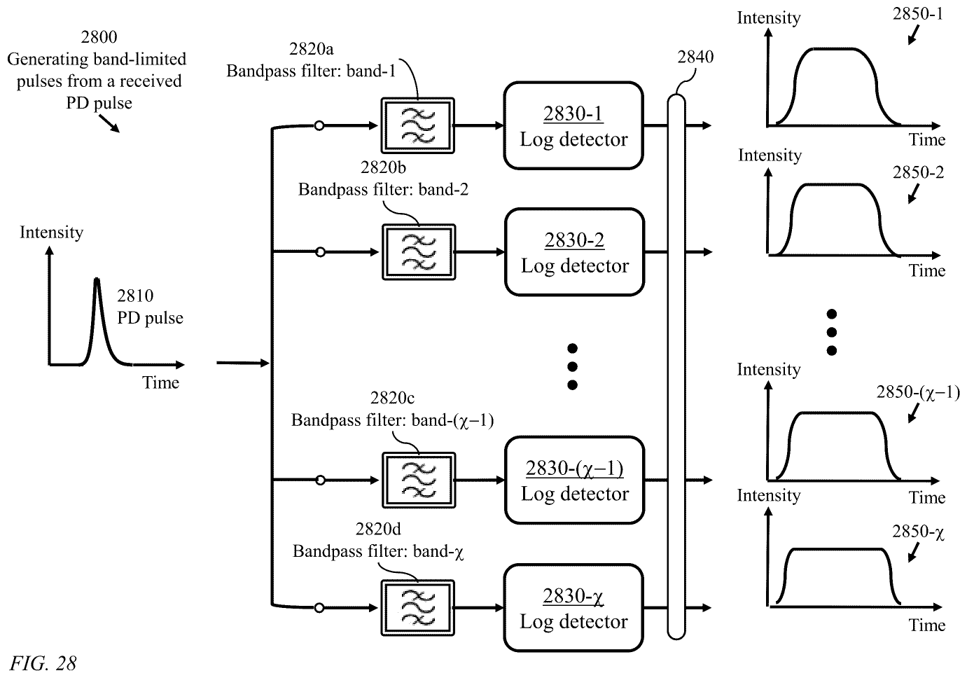

FIG. 28 illustrates basic process 2520 of selecting a set of narrower bands from an envisaged broadband of PD electromagnetic (EM) spectrum, extracting respective narrowband signals from the electrical output signals of the antennas, and using logarithmic detectors (log detectors) to produce wider-duration pulses from each narrow-band signal to be used for ascertaining and classification of any received PDF EM wave. Upon receiving a single sharp EM PD pulse 2810, which may be one of many received at each antenna 140, the electrical outputs of the antennas are supplied to a number χ of bandpass filters 2820 which may be synthesized to extract slices of the pulse's spectrum of equal (FIG. 4) or different (FIG. 5) bandwidth; χ=4 in the example of FIG. 28. The log detectors 2830 may handle passbands of equal width (FIG. 4) or different widths (FIG. 5). Pulse shapes 2850-1 to 2850-4, relevant to the received pulse 2810, at outputs of the log detectors, together with other band-filtered extraneous signals are communicated through a transport medium 2840 to a processing hub 3050 introduced in FIG. 30.

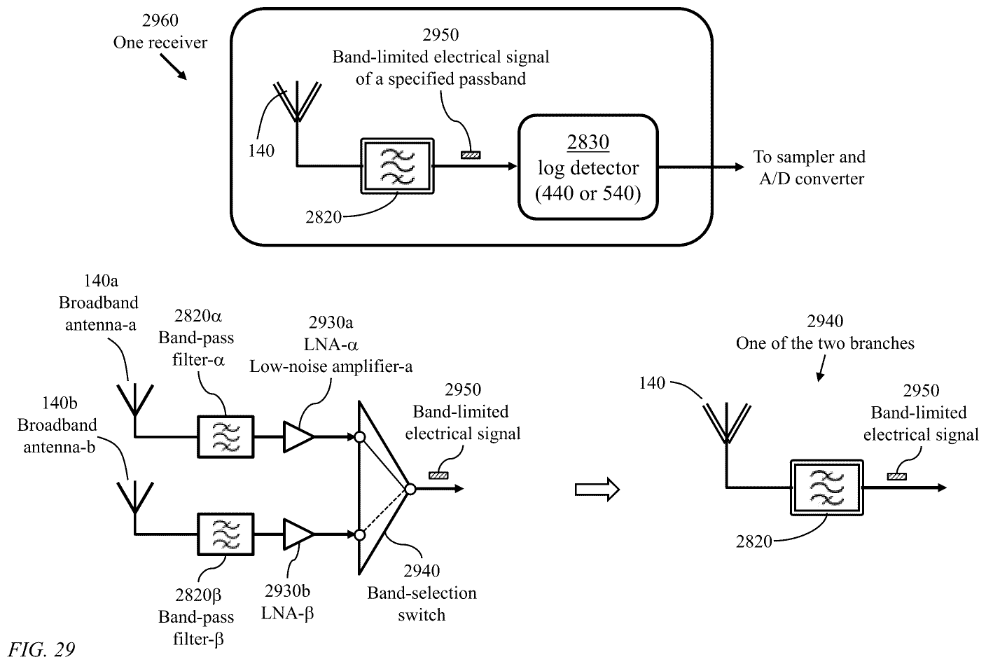

FIG. 29 illustrates a specific analog receiver 2900 as one of the analog receivers of the receivers-assembly 430 or 530 with an option of using more receivers than intended for executing process 2520 of FIG. 25. As illustrated, instead of using a single antenna 140 and a single bandpass filter 2820 (which is 420 or 520), two broadband antennas 140a and 140b, two bandpass filters 2920α and 2920ß, and two low noise amplifiers 2930a and 2930b are used to acquire EM signals and extract narrowband slices of the broad spectrum of the output electrical signals of the antennas 140a and 140b. A band-selection switch 2940 selects one of the outputs of LNAs 2930 and 293b based on reception quality. The band-selection RF switch 2940 comprises a comparator (not illustrated) output or other feature of the hub controller communicated to the receiver. The electrical signal output 2950 of the band-selection switch is supplied to a log detector 3830 (which is 440 or 540 of FIG. 4 and FIG. 5) of a specified passband.

In an exemplary embodiment, there are four antennas, four filters, four amplifiers, two RF switches, two log detectors, and two signals transmitted to two A/D converters in the hub. A first and second antenna and filter measure a first and second lower frequency, for example below 1000 MHz and a first switch selects one of these signals based on noise levels from interference and signal strength. A third and fourth antenna and filter measure a first and second upper frequency, for example, above 1000 MHz and a second switch selects one of these signals based on noise levels from interference and signal strength. The selected low frequency and selected high frequency signals are transmitted to the hub, where they are compared for coincidence and synchronicity.

FIG. 30 is an overview 3000 of a PD detection system organized as analog-receivers assembly 430 or 530 and a process hub 3050; only the set 3020 of log detectors of the analog-receivers assembly are illustrated in FIG. 30. A master clock 3040 timing operations of processing hub 3050 is phase-locked to the power cycle. The processing hub generates indications 3090 of partial discharges, if any, which are stored in a memory device. The processing hub 3050 may comprise a logic board, a microprocessor system on chip, or field programmable gate array (FPGA).

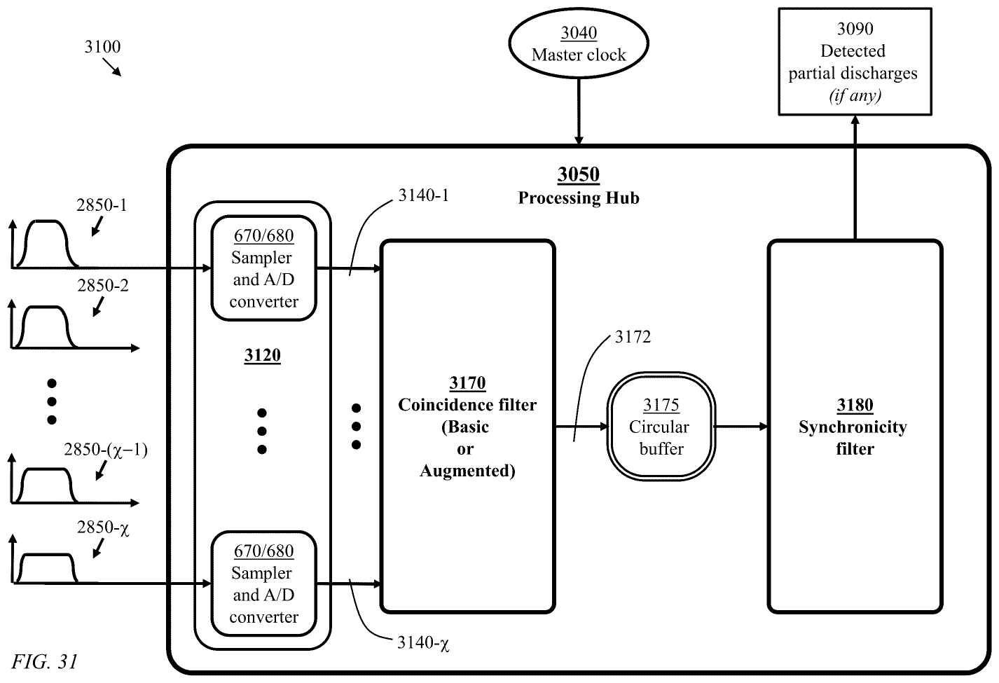

FIG. 31 illustrates basic components 3100 of the processing hub, including set 3120 of fine samplers and A/D convertors, a coincidence filter 3170, a circular buffer 3175, and a synchronicity filter 3180. Data 3140 from the A/D convertors 3120 is supplied to the coincidence filter 3170. The coincidence filter 3170 generates indications 3172 of presence of PDs.

As illustrated in FIG. 31, Data 3140 from the A/D convertors 3120 is supplied to the coincidence filter 3170. The coincidence filter considers a signal to potentially represent to a partial discharge (PD) if it is present in a plurality of frequency bands at the same time, preferably with comparable amplitudes or an expected frequency dependence of amplitudes. The output of the filter is a weighted combination of the received and filtered waveforms.

In some embodiments, the cross-correlations of the signals in pairs of channels are used. In a logarithmic scheme, either the sum or the arithmetic average of the logarithmic signals is taken, providing the product or the geometric mean of the linearized values that would be needed for the correlation. The average of the dB signals is preferred as it does not change the units or the scale of the equivalent linearized signal. In this approach the overall amplitude is reduced if either signal is small, emphasizing signals that are present in both channels, and the function is linear and easily implemented in FPGA fabric or analog electronics.

In a linear scheme, multiplicative correlation can be used, or averaging can be used.

In a more preferred embodiment, the result is normalized by a term that limits to 1 if all signals are equal or have a desired difference. Normalization would entail division of linear signals or subtraction of a dB term. In order to correct for variations in signal strength due to receiver design and construction, the normalization may correct for a predetermined linear ratio or logarithmic offset, either by frequency-specific amplification factors or by an offset in the normalizing term to account for instrumentation induced frequency effects. This provides a preselected reduction in value for a degree of signal mismatch that is considered the acceptable limit.

For the case of two linear signals, S1 and S2, the divisor may be (1+a*(S1−S2−d₁₂)²) by way of non-limiting example and the correlator output would be sqrt (S1*S2)/(1+a*(S1−S2−d₁₂)²). The sqrt is optional, and it is possible to use large integer numbers without it. The parameter, a, provides a weighting to the deemphasis function when there is amplitude imbalance and d₁₂ is an optional, desired imbalance between the low and high channel. For two logarithmic signals, the correlator output would be ½ (log S1+log S2)−a(|log S1−log S2−d₁₂|), which provides the log of the geometric mean of the two signals, reduced by a factor related to the imbalance in the two signals adjusted by a n optional, desired offset d₁₂.

Multiple signals may be scaled in a similar manner as (1+a*(S1−S2−d₁₂)²+b*(S1−S3−d₁₃)²+c*(S2−S3−d₂₃)²) and so on or (log S1+log S2+ . . . +log Sχ)/χ−a₁₂(|log S1−log S2−d₁₂)−a₁₃(|log S1−log S3−d₁₃|) . . . aᵢⱼ(|log Si−log Sj−dᵢⱼ| . . . ).

In the above equations, S1, S2 etc are respective output signals from linear detectors, and log S1, log S2 etc are respective output signals from log detectors.

In embodiments wherein the raw signals were correlated to one or more classification signatures of partial discharge, the cross-correlation would determine if the same classification was present in more than one frequency band within a time window. In such embodiments there would exist an array of K correlation processes for K classes with K outputs of the correlation or coincidence, one for each classification, and the coincidence filter would be a vector of the same order as the number of signatures used for classification.

In preferred embodiments the raw signals or the cross-correlated signals have a very high data rate of millions of samples per second while the synchronicity filter would want far fewer samples. In some embodiments the sampling rate reduction is performed by under-sampling and the coincidence filter would have a peak hold (max value) functionality over a set of samples of length equal to the sampling rate reduction. For example, A 50 Hz waveform may have 20 ms of data at 30 million samples per second resulting in 600 thousand samples while the synchronicity filter may only need 3600 time-samples and the under-sampling rate would be 167 with a timing of 5.56 microseconds. Time compression can be accomplished by averaging, accumulating, or peak holding the coincidence filter output over a number of samples comparable to the under-sampling rate.

In other embodiments, the at least two frequency band signals are individually weighted by the degree of imbalance but are not correlated, with each frequency band representing a separate output that is weighted for frequency balance amongst the frequency bands. For linear signals, the modified signal is

S′1=S1/(1+a*(S1−S2−d₁₂)²+b*(S1−S3−d₁₃)²+c*(S2−S3−d₂₃)² . . . )

S′2=S2/(1+a*(S1−S2−d₁₂)²+b*(S1−S3−d₁₃)²+c*(S2−S3−d₂₃)² . . . )

S′3=S3/(1+a*(S1−S2−d₁₂)²+b*(S1−S3−d₁₃)²+c*(S2−S3−d₂₃)² . . . )

For logarithmic signals, the modified signal is

log S′1=log S1−a(|log S1−log S2−d₁₂|)−b(|log S1−log S3−d₁₃|)−c(|log S2−log S3−d₂₃|) . . .

log S′2=log S2−a(|log S1−log S2−d₁₂|)−b(|log S1−log S3−d₁₃|)−c(|log S2−log S3−d₂₃|) . . .

log S′3=log S3−a(|log S1−log S2−d₁₂|)−b(|log S1−log S3−d₁₃|)−c(|log S2−log S3−d₂₃|) . . .

In either case, the modified signals could then be used in a simple multiplicative or additive coincidence filter or as separate coincidence-weighted signals. It is understood that for positive values systems, the lower bounds on subtractions is zero.

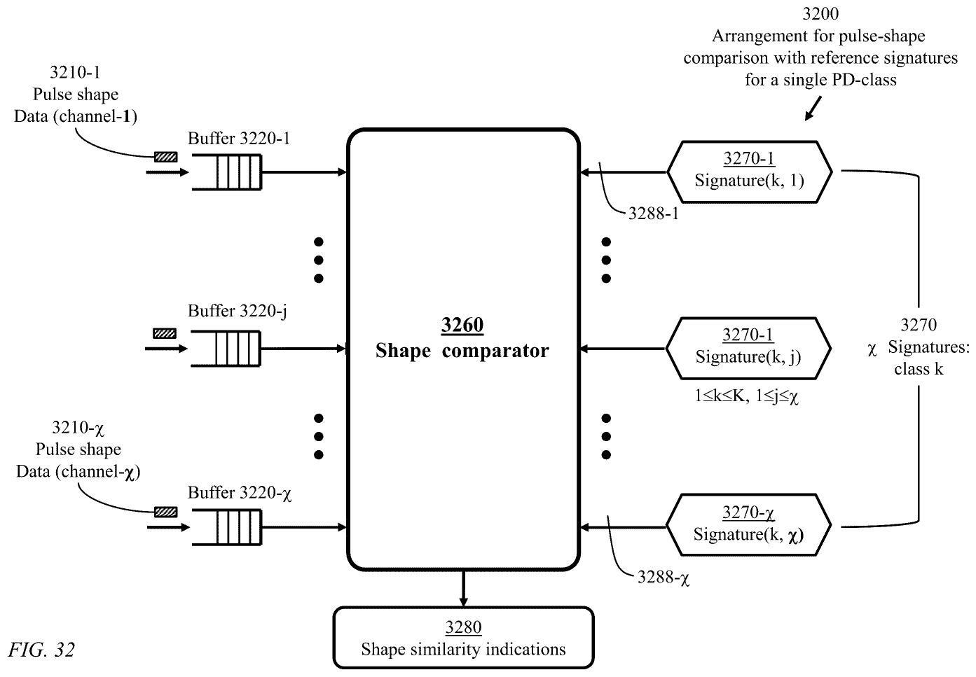

FIG. 32 illustrates an arrangement 3200 for pulse-shape comparison with reference pulse shapes 3270 of a single PD class. A reference pulse shape is also referenced as a “signature”. Pulse shape data 3210 from outputs of set 3120 of fine samplers and A/D convertors is held in buffers 3220 coupled to a shape comparator 3260. Each buffer 3220 holds received from one of the A/D convertors. The shape comparator compares content of each buffer with a corresponding reference pulse shape. Each reference pulse shape corresponds to the PD class under consideration. The shape comparator 3260 produces shape similarity indicators for each of the pulses 2850-1 to 2850-χ.

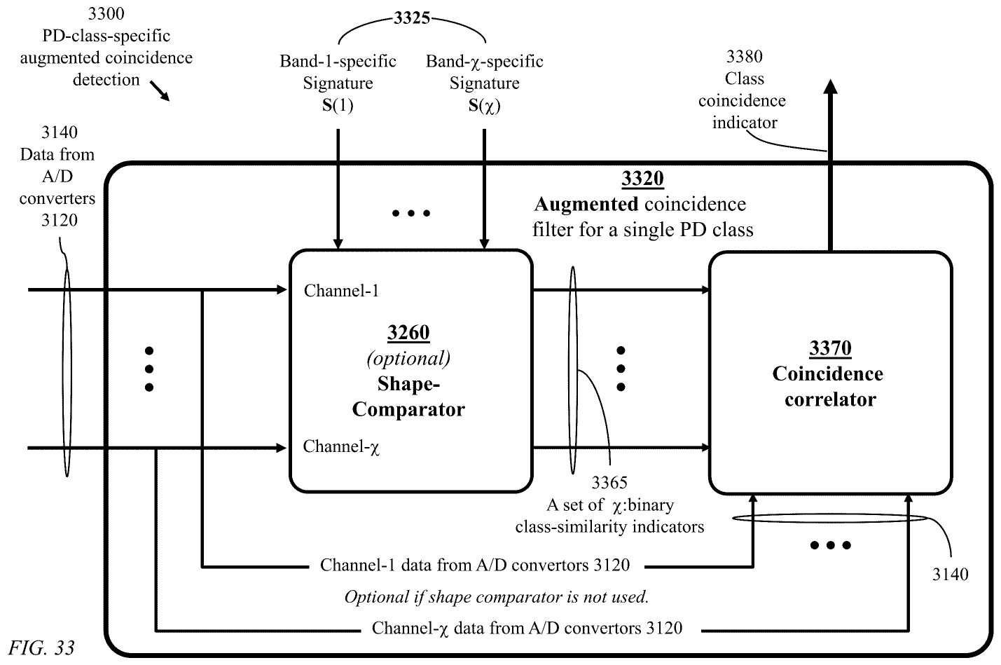

FIG. 33 illustrates an arrangement 3300 for PD-class-specific augmented coincident detection an augmented coincidence filter for a single PD-class, based on pulse-shapes similarities to reference pulse shapes of detected pulse from different log detectors and their temporal coincidence. An augmented coincidence filter 3320 for a single PD class of class k, 1≤k≤K, comprises a shape comparator 3260 and a coincidence correlator 3370. Data 3140 from the A/D convertors 3120 is supplied to shape comparator 3260, if used, and alternately supplied directly to the coincidence correlator 3370. Shape comparator 3365 uses a set 3325 of pulse-shape signatures to produce a set of χ analog class-k similarity indicators that represent the amplitude of the incoming signal weighted by the degree to which the input signal matches the class signature. Coincidence correlator 3370 determines a coincidence indicator 3380-k that is the degree to which the enables frequency bands' class-k similarity indicators coincide in time. In preferred embodiments the coincidence filter also discriminates on the degree to which a desired amplitude balance is attained. Shape comparator 3260 could comprise a matched filter using finite impulse response (FIR) methods. Instead of an alternate data path, the raw signals 3140 would carry to 3365 if the matched filters had a single sample of unit value with the remainder being zero. Time shifting the unit value or matched filter values within the shape reference allows delay compensation between frequency channels.

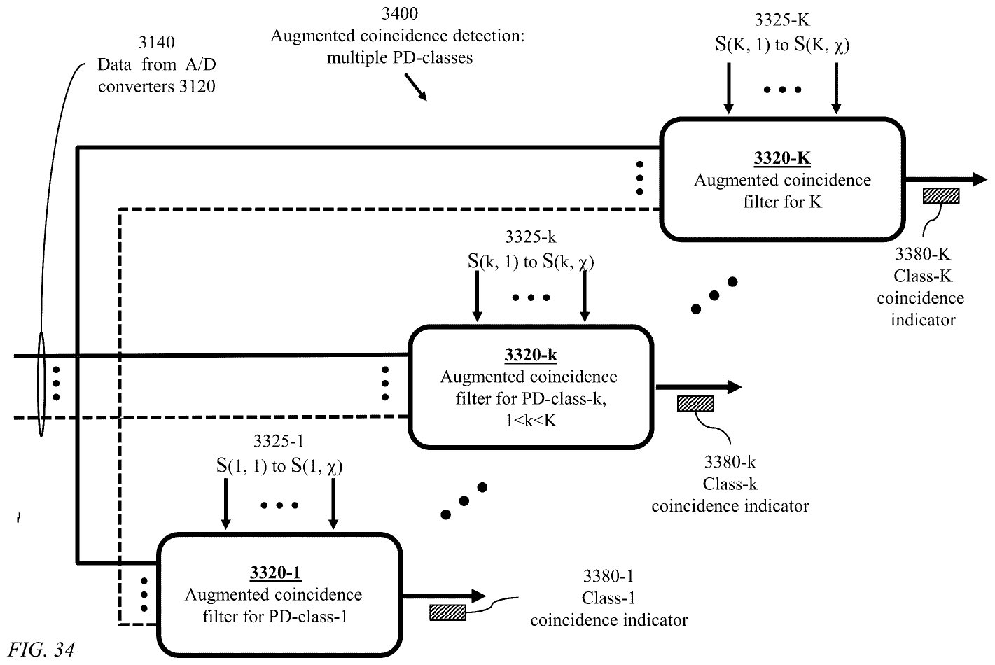

FIG. 34 illustrates an augmented coincidence filter 3400 comprising a set of parallel augmented class-specific coincidence filters 3320 to determine coincidence indicators. Each class-specific coincidence filter 3320 determines a respective class-specific coincidence indicator based on data 3140 from A/D converters and a respective set of χ signatures 3325 for a respective PD class. Each class-k output forms a parallel channel of processing for subsequent processing and visualizing corresponding to the associated class. It is noted that S(k,x) for 0<=x<χ, will comprise χ dissimilar waveforms meant to match not the input waveform, but its distorted replica after bandpass filtering and log detecting. Again, delay balance may be built into S(k,x).

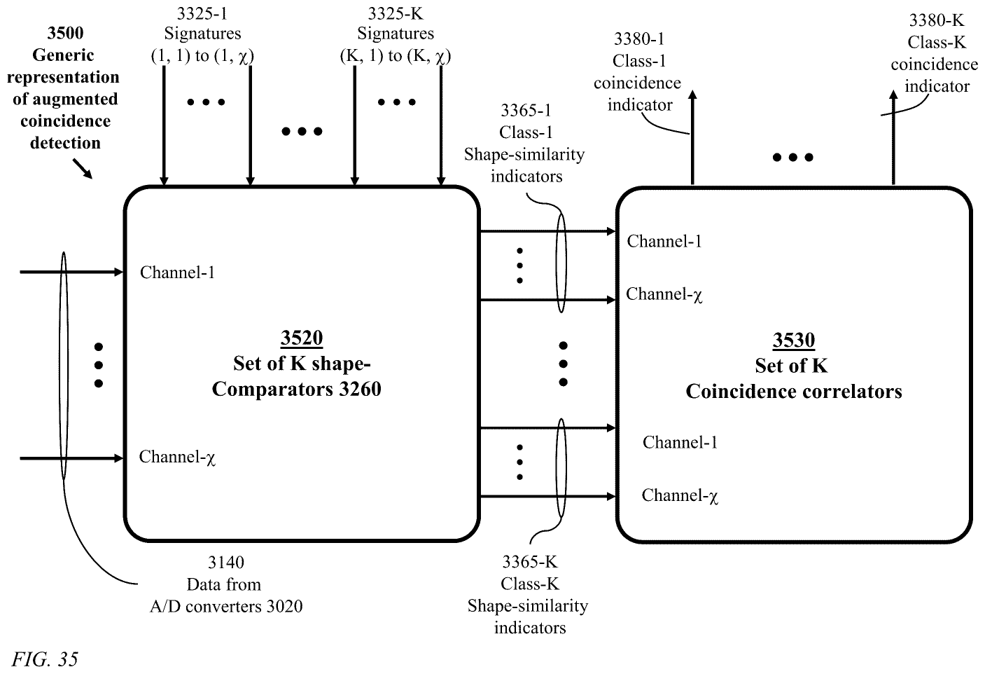

FIG. 35 is a generic representation 3500 of an augmented coincidence detector which uses similarity to pulse-shape signatures in addition to temporal coincidence. The generic augmented coincidence detector comprises a set 3520 of shape comparators 3260 and a set 3530 of K coincidence correlators 3370-1 to 3370-χ. The set 3520 of K shape-comparators (K being a number of PD classes) produces K sets 3365-1 to 3365-K each comprising χ shape-similarity indicators. The set 3530 of K coincidence correlators produces K class-specific coincidence indicators 3380-1 to 3380-K that provide amplitude data on K different classifications of partial discharge that has been verified to coincide in multiple frequency bands.

Thus, a group of χ received waveforms are received and digitized 3140. The resulting digital time series are optionally processed by one or more digital filters. In some embodiments the processing is omitted, and no classification is performed. In other embodiments the digital filter may detect and hold a peak amplitude of a function of one or more samples, for example, an average or a quadratic interpolation, again performing no classification. In yet other embodiments the digital streams are each processed by a correlator, matched filter, or similar process to determine the degree to which the input waveform matches the waveform anticipated for a class of partial discharge. These processed outputs or indicators, indicate the degree to which the input signal matches a target waveform at a moment in time. Without peak detection or integration, they continue to represent a pulse. With peak detection or integration, they represent the magnitude of the PD and are an event.

The group of indicators derived from a group of narrow-band filtered replicas of a received electrical signal are for the degree to which their arrival coincides in time. They may optionally be further tested for the balance of their amplitudes. Correlation in the context of a coincidence filter may, by way of nonlimiting example, be a function that determines the overlap and amplitude balance of the signals at a given time and a peak detection scheme for obtaining the most correlated result.

The output of the coincidence correlator 3530 is a time sequence indicating the time varying degree of the correlation and describes the degree to which the signals coincide and are in balance. It is a proportional analog to the overall signal strength but will have an altered pulse shape.

In some embodiments, as illustrated in FIG. 35, there are a plurality of target PD class signatures and a plurality of resulting PD class coincident indicators being output to a plurality of synchronicity processors in the synchronicity filter module.

Performing optional shape comparator processing before performing coincidence correlation (a) eliminates some noise signals that do not match any class of target PD before that noise can falsely be coincident with signal or noise from another narrow band replica and (b) allows a plurality of coincidence correlators using the plurality of shape indicator waveforms. If the processes were reversed, the specific pulse shape of the individual frequency bands would be lost in the coincidence correlation process, which discards unused information, and would not be available to later determine relatedness to various signatures.

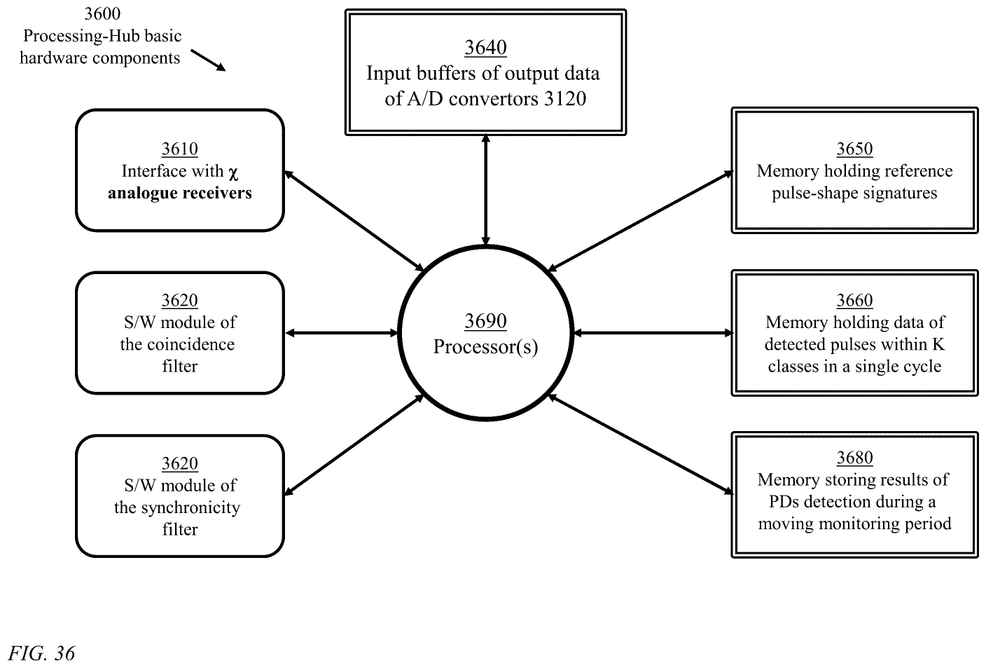

FIG. 36 illustrates a basic structure 3600 of processing-hub 3060. An interface software module 3610 receives signals from an analog receiver assembly 430 or 530 which comprises χ analog receivers. Input buffers 3640 hold data from the A/D convertors. A memory device 3650 holds acquired or generated reference pulse-shape signatures. A software module 3620 implements the coincidence filtering processes, optionally for no classes, a single class, or a plurality of classes. A memory device 3660 holds coincidence-filtered data of detected pulses, within K classes, during a single power cycle, optionally of length β but of a single sample in some implementations. A software module 3630 implements the synchronicity filtering processes either for a single class or, in parallel processes, for K classes. A memory device 3680 stores results of PDs detected during a moving monitoring period. A processor (or an assembly of processors) 3600 executes the processes of processing-hub 3050.

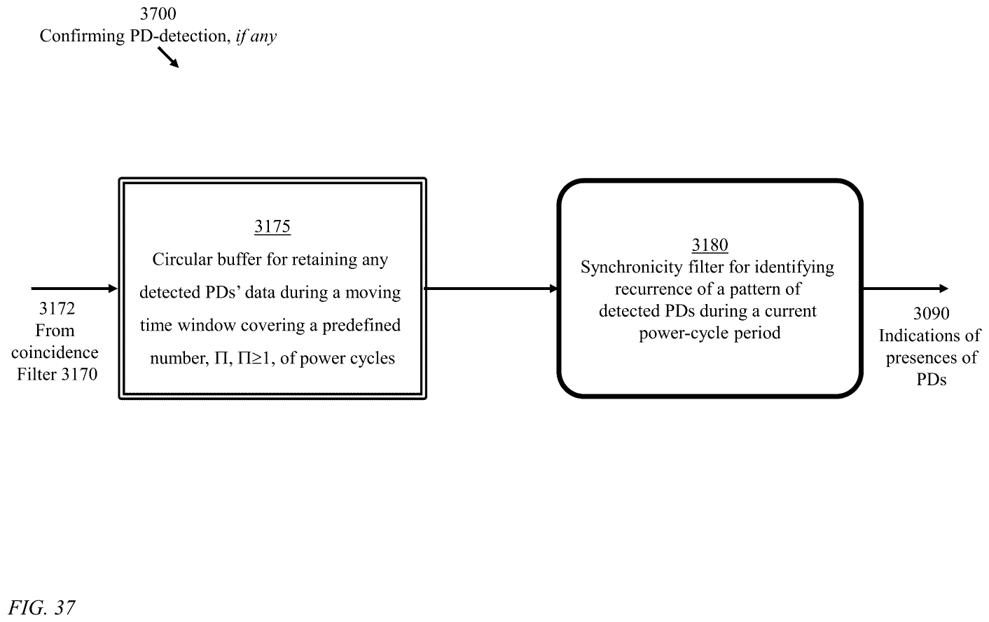

FIG. 37 illustrates components 3700 of the processing hub 3050 used for confirming PD-detection, if any. Circular buffer 3175 retains any detected PDs' data, relevant to indications 3172 of presence of PDs, during a moving time window. Synchronicity filter 3180 identifies multiple occurrences of any detected PD in a super cycle of a number of power cycles. The synchronicity filter produces indications 3090 of potential partial discharges, if any, which are stored in a memory device for further processing.

The historical data is ranked and the Λ^{th} highest value is taken. The output is the lesser of the new value and the Λ^{th} highest value of the previous data and then the previous data of the present record, J, is replaced by the current data. For Π>1 there is flexibility to select the second highest, third highest, . . . k^{th} highest, k>3, of the samples (present and past). The choice of which successively smaller amplitude value to choose is a matter of aggressively reporting PD at the risk of false positives versus aggressively rejecting false negatives at the risk of underreporting PD. In some embodiments, if the new value exceeds the Λ^{th} highest value, zero (or the lowest negative number) is output.

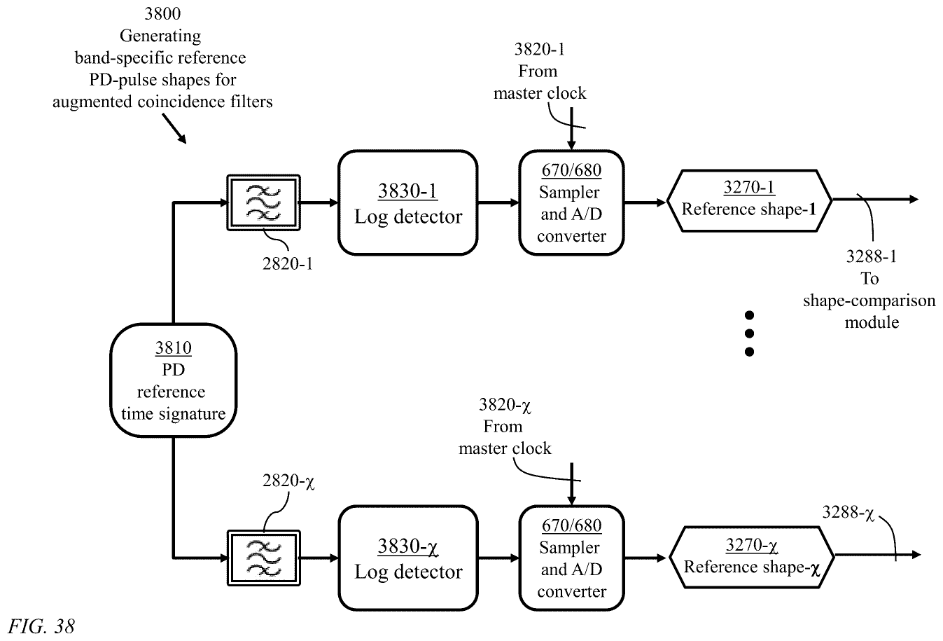

FIG. 38 illustrates a process 3800 of generating reference band-specific PD-pulse shapes 3270 for use in shape comparator(s) 3260 for classifying detected PD pulses. A reference band-specific PD-pulse 3270 is also referenced as a signature (k, j), k being a PD-discharge class, 1≤k≤K, and j is an index of a frequency band, 1≤j≤χ. The signatures (reference pulse shapes) are communicated to the shape comparator(s) via paths 3228-1 to 3288-χ.

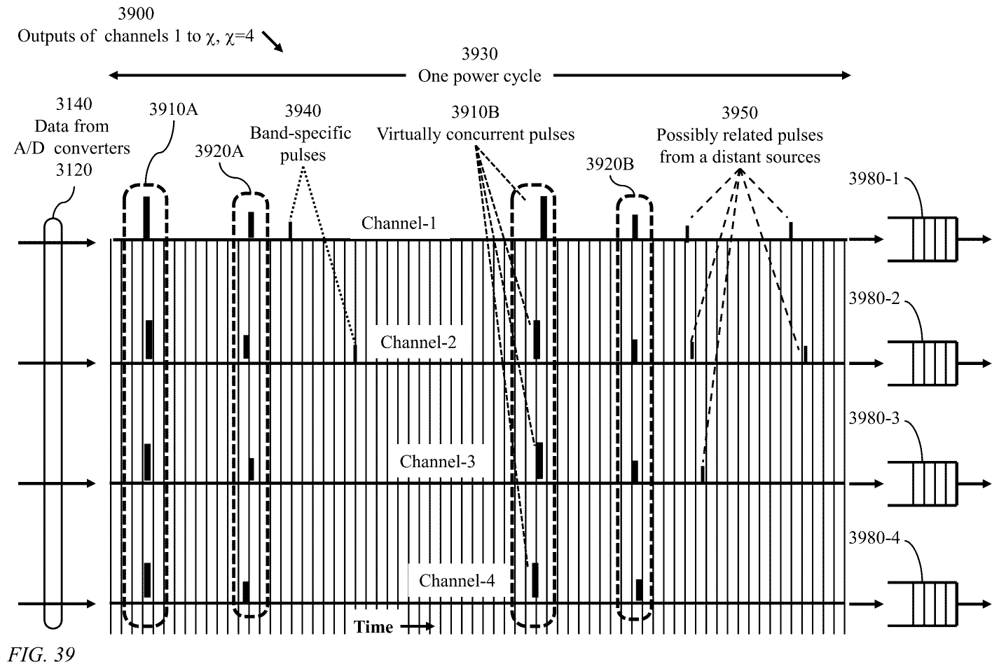

FIG. 39 illustrates exemplary patterns 3900 of detected pulses of individual channels 1 to χ, for χ=4 during one power cycle (20 milliseconds or 50/3 milliseconds). Set 3910 of band-specific significant pulses pass the temporal-coincidence test and may belong to one PD subject to passing the subsequent super-cycle synchronicity test. Likewise, set 3920 of band-specific significant pulses may be considered to belong to another PD. Band-specific pulses 3940 are considered to belong to extraneous signals. Band-specific pulses 3950 are possibly related to PDs from distant sources having low frequency signal but not high frequency signal and having frequency channels dispersed in time. Buffers 3980 hold data identifying respective significant band-specific pulses.

The indicated pulses 3950 may have been concurrent at a significant distance but have separated in time due to wave dispersion along a transmission path and had disproportionately higher losses at higher frequencies. In some embodiments, it is desirable to detect such dispersed pulses and to identify the distance of the source from the detector. In such embodiments, it might further be desirable to reject pulses that originate at a shorter distance. In other embodiments it is preferable to reject distant pulses as they would be reported by an instrument closer to the point of origination and are assumed to not be relevant to the local detector. This can be accomplished by using the class similarity filters to differentially delay different bands to compensate for the dispersion and to balance their gain.

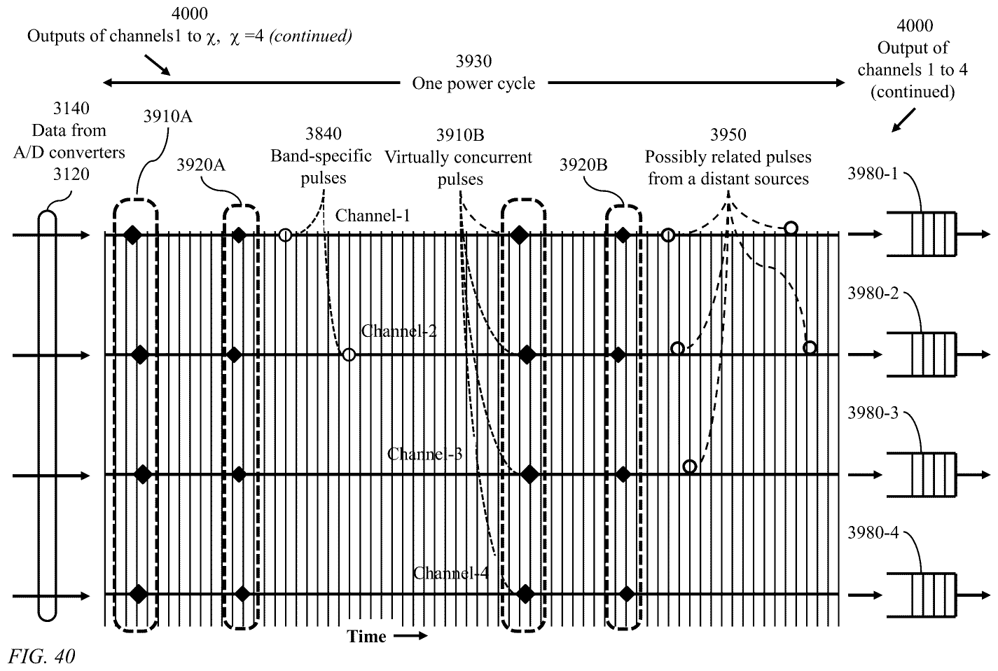

FIG. 40 presents an alternate representation 4000 of the patterns of FIG. 39, with diamond-shaped pulses passing the temporal-coincidence test and would be considered to belong to respective PDs subject to passing the super-cycle synchronicity test.

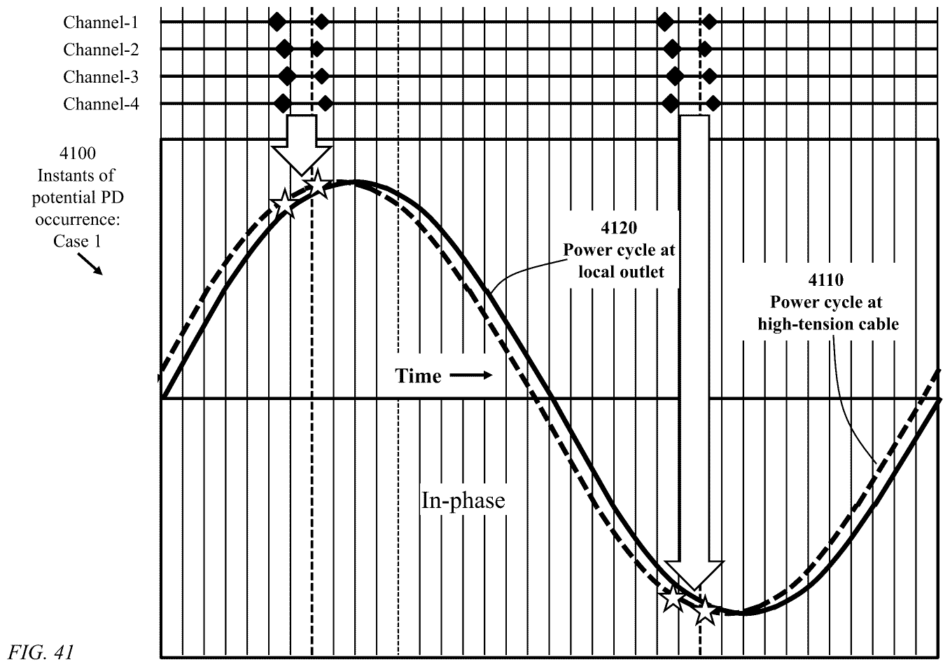

FIG. 41 illustrates instants 4100 of potential PDs within a power cycle at a three-phase high-voltage generation or distribution facility where the phase difference between the waveform 4110 and 4120 of a sinusoidal high-voltage source of the PDs and an accessible stepped-down low-voltage sinusoidal waveform is negligible. Waveform 4120 may be derived from the high-voltage source through other magnetic-induction means. Deriving split phase wall power from three phase power generally incurs a phase shift of n*60 degrees plus any small phase lags of the magnetics themselves.

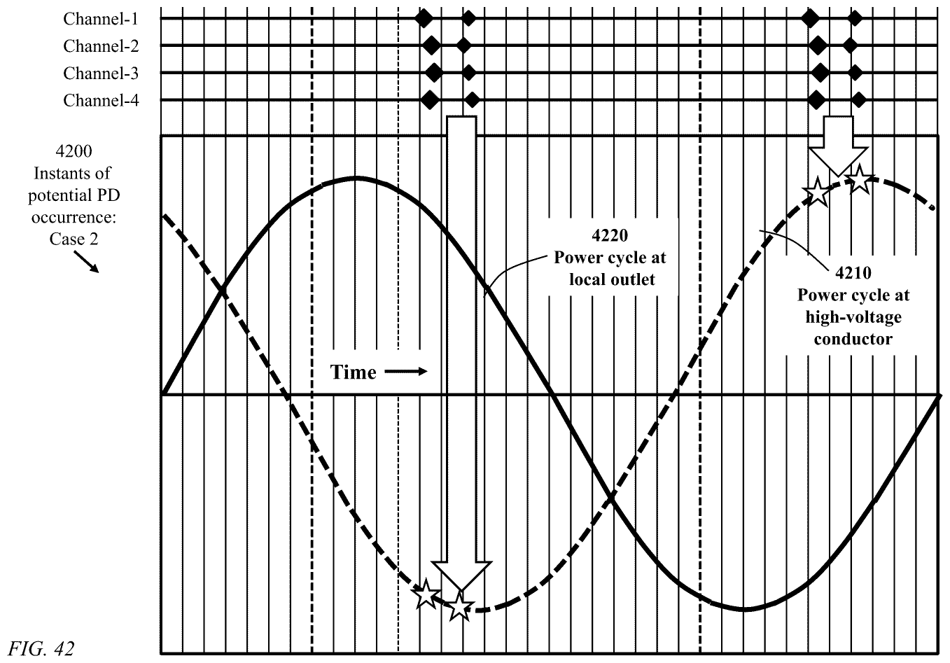

FIG. 42 illustrates instants 4200 of potential PDs within a power cycle at a three-phase high-voltage generation or distribution facility where the phase difference between the sinusoidal high-voltage source of the PDs and an accessible stepped-down low-voltage sinusoidal waveform is approximately 2π/3 radians.

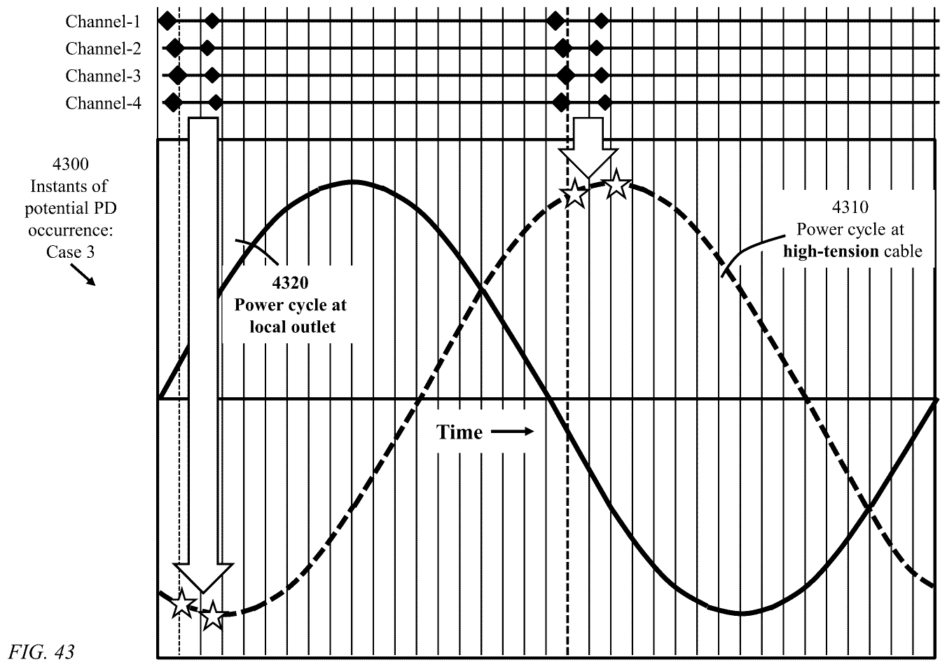

FIG. 43 illustrates instants 4300 of potential PDs within a power cycle at a three-phase high-voltage generation or distribution facility where the phase difference between the sinusoidal high-voltage source of the PDs and an accessible stepped-down low-voltage sinusoidal waveform is approximately 4π/3 radians.

Note that there is generally an in-phase replica of the three phase voltages from the so-called potential transformer (PT) instruments in many power systems. While this could be used to calibrate an offset of the wall power, it is generally not permissible to route this signal to third party instrumentation.

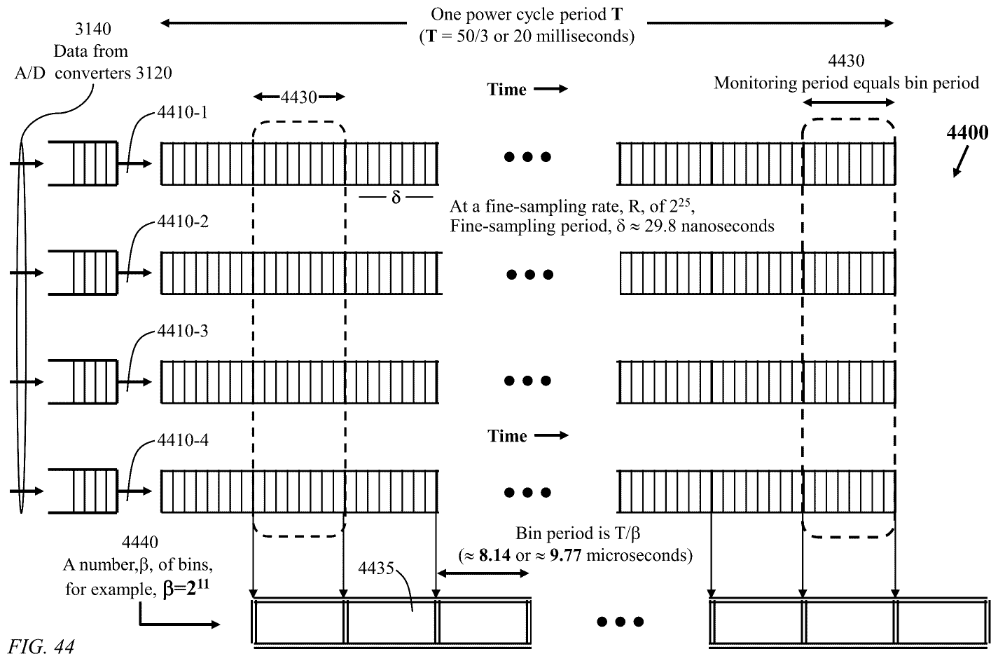

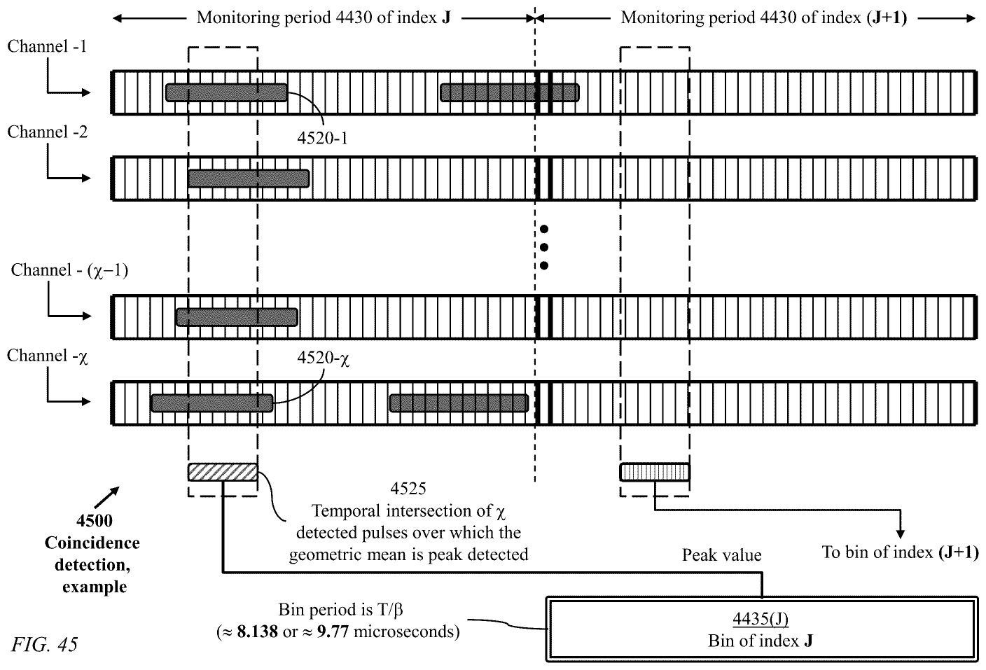

FIG. 44 illustrates an arrangement 4400 for use of fine sampling of the output signals of the log detectors to establish coincidence, or otherwise, of detected pulses from the output samples. Band-specific outputs 3140 of A/D convertors, optionally class-similarity filtered and peak detected, are held in input buffers of the coincidence filter 3170. Band-specific samples 4410-1 to 4410-χ of the χ narrow bands (χ=4 in the example of FIG. 4) are compared over a moving monitoring period 4430 to determine temporal coincidence periods as detailed in FIG. 45. The moving monitoring period may be circular (retaining history across monitoring periods) or linear (resetting after each monitoring period). In some embodiments the monitoring period equals the bin period. In others the monitoring period may be longer than the bin period, even being indefinite, with zero (or the lowest negative number) placed in a bin that did not receive a monitoring period output. The result of comparison during each monitoring period 4430 is held in a respective time-bin 4435 of an array 4440 of β bins. The bins' indices have a one-to-one correspondence to cyclical indices of the moving monitoring period 4430. In an exemplary implementation, the power cycle (20 milliseconds, for example) is divided into 2048 temporal bins 4435 and, consequently the monitoring period 435 would be ≈9.77 for a 20-milliseconds power cycle or ≈8.14 for a power cycle of 50/3 milliseconds. In cases in which more than one discharge occurs in a monitoring period there would potentially be a loss of the lower PD value. With an amplitude on the order of 1 nC and on the order of 1000 PDs before any statistical likelihood of overlap, the total discharge per period would be 1 uC, which is quite severe.

FIG. 45 illustrates a process 4500 of determining temporal coincidence of pulses detected from the band-specific samples. During a monitoring period 4430 of index J, pulses 4520-1 to 4520-χ are detected from the band-specific pulses of the χ band-specific streams (channels 1 to χ). The χ pulses coexist during an intersection period 4525. Subsequently, during the same monitoring period, only two pulses are detected from the band-specific streams of the χ band-specific streams and the two pulses are considered to belong to extraneous signals. The area (amplitude and time) of intersection period 4525 is written in a specific time bin 4535(J), 0≤J<β, β being the degree of correlation during a cyclical monitoring periods 4430. Alternate methods and output values may also be employed, as discussed earlier and subsequently.

Incoming sample series provide (a) raw ADC samples, (b) processed ADC samples (for example, averaged or peak detected), or (c) class-k matched samples with K classes in parallel. The coincidence correlation output in some embodiments takes a single sample computation of the samples, then peak detects said computation over the monitoring period. Exemplary calculations suitable for the coincidence filter are discussed later.

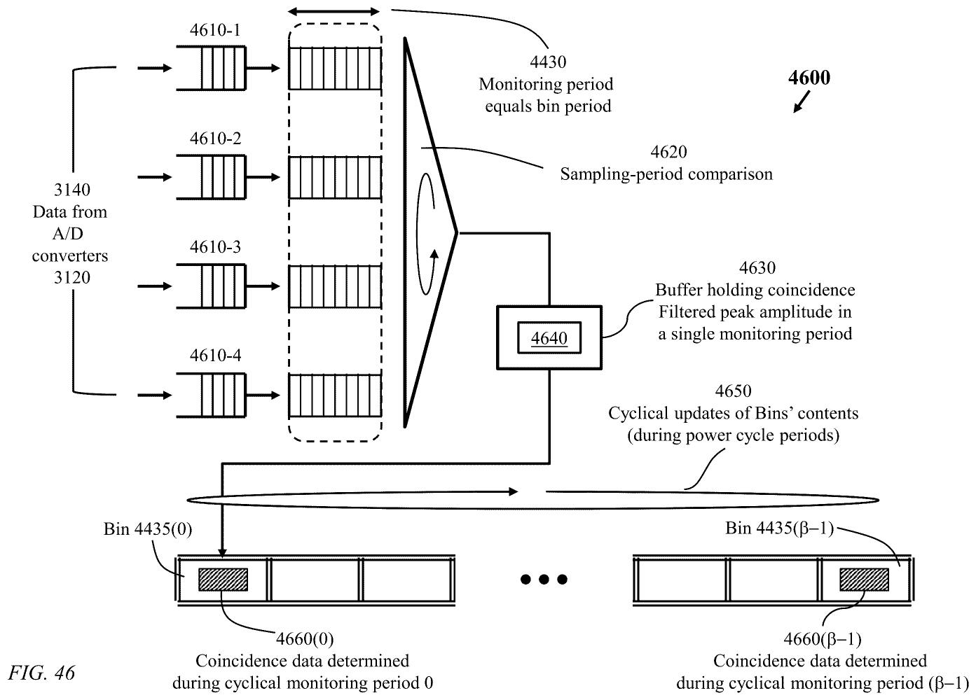

FIG. 46 is an overview 4600 of an arrangement for determining coincidence of a number χ of band-specific pulses based on arrangement 4400 and process 4500. A number χ of buffers 4610 hold data 3140 from the A/D convertors 3120. A module 4620 compares band-specific samples of the χ bands during each monitoring period 4430. A buffer 4630 holds results 4640 of the comparison, such as the geometric mean of the instantaneous samples, reduced by a factor related to their amplitude imbalance, and peak held through the monitoring period 4525. A mechanism 4650, implemented in software or hardware, cyclically updates contents of bins 4435 during successive cyclical monitoring periods storing coincidence data 4660 which includes results 4640. Coincidence data 4660 determined during a cyclical monitoring period of index J, 0≤J<β, is stored in a bin of index J.

FIG. 47 illustrates operation of a first implementation 4700 synchronicity filter 3180 using separate memory devices 4720 for determining multiple occurrences of detected pulses during a current power-cycle within a preceding moving super cycle of a number Π, Π>1, of power-cycles (20 or 50/3 milliseconds each); Π=8 in the example of FIG. 47.

A currently detected PD event magnitude 4710 of a pulse (or a record of event magnitudes during a power cycle) during a current power-cycle period is compared with Π prior temporal-coincidence records as illustrated in FIG. 26. A module 4750 ranks all coincidence filtered PD amplitudes for each time element within Π immediately preceding power cycles, by amplitude and a predetermined ranked highest magnitude PD from the history is compared to the current event. If the number of prior record events equal to or exceeding the magnitude of the new event exceeds a predetermined threshold, Λ, the pulse of currently detected coincidence record 4710 at said time element is considered valid a indication of partial discharge. The predetermined threshold is preferably determined based on the ratio of (Λ/Π) with the integers Λ and Π treated as though they are real numbers. In any case, the currently detected coincidence record overwrites a prior record stored during a corresponding prior power cycle of the immediately preceding super cycle. In some embodiments a completed new record is obtained and at the end of each cycle, the synchronicity tests are performed, and the super cycle buffer is updated. In more preferred embodiments the new record and the oldest record are the same record in the super cycle buffer and the old data is replaced with new data as the pipelined data is received. The choice of Λ is one of more permissive acceptance (low) to more stringent filtering (Λ approaching Π). The choice of Π is a trade off between memory use and a reduced reliance on any one sample point to determine the filter result.

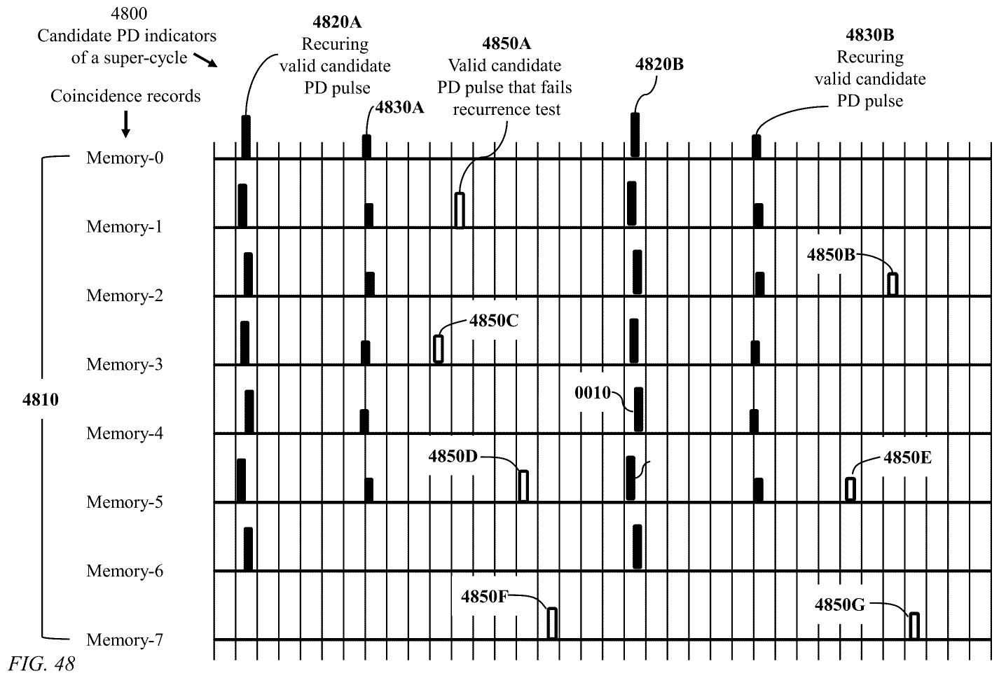

FIG. 48 illustrates an example 4800 of candidate PDs indicators within a super cycle of eight power cycles. A set 4810 of Π coincidence records (Π=8) is stored in Π separate memory devices accessed sequentially in a circular mode or in Π memory division in a shared single memory operated in a circular-storage mode. Each of coincidence records 4810-0 and 4810-4 comprises four valid pulses (4820A, 4830A, 4820B, 4830B), of acceptable magnitude. Each of coincidence records 4810-1, 4810-2, 4810-3, and 4810-5 include the pulses of records 4810-0 and 4810-4 in addition to other pulses, at different instants of the power cycle, that do not appear to belong to a single, repeating, synchronous source: 4850A in record 4810-1; 4850B in record 4810-2; 4850C in record 4810-3; and pulses 4850D and 4850 in record 4810-5. The pulses of set 4810 appear during seven power cycles of the super cycle (Λ=7) and the pulses of set 4820 appear in six power cycles of the super cycle (Λ=6).

FIG. 49 illustrates a memory device 4900 operated in a circular buffer mode for holding validated PD-related pulse for each cycle of the Π cycles of the moving super cycle. A super cycle comprises Π successive power cycles (20 or 50/3 milliseconds, each) indexed as 4910-0 to 4910-(Π−1). Memory 4900 stores data 3172 from coincidence filter 3170 for each cycle of the super cycle; the data comprises indications of presence of PDs. A currently detected coincidence record, during a power cycle of index J, 0≤J<Π, is compared with all of the stored Π records of the super cycle retrieved using rotating READ index 4960. The currently detected coincidence record then overwrites a prior record of a corresponding WRITE index 4950. Note that while other figures showed discrete memory per record, a typical c language construct would be BUF[8][2048] for 8 discrete buffers and (BUF[0]) points to the base of the first discrete buffer as well as to the base of the super cycle buffer. While conceptually different, the two implementations are, in most final implementations, identical.

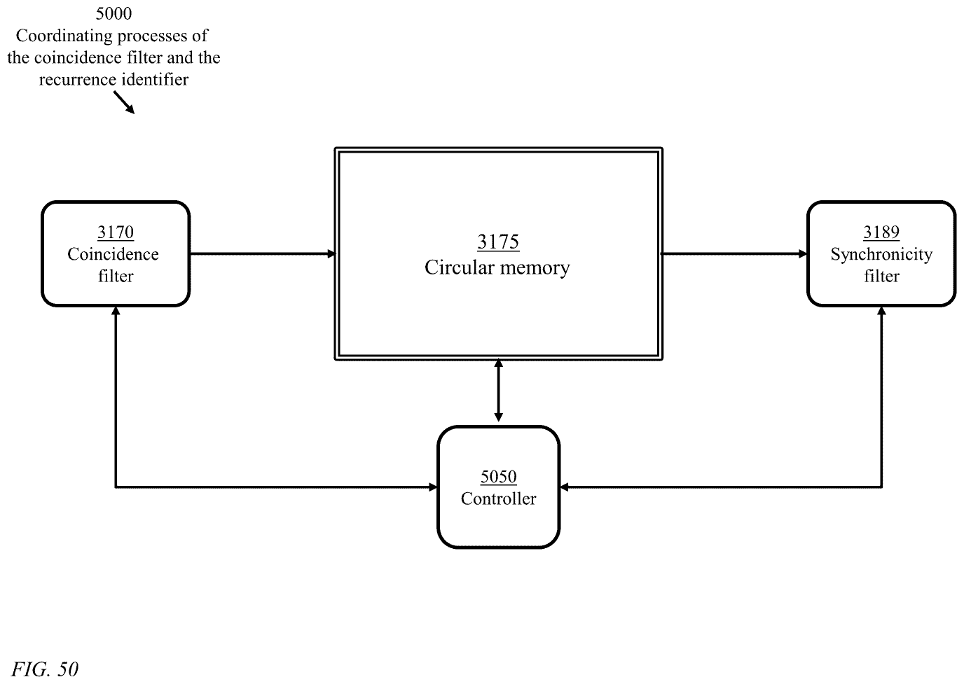

FIG. 50 illustrates an arrangement 5000 for temporal coordination of the processes of the coincidence filter 3170 determining coincidence of detected pulses, the circular buffer 3175, and the synchronicity filter 3180. A controller 5050, employing at least one hardware processor, is configured to regulate the processes.

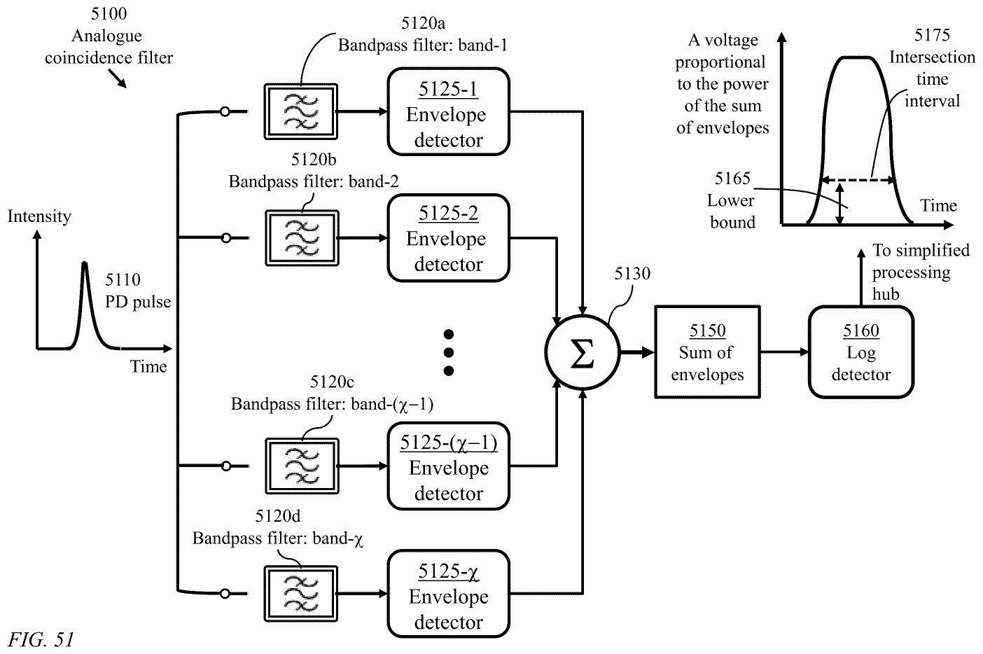

FIG. 51 illustrates an alternative 5100 to digital coincidence filtering in which the RF pulses 5110 are bandpass filtered 5120a-χ and envelope detected 5125-1 to 5125-χ to linear, positive pulse amplitudes. The linear amplitudes are summed or averaged 5130. The sum or average of amplitudes may be further processed 5150, for example, to subtract a value related to the disparity of the min and max envelope values. The processed value is optionally log detected 5160 but may be transmitted as linear values. The result is a single pulse per sensor being an aggregate of the filtered pulses, optionally penalized for the pulse imbalance. This has the advantage of allowing multiple frequency bands while reducing the number of signal wires to the hub.

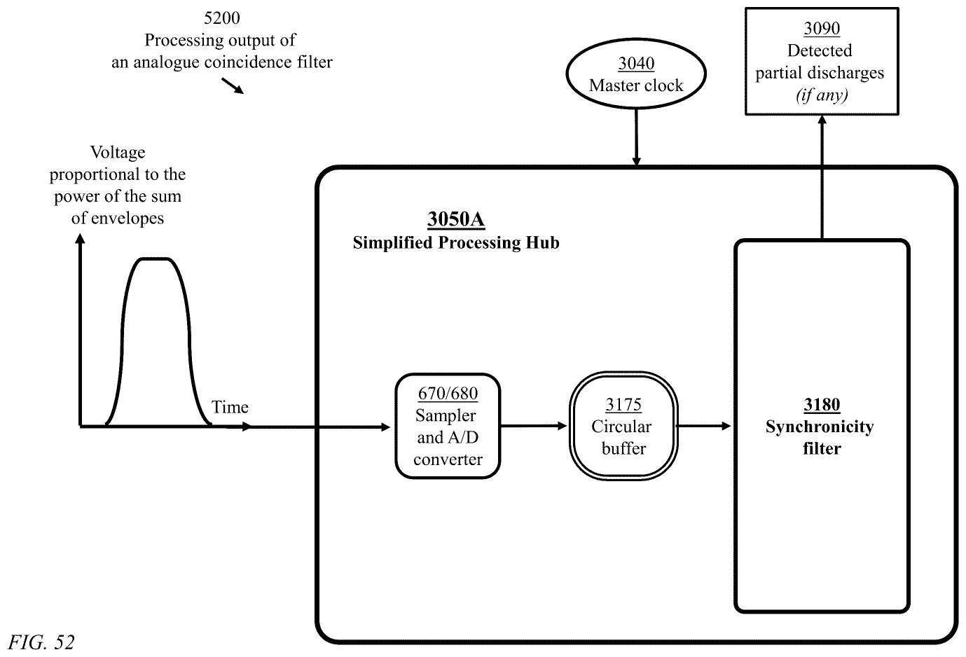

FIG. 52 illustrates further processing 5200 of transmitting the analog coincidence filter result to hub 3050 with ADC 670/680, buffer 3175, synchronicity filter 3180, and master clock 3040 outputting PD 3090.

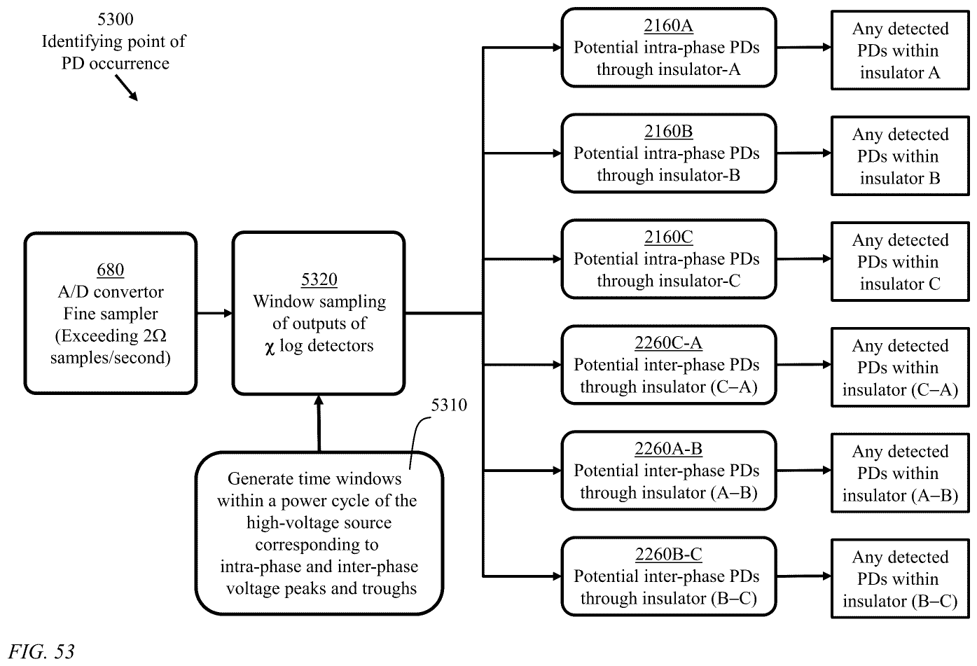

FIG. 53 illustrates a process 5300 of identifying source(s) of PD occurrence employing six processing channels 2160-1 to 2160-3 and 2260-A to 2260-C within hub 3050. A process 5310 generates time windows within a power cycle of the high-voltage source corresponding to intra-phase and inter-phase voltage peaks and troughs. A process 5320 performs intra-phase and inter-phase window sampling of outputs of the χ log detectors 440-1 to 440-χ or 440-1 to 440-χ. as illustrated in FIG. 19 to FIG. 22.

As illustrated in FIG. 21, the pair of time windows referenced as 2160A corresponds to time intervals of a power cycle during which only phase-A PDs, traversing an intra-phase insulator of phase-A, may occur. The pair of time windows referenced as 2160B corresponds to time intervals of a power cycle during which only phase-B PDs, traversing an intra-phase insulator of phase-B, may occur. The pair of time windows referenced as 2160C corresponds to time intervals of a power cycle during which only phase-C PDs, traversing an intra-phase insulator of phase-C, may occur.

As illustrated in FIG. 22, the pair of time windows referenced as 2260(C-A) corresponds to time intervals of a power cycle during which only PDs between conductors serving phases C and A may occur, traversing an insulator between a conductor of phase-C and a conductor of phase-A. The pair of time windows referenced as 2260(A-B) corresponds to time intervals of a power cycle during which only PDs between conductors serving phases A and B may occur, traversing an insulator between the conductor of phase-A and a conductor of phase-B. The pair of time windows referenced as 2260(B-C) corresponds to time intervals of a power cycle during which only PDs between conductors serving phases B and C may occur, traversing an insulator between the conductor of phase-B and the conductor of phase-C.

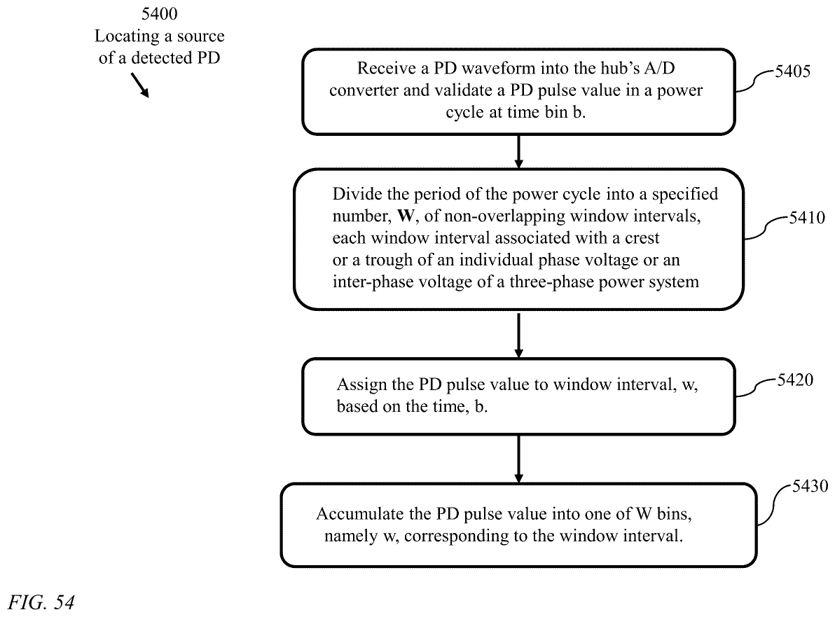

FIG. 54 illustrates a method 5400 for identifying a source, or sources, of detected partial discharges. Process 5405 receives a PD waveform as validated (coincidence and recurrence filters) pulses. Process 5410 divides the period of the power cycle into a specified number, W, of non-overlapping window intervals, each window interval associated with a crest or a trough of an individual phase voltage or an inter-phase voltage of a three-phase power system. In some implementations the bins are centered on the crest and on others they are fully in advance of the crest with any intermediate association being allowed. Process 5420 submits the output of a log detector to W window samplers each sharing inputs but routing the value to source specific bins. Process 5430 accumulates the total PD per assignment (A, B, C. AB, BC, CA).

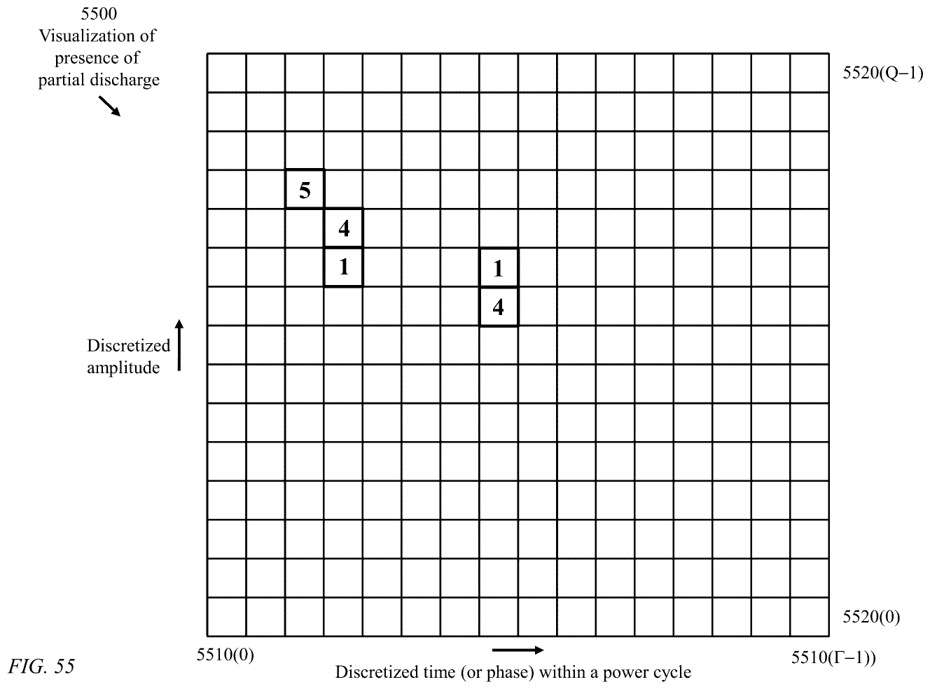

FIG. 55 illustrates an example 5500 of a memory array for creating a graphical representation of partial discharge using a matrix with a column index corresponding to discretized time (or phase) intervals and a row index corresponding to discretized amplitude intervals. The discretized time (or phase) indices within a power cycle are denoted 5510(0) to 5510(Γ−1). The discretized amplitude indices are denoted 5520(0) to 5520(Q−1), where the PD results are a scalar. The values of Γ and Q determines the granularity of the representation. An exemplary system uses 128 columns (˜2.8 degrees per column) and 127 rows. An exemplary embodiment retains the logarithmic scale of the log detector, uses an 8-bit ADC, and assumes 7 valid upper bits after linearity and processing, with each bin corresponding to a dB range and approximately related to a log interval of PD. For a system with 40 dB of linear radio frequency dynamic range and 128 rows, each row represents 0.3125 dB or a 1.155:1 PD interval.

The output of the coincidence filter and synchronicity validation filter is converted to a row index based on the amplitude and a column index based on the time of detection, and the associated matrix element is incremented to represent the number of times per accumulation period that the associated amplitude was observed in the associated time span. The matrix may be presented as a gray scale bitmap and the images are commonly called cloud plots. The bitmap is created in the processing hub 3050 and stored into a memory device and transmitted to an external Visualization unit, which may further alter the graphical visualization.

In some embodiments, the output of the coincidence filter is directly used to determine the row index, and the synchronicity filter is skipped for filling the memory associated with the graphical display. Upon accumulating a sample period, the peak synchronously recurring PD in each column time bin is determined by: for each column, start from the row index associated with the highest PD and accumulate the values into an accumulator until said accumulator exceeds a predetermined threshold. The PD amplitude associated with the row index at which the threshold is reached is the peak synchronously recurring PD in said time interval.

The peak synchronously recurring PD in the observation period is the maximum of said peak values over the set of time intervals.

In another exemplary embodiment, the individual discharges are characterized by a property (for example, pulse width, pulse shape, or high to low frequency ratio by way of non-limiting example) and separated into classifications. The data is then stored in a three-dimensional matrix for the classifications as the third dimension. When three classifications are used, the three classification elements at a time and magnitude location may be mapped to red, green, and blue in the visualization and the array may be presented as a color bitmap having red, green, and blue intensity related to the three classifications.

In embodiments with more than three classifications the image may be plotted as a 3D plot or layered 2D plot. In some embodiments a color on the spectrum is assigned to each dimension of the vector. Such implementations may order the array such that less hazardous classifications are at the background of the image and employ a color associated with low risk, for example, blue, while more hazardous classifications are at the foreground and/or use colors typically associated with imminent hazards, for example, red.

In any of these embodiments, it is useful to further condense the data into one or more values, representing the cumulative partial discharge per power cycle or segments thereof. In an exemplary embodiment, the bitmap data is used to create the 6 bins of FIG. 23 or the 12 bins of FIG. 24. For example, if the log detected data is not linearized and the bitmaps represent intervals of dB scale vertically the total PD at each time or phase column pf the bitmap is the sum over all of the columns of the linearized value of the bin times the number of pulses counted in said bin divided by the number of power waveforms accumulated to create the chart. For large values of Λ, the number of power cycles should be reduced by Λ to account for suppression of the first Λ power cycles when the historical buffers are initialized, for example, to zero. The value assigned to each of said 6 or 12 bins is the sum over the columns contained in said bin of the said column values.

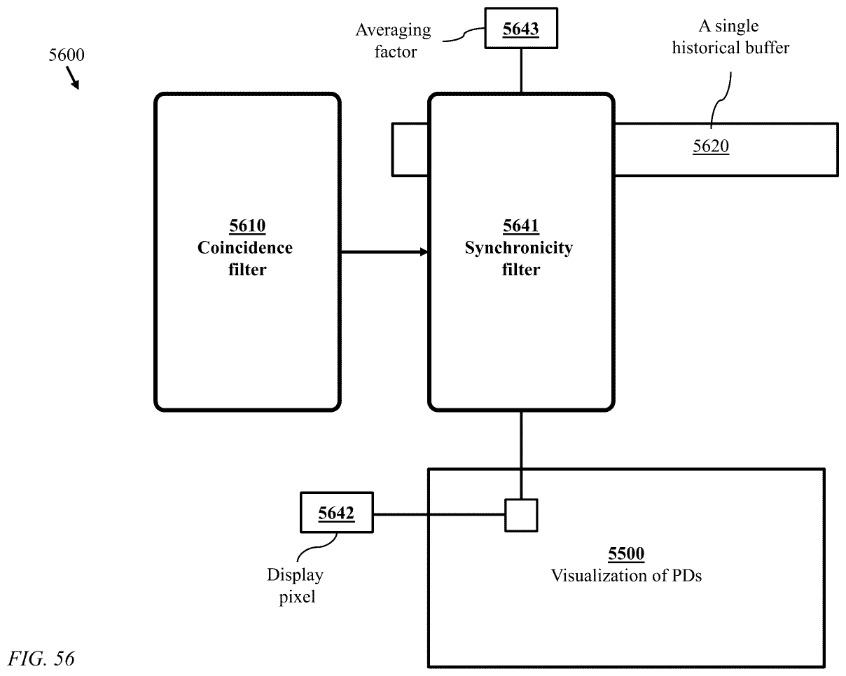

FIG. 56 illustrates an alternate embodiment of a system 5600 with coincidence filter 5621 feeding alternate synchronicity filter 5641 with a single historical buffer 5632. Filter output count is incremented into display pixel 5642 of display 5500 based on the phase of the voltage waveform and the amplitude of the filter result. The alternate filter 5641 maintains an infinite impulse response (IIR) buffer with a length of one period divided into β time intervals. The historical data in each time interval is averaged with averaging factor 5643, “F”. The filter first outputs the lesser of the new sample from 5621 and the old average value of the buffer 5432 at the current phase index to determine the row of display 5500 within the column corresponding the current phase to be incremented. The buffer then takes the new sample from 5421, multiplies it by (1−F) and adds it to the old average multiplied by F. The new average replaces the old average in the buffer. The single IIR buffer with averaging factor F is approximately equivalent to a super cycle buffer with Π≈1/(1−F) and Λ≈Π/2. The alternate embodiment is computationally simple, has low memory use, and allows arbitrarily long averaging. In integer embodiments, F is the ratio of an integer to a larger integer, 2\hat{ }f.

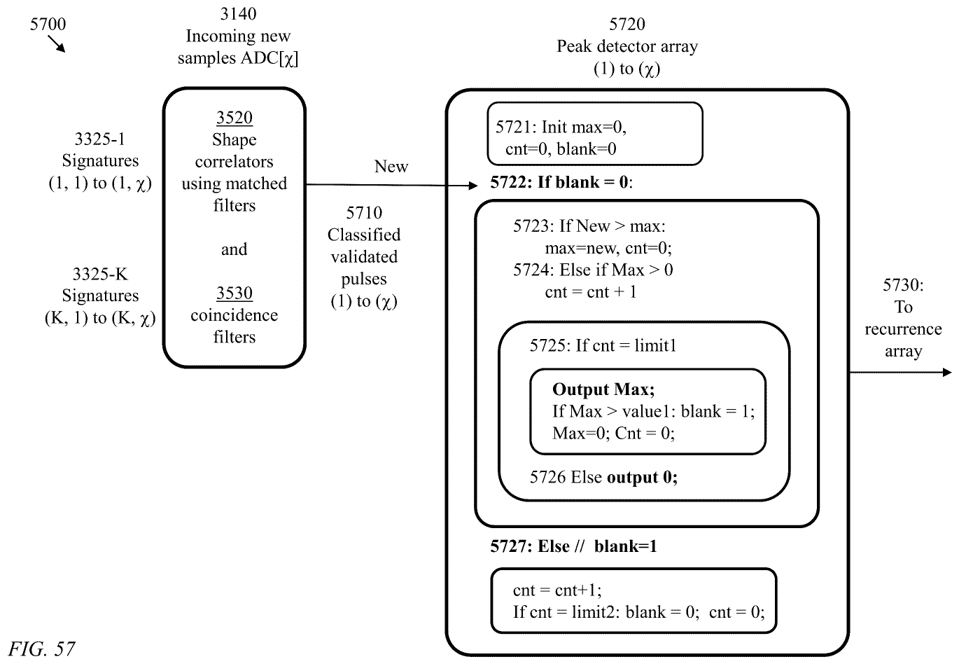

FIG. 57 illustrates an alternate method for validating PDs. Incoming sample set of χ ADC values are optionally compared 3520 to K class signatures, resulting in K×χ set of signals. The class signature FIR weights may be used to normalize amplitudes and to adjust time delays of the χ filters. Coincidence filter 3530 aggregates the χ values for each of K classes to attain K outputs being coincidence-validated and classified pulses 5710. Novel peak detection filter 5720 uses limit1 as a parameter for how long a value must remain the largest value before acceptance and limit2 parameter for how long to ignore the input after declaring a peak. The working variables are the max value, the cnt of time intervals, and a flag to determine if the input is being blanked.

Step S721 initializes the system.

Step S722, on each sample: test if the input is being accepted. If so,
Step S723 test if we have a new peak. If we have a new peak update max, reset cnt.
Step S724 Else if Max>0, increment cnt.
Step S725 If cnt has reached limit1
   Output Max, clear Max and Cnt. Enable blanking.
5726 Else
   Increment cnt
   If cnt has reached limit2, disable blanking, clear cnt.

This peak hold has three significant features:
1) Suppress the rising edge of a peak from being reported.
2) Suppress the falling edge of a peak from being reported.
3) Output a single value per PD, into the monitoring period at which it was confirmed, independent of the pulse timing.

The details of FIG. 57 assume that the samples are positive integer ADC readings related to ADC samples of an always positive log detector output. For dBm values that may be negative, Max would be initialized and reset to the most negative value and tested against that value instead of zero.

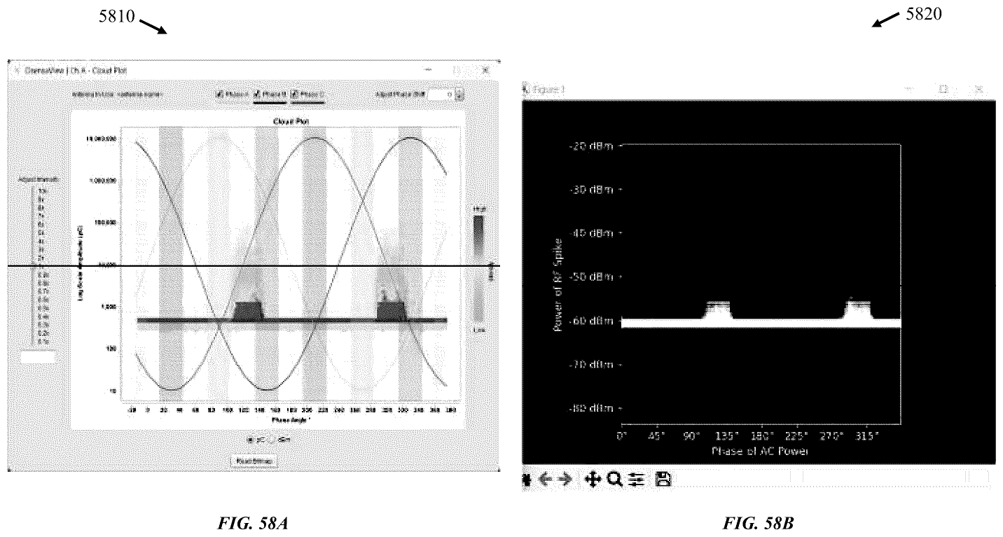

FIG. 58A is a cloud plot illustrating a partial discharge, and FIG. 58B is a gray-scale bitmap illustrating the partial discharge.

### Identifying Sources of a Partial Discharge

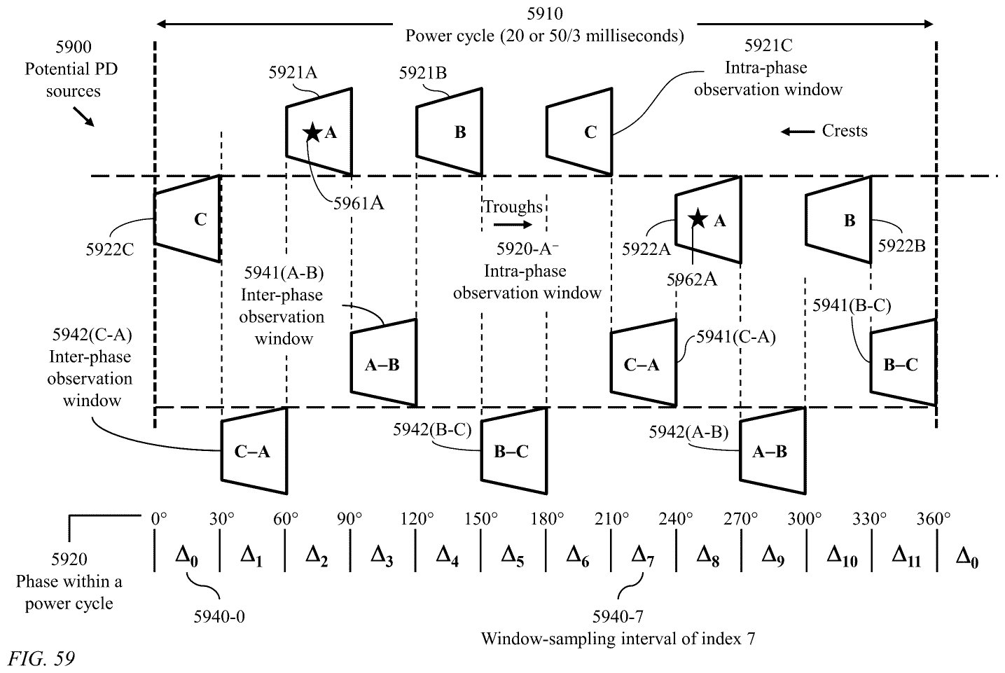

FIG. 59 illustrates observation windows 5921A, 5921B, and 5921C corresponding to voltage crests of phases A, B, and C, respectively, of the three-phase power system, and observation windows 5922A, 5922B, and 5922C corresponding to voltage troughs of phases A, B, and C, respectively. Observation windows 5941(A-B), 5941(C-A), and 5941(B-C) correspond to crests of inter-phase voltages of phases pairs (A-B), (C-A), and (B-C), respectively. Observation windows 5942(C-A), 5942(B-C), and 5942(A-B) correspond to voltage troughs of inter-phase voltages of phase pairs (C-A), (B-C), and (A-B), respectively. The widths, Δ₀ to Δ₁₁, of all windows are equal, and with the windows being non-overlapping, the width of each is π/6 radians.

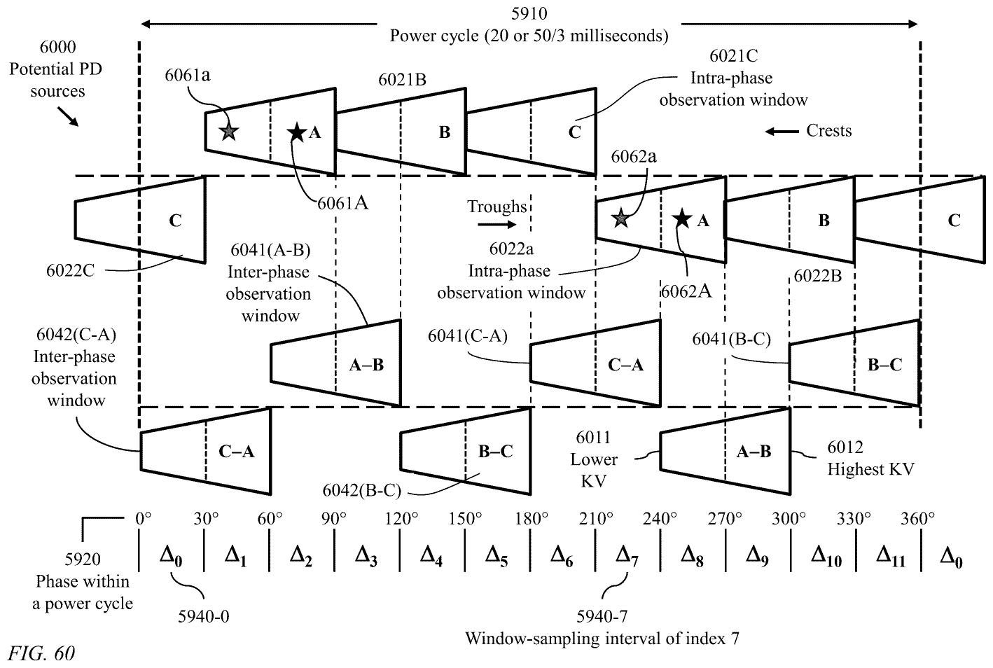

FIG. 60 illustrates observation windows 6021A, 6021B, and 6021C corresponding to voltage crests of phases A, B, and C, respectively, and observation windows 6022A, 6022B, and 6022C corresponding to voltage troughs of phases A, B, and C, respectively, for a case where each window width is π/3 radians. The intra-phase observation windows are adjacent but not overlapping. Observation windows 6041(A-B), 6041(C-A), and 6041(B-C) correspond to crests of inter-phase voltages of phases pairs (A-B), (C-A), and (B-C), respectively. Observation windows 6042(C-A), 6042(B-C), and 6042(A-B) correspond to voltage troughs of inter-phase voltages of phases pairs (C-A), (B-C), and (A-B), respectively.

With each window width being π/3 radians, the inter-phase observation windows are non-overlapping with each other, as are the intra-phase observation windows, but each inter-phase observation overlaps two intra-phase observation windows, and vice versa.

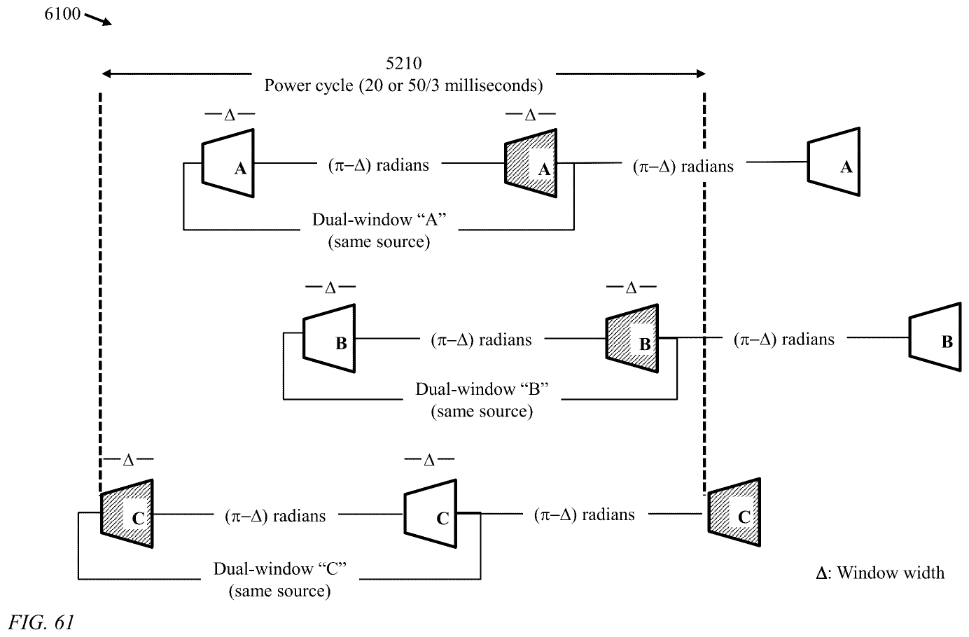

Since the near-crest and near-trough observation windows correspond to a same PD source (insulator), the observation windows are considered in pairs, herein referenced as dual windows. As illustrated in FIG. 61, the six intra-phase observation windows of FIG. 59 are presented as three dual observation windows (also called dual windows).

The pertinent number of dual observation windows is three if only intra-phase PDs are expected, as is the case for the overhead conductors of FIG. 11 or for coaxial, shielded single phase cables as are commonly used in sets of three for buried three phase distribution, The pertinent number is six if both intra-phase and inter-phase PDs are expected, as is the case of equipment feeding a cable as illustrated in FIG. 9 with unshielded cable or for bus-bars in electric power equipment having insulating spacers phase to phase and phase to enclosure earth. The width of observation windows is a flexible user-defined design parameter.

Setting a window width to equal a ratio of π to the pertinent number of dual observation windows, result in non-overlapping dual observation windows so that a detected PD relates to only one dual observation window, hence one potential source. Setting the specified window width to be larger than a first ratio of π to the pertinent number but less than double the first ratio, result in overlapping dual observation windows so that a detected PD can relate to at most two dual observation windows, hence at most two potential sources. As PD becomes more severe, it occupies a larger phase angle and tends to advance in phase from the peaks, causing ambiguity that may best be addressed by overlapping windows. If, for example, both A and AB are identified as having PD, inspection of all insulators touching phase A is recommended regardless of which diagnosis is correct.

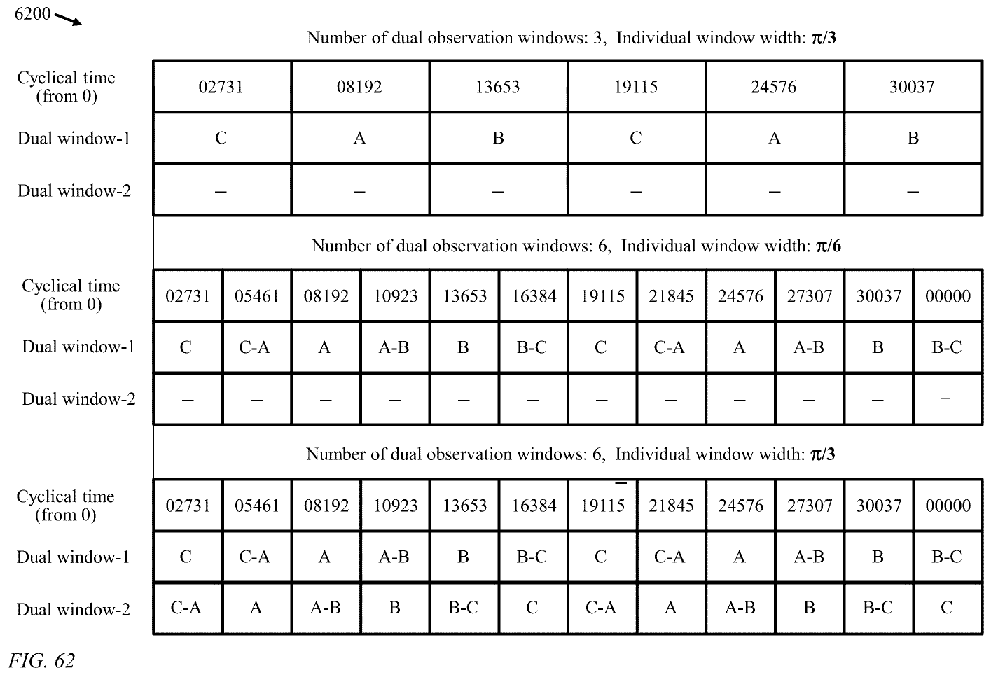

FIG. 62 illustrates a table 6300 relating ranges of time instants to identifiers of individual and dual observation windows. The source-identification module, also to be referred to as apparatus, has a generator of a sinusoidal signal that is phase-locked to the waveform of a selected phase of the three phases of the power-distribution system; the sinusoidal signal having a measurable phase displacement from the selected phase.

A cyclical timer indicates discrete time instants, within a power cycle, based on a master clock that is phase-locked to the sinusoidal signal. In the example of FIG. 62, the discrete time instants within a power cycle (20 or 50/3 milliseconds) are indexed as 0 to 32767.

With three dual observation windows, i.e., six individual windows, per power cycle, the six individual windows correspond to discrete time instants in the ranges:
{30037 to 2730), {2731 to 8191}, {8192 to 13652}, (13653 to 19114}, {19115 to 24575}, and {24576 to 30036},
for power phases C, A, B, C, A, and B, respectively.

With six dual observation windows, i.e., twelve individual windows per power cycle, the twelve individual windows correspond to discrete time instants in the ranges:
{32768 to 2730}, i.e., {0 to 2730}, {2731 to 5460}, {5461 to 8191}, {8192 to 10922}, {10923 to 13652}, {13653 to 18383}, {16384 to 19114}, {19115 to 21844}, {21845 to 24575}, {24576 to 27306}, {27307 to 30036}, and {30037 to 32767},
for power phases C, C-A, A, A-B, B, B-C, C, C-A, A, A-B, B, and B-C, respectively. Thus, an instant of detection of a PD determines a corresponding power source phase, hence a respective insulator.

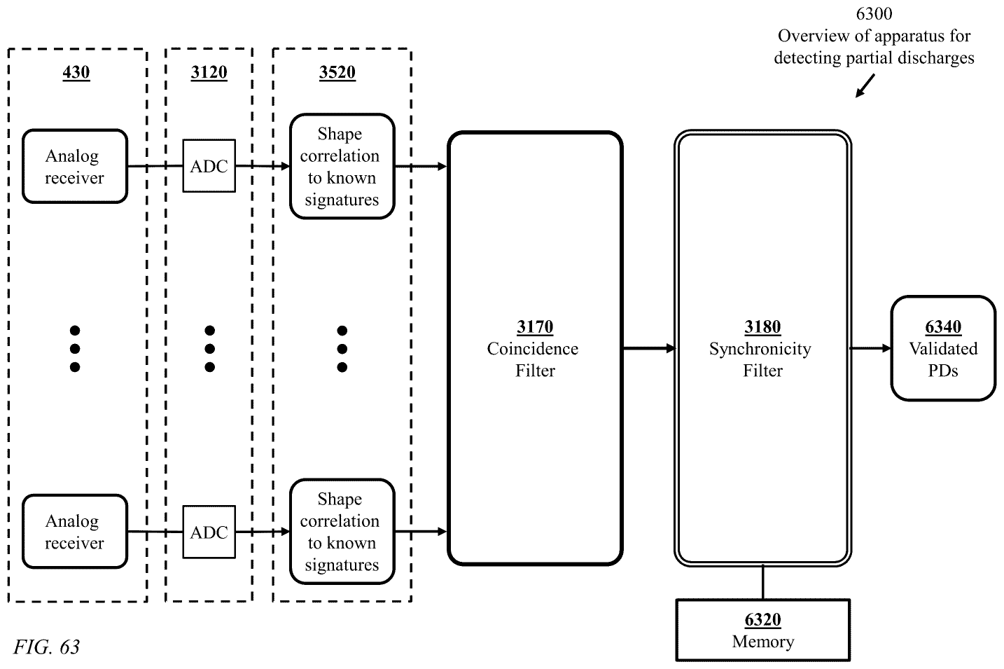

FIG. 63 presents an overview 6300 of the system for PD detection. The system comprises an array 430 (FIG. 4) of analog receivers; each analog receiver comprises an antenna, a bandpass filter, and an envelope detector or logarithmic detector as illustrated in FIG. 29. An array 3210 of samplers and ADC (A/D) convertors (FIG. 31) produces digitized samples of the detected analog signals. An array 3520 of correlators compares detected pulses with signatures of known PD classes for confirmation that the pulses are potentially a result of a PD (detailed in FIGS. 32 to 35). A coincidence filter 3170 (FIG. 31) determines the extent of temporal coincidence of pulses detected directly from output of array 3210 or received from correlator array 3520 which are acquired from different receivers. A synchronicity filter 3180 (FIG. 31) further examines pulses that pass the coincidence test of the coincidence filter 3170 to determine an extent of recurrence in successive power-cycle periods (20 or 50/3 milliseconds). A memory 6320 maintains data relevant to trailing power cycles. Data relevant to validated PD incidences are held in a memory 6340.

The output of the processing hub 3050 of FIG. 30 or the simplified hub 3050A is supplied to a source-identification module for identifying sources of partial discharge (PD), from a set of potential sources. The source-identification module comprises:
a generator of a timing signal phase-locked to the waveform of a selected phase of three phases of the power-distribution system, the timing signal having a measurable phase displacement from the selected phase;
a cyclical timer for indicating time within a power cycle based on a master clock phase-locked to the timing signal, the cyclical timer is configured to indicate cyclical time instants within each of successive power cycles, each time instant corresponding to an angular displacement between 0 and 2π;
a memory holding a data structure of a pertinent number of dual observation windows fitting a power-cycle period, each dual observation window corresponding to a potential PD source and comprising two individual windows, π-radians apart, and a specified window width, greater than zero, less than π radians;
an interface for receiving from the processing hub 3050 magnitudes and time instants of PD detection during successive power cycles;
a first device for associating PD detection to respective dual observation windows, hence respective PD sources, based, on the time instants of PD detection, the device is configured to determine angular displacements corresponding to the time instants of PD detection to determine respective dual observation windows and corresponding potential PD sources;
a processing unit for generating a table relating ranges of time instants to identifiers of the pertinent number of dual observation windows, for different values of the number of dual observation windows and individual window widths, thereby facilitating determining dual observation windows corresponding to the time instants of PD detection. An exemplary table is illustrated in FIG. 62.

The source-identification module may also comprise a second device configured to: maintain a sequence of the instants of PD detection and sort the sequence to distinguish source-specific pairs of PDs, with PDs of each source-specific PD being π radians apart and of magnitudes within a prescribed acceptable differential. Only the source-specific pairs of PDs are allotted to respective dual observation windows.

The source-identification module may also comprise a third device configured to select the width of each of windows of the dual observation windows and position the dual observation windows based on input from a user according to one of two disciplines. A first discipline centers the individual windows of each dual observation window coincide with each crest-trough pair of voltages across one of the potential sources of the set of potential sources. A second discipline places the centers of the individual windows of each dual observation window to precede each crest-trough pair of voltages across one of the potential sources of the set of potential sources by a predetermined amount no larger than half the width of said window.

In some embodiments, the degree to which the individual phase windows precede the peaks and troughs is automated and is:
A predetermined minimum value, for example, zero, if the accumulated PD in the window on a prior measurement was less than a lower threshold;
A predetermined maximum value, for example, half the width, if the accumulated PD in the window on a prior measurement was more than an upper threshold;
And an amount between the minimum and maximum predetermined amounts proportional to the relationship of the accumulated PD between the lower and upper limits.

The third device is further configured to generate multiple observation sets of the dual observation windows, each observation set comprising the pertinent number of dual observation windows with a respective distinct positioning discipline and width of individual windows. The device then determines PD sources corresponding to the multiple observation sets to single out commonly identified sources.

The source-identification module may be configured as a stand-alone module or integrated with the processing hub sharing the generator and cyclical timer.

The outputs of said coincidence and synchronicity filters are accumulated into an array and time bins comprising a column of counts for the number of recurrences of a given amplitude at a given phase of the power waveform.

The samples are accumulated over a plurality of power frequency periods, wherein the number of samples in the selected amplitude bin corresponding to the time or phase value is incremented, and a linear signal related to the accumulated partial discharge is approximated by first multiplying the count and the nominal linear value of the bin, second summing said product over all amplitude bins at a given time or phase, and third dividing the sum by the number of power cycles that were accumulated.

The array phase axis is compressed to a smaller number of bins by adding the linear amplitudes of each original bin falling within the new bin.

The array phase axis is compressed to a smaller number of bins by placing the largest linear amplitude of the set original bins falling within the new bin into the new bin. A value related to the linear amount of partial discharge is added to the value of a bin corresponding to the phase of the power waveform.

The width of the time or phase bins is 30 degrees with six bins corresponding to the peak positive and negative line to earth voltages and another six bins corresponding to the peak positive and negative line to line voltages of a three-phase power system. The offsets of the 30 degree bins are adjusted to be in advance of the peak voltages by an amount between 0 and 15 degrees.

Below is a summary of the method and system for identifying sources of partial discharge as described above.

According to one aspect of the invention, there is provided a method of identifying sources of partial discharge (PD), from a set of potential sources, in an AC (alternating current) three-phase high-voltage power-distribution system comprising:
generating a timing signal phase-locked to a selected phase of three phases of the power-distribution system, having a measurable phase displacement from the selected phase;
generating a cyclical timer for indicating time within a power cycle based on a master clock phase-locked to said timing signal;
partitioning a power-cycle period into a pertinent number of dual observation windows, each dual observation window corresponding to a potential source and comprising two individual windows, π-radians apart, and a specified window width, greater than zero, less than radians;
receiving from a PD-detection apparatus, configured to use the timing signal and the timer, magnitudes and time instants of PD detection during successive power cycles;
associating PD detection to respective dual observation windows, hence respective PD sources based, on the time instants.

In the method described above, the timer indicates cyclical time instants within each of the successive power cycles, each time instant corresponding to an angular displacement between 0 and 2π; and the associating comprises a step of determining angular displacements corresponding to the time instants of PD detection to determine said respective dual observation windows and corresponding potential PD sources.

The method further comprises generating a table relating ranges of time instants to identifiers of said pertinent number of dual observation windows, for different values of the number of dual observation windows and individual window widths, thereby facilitating determining dual observation windows corresponding to said time instants of PD detection.

The method further comprises setting the specified window width to equal a ratio of π to said pertinent number, thereby resulting in non-overlapping dual observation windows so that a detected PD relates to only one dual observation window, hence one potential source.

The method further comprises setting the specified window width to be larger than a first ratio of π to the pertinent number but less than double the first ratio, thereby resulting in overlapping dual observation windows so that a detected PD can relate to at most two dual observation windows, hence at most two potential sources.

In the method, the pertinent number is three, hence the specified window width is set to equal π/3 radians, as the set of potential sources comprises only three insulators each separating a conductor from ground or three insulators each separating each conductor from the other two with no ground.

In the method, the pertinent number may be six, hence said specified window width is set to equal π/6 radians, as the set of potential sources comprises three insulators each separating a conductor from ground, and three insulators separating conductors from each other.

In the method, where the pertinent number is six as the set of potential sources comprises three insulators each separating a conductor from ground, and three insulators separating conductors from each other, with said specified window width being set to equal π/3 radians, a detected PD can be associated with two dual observation windows.

In the above method, positioning the dual observation windows and selection of the specified window width are user defined.

In the above method, the positioning follows one of two disciplines:
the centers of the individual windows of each dual observation window coincide with each crest-trough pair of voltages across one of the potential sources of the set of potential sources; and
the centers of the individual windows of each dual observation window precede each crest-trough pair of voltages across one of the potential sources of the set of potential sources by a predetermined amount no larger than half the width of the window.

In the above method, the positioning follows one of the following:
the centers of the individual windows of each dual observation window precede each crest-trough pair of voltages across one of the potential sources of the set of potential sources by a predetermined minimum amount when the PD in the dual observation window is below a lower threshold; and
the centers of the individual windows of each dual observation window precede each crest-trough pair of voltages across one of the potential sources of the set of potential sources by a predetermined maximum amount when the PD in said dual observation window is above an upper threshold;
with transitioning between said minimum and maximum positions as PDs in the dual observation window transitions between the lower and upper thresholds.

The method further comprises:
using multiple observation sets of said dual observation windows, each set comprising said pertinent number of dual observation windows with a respective distinct positioning discipline and width of individual windows; and
comparing said respective PD sources corresponding to said multiple observation sets to single out commonly identified sources.

The method further comprises determining for each dual observation window:
a cumulative count of PD detections;
a moving magnitude average; and
a moving magnitude standard deviation;
for use in additional validation of results of said PD-detection apparatus.

According to another aspect of the invention, there is provided an apparatus for identifying sources of partial discharge (PD), from a set of potential sources, in an AC (alternating current) three-phase high-voltage power distribution system, the apparatus comprising:
a generator of a timing signal phase-locked to waveform of a selected phase of three phases of the power-distribution system, said timing signal having a measurable phase displacement from the selected phase;
a cyclical timer for indicating time within a power cycle based on a master clock phase-locked to said timing signal;
a memory holding a data structure a pertinent number of dual observation windows fitting a power-cycle period, each dual observation window corresponding to a potential PD source and comprising two individual windows, π-radians apart, and a specified window width, greater than zero, less than π radians;
a receiver for receiving from a PD-detection apparatus, configured to use the sinusoidal signal and the timer, magnitudes and time instants of PD detection during successive power cycles; and
a first device for associating PD detection to respective dual observation windows, hence respective PD sources, based, on the time instants.

In the above apparatus:
the cyclical timer is configured to indicate cyclical time instants within each of the successive power cycles, each time instant corresponding to an angular displacement between 0 and 2π; and
the first device is configured to determining angular displacements corresponding to said time instants of PD detection to determine the respective dual observation windows and corresponding potential PD sources.

The apparatus further comprises a processing unit for generating a table relating ranges of time instants to identifiers of said pertinent number of dual observation windows, for different values of the number of dual observation windows and individual window widths, thereby facilitating determining dual observation windows corresponding to the time instants of PD detection.

The apparatus further comprises a third device configured to select the specified window width and position said dual observation windows, based on input from a user, according to one of two disciplines:
a first discipline centers the individual windows of each dual observation window coincide with each crest-trough pair of voltages across one of the potential sources of the set of potential sources; and
a second discipline places the individual windows of each dual observation window to precede each crest-trough pair of voltages across one of the potential sources of the set of potential sources.

In the above apparatus, the third device is further configured to:
generate multiple observation sets of said dual observation windows, each observation set comprising said pertinent number of dual observation windows with a respective distinct positioning discipline and width of individual windows; and
determine said respective PD sources corresponding to said multiple observation sets to single out commonly identified sources.

The apparatus is further configured to determine for each dual observation window:
a cumulative count of PD detections;
a moving magnitude average; and
a moving magnitude standard deviation;
thereby enabling additional validation of results of said PD-detection apparatus.

The apparatus is optionally integrated with the PD-detection apparatus sharing the generator and cyclical timer.

Various modification and variations may be made to the above noted embodiments of the invention.

In some embodiments, the outputs of the coincidence filter comprise a separate value for each frequency band indicating the signal strength in said band, adjusted for the balance of frequency data, and the outputs of said synchronicity filters provide phase resolved partial discharge data components contributed in each frequency band. In preferred embodiments the output is a single value being the correlation of the inputs, adjusted for the balance of frequency data.

In some embodiments, the outputs of the coincidence filter comprise a value for each waveform correlation classification signature indicating the signal strength for said classification and the outputs of said synchronicity filters provide phase resolved partial discharge data components contributed by each classification. In preferred embodiments, a single value is assigned to the classification offering the best match with an amplitude related to the coincident filter output of the best classification. The latter approach assumes that the inputs comprise a single class of PD along with some noise that looks like other PDs and that only the class-correlated and coincident part of the signal is truly PD. The former approach allows all classifications to be supplied to parallel synchronicity filters on the assumption that more than one class of PD overlap in time or that the classification is not stable over the measured superset but that a majority of detections will give the same classification.

The outputs of the synchronicity filter for each frequency band are input to a clustering analyzer and the relative strengths of the frequency bands are used to classify the discharge, and the outputs of the synchronicity filter for each waveform correlation classification filter are input to a clustering analyzer and the relative strengths of the frequency bands are used to classify the discharge.

A plurality of power cycles are accumulated into up to three arrays of pixels each array corresponding to a frequency band or a classification of partial discharge each array having one dimension correspond to time or phase bins and the other dimension correspond to amplitude bins accumulating samples from a plurality of power cycles, and each array presenting the number of samples per pixel indicated by the brightness of one of red, green or blue for the pixel, the color of each pixel indicating a classification and the brightness indicating a level of partial discharge.

There is provided a plurality of signal receivers, each comprising a transducer to receive a signal related to partial discharge, a filter to select a portion of the frequency content of said signal, a converter to convert the signal to a frequency capable of digital signal processing an analog to digital signal processor, at least one coincidence filter to select components of a signal that are coincident in time, at least one synchronicity filter to select signals that repeat at a stable time or phase relative to the power frequency. The convertor is an envelope or amplitude detector, the converter is a logarithmic detector, and at least one signal is a radio wave.

Receivers are disclosed for radio frequency energy, however, the invention may be performed on signals from many transducers, including UV detectors, sound detectors, and the like where the signals are indicative of partial discharge. Radio signals are described as being received by antennas, however other radio frequency transducers are known in the art and are used interchangeably with antennas including capacitive and magnetic probes and the like.

Another method of synchronicity filtering within a cloud plot is also disclosed. The method comprises filtering candidate partial discharge events for synchronicity wherein, candidate partial discharge events are counted in a two dimensional memory with one dimension providing a set of time intervals and another a set of amplitude intervals. Before an accumulation period, said memory is reset to zero counts. On receiving a candidate partial discharge from a coincidence filter, the memory element corresponding to the time and amplitude is incremented. After an accumulation period, for each time index of the memory, starting from the highest partial discharge index, accumulate the counts downward until a predetermined count number is attained. The index at which the count number is attained, if any, corresponds to the peak PD in that time interval. Optionally draw symbol in each column of a display at this element. Take the maximum of the peaks from each time interval and report said maximum as the peak PD.

Methods of the embodiment of the invention are performed using one or more hardware processors, executing processor-executable instructions causing the hardware processors to implement the processes described above. Computer executable instructions may be stored in processor-readable storage media such as hard disks, Flash Read Only Memory (ROM), non-volatile ROM, and Random Access Memory (RAM). A variety of processors, such as microprocessors, digital signal processors, and gate arrays, may be employed.

Systems of the embodiments of the invention may be implemented as any of a variety of suitable circuitry, such as one or more microprocessors, digital signal processors (DSPs), application-specific integrated circuits (ASICs), field programmable gate arrays (FPGAs), discrete logic, software, hardware, firmware or any combinations thereof. When modules of the systems of the embodiments of the invention are implemented partially or entirely in software, the modules contain a memory device for storing software instructions in a suitable, non-transitory computer-readable storage medium, and software instructions are executed in hardware using one or more processors to perform the techniques of this disclosure.

It should be noted that methods and systems of the embodiments of the invention and data streams described above are not, in any sense, abstract or intangible. Instead, the data is necessarily presented in a digital form and stored in a physical data-storage computer-readable medium, such as an electronic memory, mass-storage device, or other physical, tangible, data-storage device and medium. It should also be noted that the currently described data-processing and data-storage methods cannot be carried out manually by a human analyst, because of the complexity and vast numbers of intermediate results generated for processing and analysis of even quite modest amounts of data. Instead, the methods described herein are necessarily carried out by electronic computing systems having processors on electronically or magnetically stored data, with the results of the data processing and data analysis digitally stored in one or more tangible, physical, data-storage devices and media.

1. A method for detecting a partial discharge in electric power equipment, comprising:
(a) by at least two receivers, obtaining corresponding at least two narrowband signals corresponding to respective frequency bands of the partial discharge; and
(b) detecting a temporal coincidence of said at least two narrowband signals, thereby indicating presence of the partial discharge.

2. The method of claim 1, further comprising identifying a synchronous recurrence of the partial discharge over a plurality of power cycles, thereby validating the possible presence of the partial discharge.

3. The method of claim 1, wherein:
the step (a) comprises:
receiving electromagnetic signals using one or more antennas placed in the vicinity of said electric power equipment at a location selected to acquire radiation induced by the partial discharge;
submitting output electrical signals of said one or more antennas to a set of bandpass filters of different passbands;
the step (b) comprises:
detecting significant pulses within output signal streams of said set of bandpass filters, each significant pulse indicating a possible partial discharge; and
determining candidate indicators of occurrence of the partial discharge as significant pulses that appear concurrently in two or more of the output signal streams of said set of bandpass filters.

4. The method of claim 3, wherein the significant pulses have an amplitude exceeding a specified threshold and a joint overlap time interval exceeding a specified time duration.

5. The method of claim 3, further comprising:
determining a pattern of said determining candidate indicators between each electric power cycle of a moving superset of a predetermined number of successive electric power cycles;
comparing the most recent of said candidate indicators to previous indicators within said superset occurring within a predetermined time interval of the superset of power cycles related to the times of said candidate indicators; and
affirming that said candidate indicators repeat synchronously and at the same or higher signal strength, a predetermined number of times within the superset.

6. The method of claim 3, further comprising:
dividing each said power cycle into a number of monitoring periods;
comparing said output signal streams of said set of bandpass filters during each monitoring period to determine temporal coincidence of a majority of said significant pulses; and
acquiring said candidate indicators for each of said successive power cycles.

7. The method of claim 3, further comprising:
employing a second set of bandpass filters, exceeding said set of passband filters, each being coupled to an output of said one or more antennas; and
selecting a number of output signal streams from said second set of bandpass filters, equal to a number of bandpass filters in said set of bandpass filters, based on signal quality indications.

8. The method of claim 1, wherein the step (b) is based on one of the following:
direct logarithmic envelope detection of said at least two narrowband signals;
direct linear envelope detection of said at least two narrowband signals; and
direct linear envelope detection of said at least two narrowband signals to produce detected envelopes followed by logarithmic conversion of the detected envelopes.

9. The method of claim 1, wherein the step (b) comprises processing said at least two narrowband signals according to a peak and hold method to capture amplitudes of partial discharge pulses, with optional blanking feature to suppress noise.

10. The method of claim 1, wherein said partial discharge belongs to a known set of classes of partial discharges, and said different passbands are selected based on known bandwidths of radiated spectra of said partial discharges, said passbands being selected according to one of the following:
equal bandwidths around spread central frequencies; and
bandwidths determined as a function of central frequencies.

11. The method of claim 1, further comprising classifying the partial discharge signal.

12. The method of claim 3, wherein said partial discharge belongs to a known set of classes of partial discharges, the method further comprises determining a number of class-specific, band-specific, signatures for each class of said set of classes and each spectral band of said different passbands based on:
acquiring a set of reference signals, each reference signal representing a respective class of partial discharge at source;
supplying, said each reference signal to each bandpass filter of said set of bandpass filters; and
extracting said class-specific, band-specific, signatures as detected signals of said set of bandpass filters.

13. The method of claim 3, wherein said partial discharge belongs to a known set of classes of partial discharges, the method further comprising:
determining a number of class-specific, band-specific, signatures for each class of said set of classes and each spectral band of said different passbands based on:
acquiring one of:
a set of time-domain characterizations of partial-discharge at source, each time-domain characterization corresponding to a respective partial-discharge class; and
a set of frequency-domain characterizations of partial-discharge at source, each frequency-domain characterization corresponding to a respective partial-discharge class; and
computing said class-specific, band-specific, signatures using an analytical model of said bandpass filters, and one of said time-domain characterizations and frequency-domain characterization.

14. The method of claim 12, further comprising:
for each set of class-specific signatures, comparing a shape of each of said significant pulses with a respective band-specific signature to produce respective shape-similarity indicators; and
associating said significant pulses with either of:
at least one of the classes of said known set of classes of partial discharges based on acceptable levels of said respective shape-similarity indicators; and
a null class otherwise.

15. The method of claim 14, further comprising determining said respective shape-similarity indicators prior to said determining candidate indicators.

16. The method of claim 1, further comprising visualizing the partial discharge.

17. A system for detecting a partial discharge in electrical power equipment, comprising:
(a) at least two receivers for obtaining corresponding at least two narrowband signals corresponding to respective frequency bands of the partial discharge signal; and
(b) a means for detecting a temporal coincidence of said at least two narrowband signals, thereby indicating a presence of the partial discharge.

18. The system of claim 17, further comprising a means for identifying a synchronous recurrence of the partial discharge signal over a plurality of power cycles, thereby validating the partial discharge.

19. The system of claim 17, wherein:
said at least two receivers (a) comprise:
at least one antenna placed at a location selected to acquire electromagnetic radiation induced by the partial discharge;
a set of bandpass filters, of different passbands, each coupled to said at least one antenna to produce a respective signal stream;
said means for detecting (b) comprise:
a set of pulse detectors, each detector for detecting pulses within a signal stream of a respective bandpass filter; and
a coincidence filter configured to determine occurrence of a possible partial discharge based on the pulses appearing concurrently in two or more of the signal streams of said pulse detectors.

20. The system of claim 19, wherein the significant pulses have an amplitude exceeding a specified threshold and a joint overlap time interval exceeding a specified time duration.

21. The system of claim 17, further comprising a synchronicity filter configured to:
determine a pattern of detected signals within each electric power cycle of a moving superset of a predetermined number of successive electric power cycles;
identify signals, within said superset, occurring within a predefined mutual phase-displacement within a power cycle period; and
affirm that said detected signals repeat synchronously at the same or higher signal strength, a predetermined number of times within the superset.

22. The system of claim 19, further comprising a buffer for holding said candidate indicators of occurrence of partial discharges during a moving superset of a predetermined number of successive electric power cycles.

23. The system of claim 19, wherein said each detector is one of:
a logarithmic envelope detector directly coupled to said respective bandpass filter;
a linear envelope detector directly coupled to said respective bandpass filter; and
a linear envelope detector, directly coupled to said respective bandpass filter to produce detected envelopes, coupled to a logarithmic converter of the detected envelopes.

24. The system of claim 19 configured to select said set of bandpass filters and said set of detectors from a larger number of antennas, together with corresponding bandpass filters and detectors, based on signal-quality indications.

25. The system of claim 19, further comprising means for processing the output signal streams of said set of bandpass filters according to a peak and hold technique to capture amplitudes of partial discharge pulses, with an optional blanking feature for suppressing noise.

26. The system of claim 19, further comprising a means for classifying the partial discharge signal.

27. The system of claim 19, further comprising a module for determining a number of class-specific, band-specific signatures for each class of a known set of partial discharge classes and each spectral band of said different passbands, said module configured to:
acquire a set of reference signals, each reference signal representing a respective partial discharge class at a source; and
supply said each reference signal to each bandpass filter of said set of bandpass filters; and
extract said class-specific, band-specific, signatures as detected signals of said set of bandpass filters.

28. The system of claim 19, further comprising a classification module, for classifying the partial discharge, configured to:
compare each of said candidate indicators of occurrence of the partial discharge with a respective band-specific signature to produce respective shape-similarity indicators; and
associate said candidate indicators with a respective class according to said respective shape-similarity indicators.

29. The system of claim 17, wherein the means for detecting further comprises a single historical buffer configured to store trailing average data for partial discharge for at least one cycle length.

30. The system of claim 17, further comprising a means for visualizing the partial discharge.
